(19) United States
(12) Patent Application Publication
(10) Pub. No.: US 2022/0165969 A1
(43) Pub. Date: May 26, 2022

(54) ORGANIC ELECTROLUMINESCENT COMPOUND AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Hyun KIM, Gyeonggi-do (KR); Dong-Hyung LEE, Gyeonggi-do (KR)

(21) Appl. No.: 17/666,885

(22) Filed: Feb. 8, 2022

Related U.S. Application Data
(63) Continuation-in-part of application No. 16/462,985, filed on May 22, 2019, now abandoned.

(30) Foreign Application Priority Data
Dec. 27, 2016 (KR) 10-2016-0180012
Mar. 2, 2017 (KR) 10-2017-0027214
Dec. 22, 2017 (KR) 10-2017-0178000

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

The present disclosure relates to an organic electroluminescent compound and an organic electroluminescent device comprising the same. By comprising the organic electroluminescent compound of the present disclosure, it is possible to provide an organic electroluminescent device having low driving voltage and/or high luminous efficiency properties while exhibiting deep red color compared to a conventional organic electroluminescent device.

### TECHNICAL FIELD

The present disclosure relates to an organic electroluminescent compound and an organic electroluminescent device comprising the same.

### BACKGROUND ART

An electroluminescent device (EL device) is a self-light-emitting display device which has advantages in that it provides a wider viewing angle, a greater contrast ratio, and a faster response time. The first organic EL device was developed by Eastman Kodak in 1987, by using small aromatic diamine molecules and aluminum complexes as materials for forming a light-emitting layer [Appl. Phys. Lett. 51, 913, 1987].

An organic EL device (OLED) changes electric energy into light by applying electricity to an organic light-emitting material, and commonly comprises an anode, a cathode, and an organic layer formed between the two electrodes. The organic layer of the OLED may comprise a hole injection layer, a hole transport layer, a hole auxiliary layer, a light-emitting auxiliary layer, an electron blocking layer, a light-emitting layer (containing host and dopant materials), an electron buffer layer, a hole blocking layer, an electron transport layer, an electron injection layer, etc, if necessary. The materials used in the organic layer can be classified into a hole injection material, a hole transport material, a hole auxiliary material, a light-emitting auxiliary material, an electron blocking material, a light-emitting material, an electron buffer material, a hole blocking material, an electron transport material, an electron injection material, etc., depending on functions. In the OLED, holes from an anode and electrons from a cathode are injected into a light-emitting layer by the application of electric voltage, and an exciton having high energy is produced by the recombination of the holes and electrons. The organic light-emitting compound moves into an excited state by the energy and emits light from energy when the organic light-emitting compound returns to the ground state from the excited state.

The most important factor determining luminous efficiency in an OLED is light-emitting materials. The light-emitting materials are required to have the following features: high quantum efficiency, high movement degree of an electron and a hole, and uniformality and stability of the formed light-emitting material layer. The light-emitting material may be classified into blue, green, and red light-emitting materials according to the light-emitting color, and further includes yellow or orange light-emitting materials. Furthermore, the light-emitting material may be classified into a host material and a dopant material in a functional aspect. In general, a device having excellent EL characteristics has a structure comprising a light-emitting layer formed by doping a dopant to a host.

Until now, Iridium(III) complexes have been widely known as a dopant of a phosphorescent light-emitting material, including bis(2-(2′-benzothienyl)-pyridinato-N,C-3′)iridium(acetylacetonate) [(acac)Ir(btp)₂], tris(2-phenylpyridine)iridium [Ir(ppy)₃] and bis(4,6-difluorophenylpyridinato-N,C2)picolinato iridium (Firpic) as red-, green- and blue-emitting materials, respectively.

In addition, 4,4′-N,N′-dicarbazol-biphenyl (CBP) is the most widely known phosphorescent host material. Recently, Pioneer (Japan) et al., developed a high performance organic electroluminescent device using bathocuproine (BCP) and aluminum(III) bis(2-methyl-8-quinolinate)(4-phenylphenolate) (BAlq), etc., as host materials, which were known as hole blocking materials.

Meanwhile, U.S. Patent Application Publication No. 2015/357588 discloses the following compound as a phosphorescent light-emitting material.

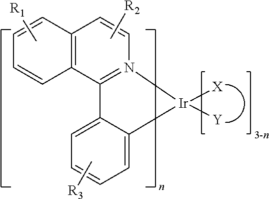

U.S. Patent Application Publication No. 2015/0001472 discloses the following ancillary ligand.

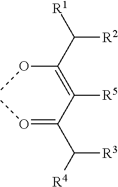

Korean Patent Application Laid-Open No. 2011-C077350 discloses the following compound as a red phosphorescent light-emitting material.

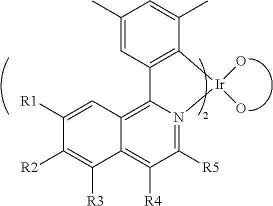

However, organic electroluminescent devices comprising the compound disclosed in the aforementioned documents are still limited in showing high color purity while exhibiting high luminescent efficiency.

### DISCLOSURE OF THE INVENTION

### Problems to be Solved

The objective of the present disclosure is firstly, to provide an organic electroluminescent compound capable of producing an organic electroluminescent device having low driving voltage and/or high luminous efficiency properties while exhibiting a deep red color, and secondly, to provide an organic electroluminescent device comprising the organic electroluminescent compound.

### Solution to Problems

The higher the X value in a standard colorimetric system set by the International Commission on Illumination (CIE) (hereinafter, referred to as “CIE 1931 colorimetric system”), the higher color purity of red, and thus, conventionally, the study has been conducted to develop a deep red organic electroluminescent device having a large X value in order to increase color purity. However, when the X value is increased in the CIE 1931 colorimetric system, the luminous efficiency of the device is lowered.

In addition, most phosphorescent emitters are isotropically oriented iridium complexes due to their near-globular shape. It is known that the theoretical External Quantum Efficiencies (EQEs) of the Iridium complex reported so far are limited to 30%. However, according to the recently reported reference, Nature Communications DOI: 10.1038/ncomms5769 (2014), in the case of acac-based Heteroleptic Iridium Complexes (HICs), the direction of the transition dipole moment (TDM) is all parallel to the N-Ir-N axis, as shown in FIG. 4 of the present disclosure. Furthermore, according to the reference, Journal of Materials Chemistry 2011, 21, 19187, it is known that a material with a more linear shape is more likely to be stacked parallel to the substrate.

Based on the above two references, the present inventors conducted research in the direction of aligning the TDM of the light emitting body in parallel with the substrate to induce a higher ratio of light emitted perpendicular to the substrate. Although not limited by theory, this is because light emitted in a direction perpendicular to the substrate reduces total internal reflection (TIR) caused by the difference in refractive index of the medium inside the OLED, thereby increasing the device's efficiency.

The present inventors tried to make the molecule linear in the N-Ir-N axis direction because TDM is formed in the N-Ir-N axis direction in the Acac based Ir complex. It has been found that molecules can be elongated in the N-Ir-N direction. Through various simulations, it was found that introducing a substituent at the 6th position of isoquinoline can make the molecule elongate in the N-Ir-N direction. Furthermore, it was thought that if the substituent was an alkyl group having 4 or more carbons, the horizontal direction would most effectively increase, thereby increasing the efficiency.

Accordingly, the present inventors have found that an organic electroluminescent device having low driving voltage and/or high luminous efficiency properties while exhibiting deep red color can be provided by using a ligand specified by introducing an alkyl group having two or more carbons at the 6-position which is the farthest from the amine of isoquinoline, and thus the present invention has been completed. Specifically, the above objective can be achieved by an organic electroluminescent compound represented by the following formula 1, wherein an organic electroluminescent device comprising the organic electroluminescent compound represents a deep red color.

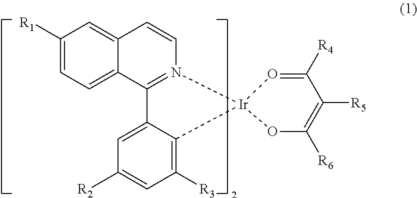

In formula 1,

R₁ represents a substituted or unsubstituted (C2-C6)alkyl,

R₂ and R₃, each independently, represent a substituted or unsubstituted (C1-C5)alkyl, and

R₄ to R₆, each independently, represent hydrogen, deuterium, a substituted or unsubstituted (C1-C5)alkyl, or a substituted or unsubstituted (C5-C30)aryl; or are linked to an adjacent substituent to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom selected from the group consisting of nitrogen, oxygen, and sulfur.

### Effects of the Invention

By comprising the organic electroluminescent compound of the present disclosure, it is possible to provide an organic electroluminescent device having low driving voltage and/or high luminous efficiency properties while exhibiting deep red color.

### BRIEF DESCRIPTION OF THE FIGURES

FIG. 1 illustrates NMR data of compound C-4 which is the organic electroluminescent compound according to one embodiment of the present disclosure.

FIG. 2 illustrates NMR data of compound C-2 which is the organic electroluminescent compound according to one embodiment of the present disclosure.

FIG. 3 illustrates NMR data of compound C-16 which is the organic electroluminescent compound according to one embodiment of the present disclosure.

FIG. 4 illustrates a molecular structure of compound C-5, which is the organic electroluminescent compound according to one embodiment of the present disclosure, in three-dimensional (3D) form.

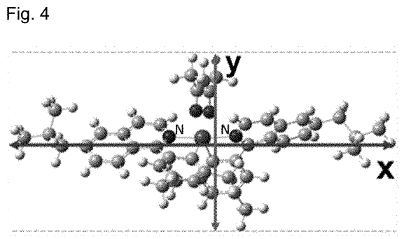

### EMBODIMENTS OF THE INVENTION

Hereinafter, the present disclosure will be described in detail. However, the following description is intended to explain the invention, and is not meant in any way to restrict the scope of the invention.

The term “organic electroluminescent compound” in the present disclosure means a compound that may be used in an organic electroluminescent device, and may be comprised in any layer constituting an organic electroluminescent device, as necessary.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material, an electron buffer material, a hole blocking material, an electron transport material, or an electron injection material.

The term “CIE 1931 colorimetric system” in the present disclosure means a standard colorimetric system defined by the International Commission on Illumination (CIE) in 1931, and is based on the XYZ colorimetric system which is a CIE standard colorimetric system among RGB colorimetric system and XYZ colorimetric system. The XYZ colorimetric system represents all colors as three parameters of X, Y and Z, based on the measurement value by the spectrophotometer. Specifically, X and Y indicate chromaticity, and a color is represented by a point of chromaticity coordinates made up of X and Y coordinates. Also, Z means lightness, and indicates luminous quantity, which is the amount of brightness of color. In a compound of the present disclosure or an organic electroluminescent device comprising the compound, the deep red color means that the X value of the CIE 1931 colorimetric system is about 0.68 or more, preferably about 0.69 or more.

Hereinafter, the organic electroluminescent compound represented by formula 1 will be described in more detail.

In formula 1, R₁ represents a substituted or unsubstituted (C2-C6)alkyl, and preferably a (C2-C6)alkyl unsubstituted or substituted with deuterium. The (C2-C6)alkyl may be any one selected from the group consisting of ethyl, n-propyl, isopropyl, n-butyl, isobutyl, sec-butyl, tert-butyl, n-pentyl, tert-pentyl, neopentyl, isopentyl, sec-pentyl and 3-pentyl, and the longer chain may be preferable. According to one embodiment of the present disclosure, R₁ represents a substituted or unsubstituted (C3-C5)alkyl. According to another embodiment of the present disclosure, R₁ represents a substituted or unsubstituted (C4-C5)alkyl.

In formula 1, R₂ and R₃, each independently, represent a substituted or unsubstituted (C1-C5)alkyl, preferably a (C1-C5)alkyl unsubstituted or substituted with deuterium, and more preferably a (C1-C4)alkyl unsubstituted or substituted with deuterium. R₂ and R₃ may be the same or different from each other, and preferably the same. The (C1-C5)alkyl is any one selected from the group consisting of methyl, ethyl, n-propyl, isopropyl, n-butyl, isobutyl, sec-butyl, tert-butyl, n-pentyl, tert-pentyl, neopentyl, isopentyl, sec-pentyl and 3-pentyl. For example, R₂ and R₃, each independently, may represent methyl, ethyl or isobutyl, and R₂ and R₃ may be the same.

In formula 1, R₄ to R₆, each independently, represent hydrogen, deuterium, a substituted or unsubstituted (C1-C5)alkyl, or a substituted or unsubstituted (C5-C30)aryl; or are linked to an adjacent substituent to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom selected from the group consisting of nitrogen, oxygen, and sulfur. Preferably, R₄ to R₆, each independently, represent hydrogen, a substituted or unsubstituted (C1-C5)alkyl, or a substituted or unsubstituted (C5-C25)aryl. The (C1-C5)alkyl is any one selected from the group consisting of methyl, ethyl, n-propyl, isopropyl, n-butyl, isobutyl, sec-butyl, tert-butyl, n-pentyl, tert-pentyl, neopentyl, isopentyl, sec-pentyl and 3-pentyl. More preferably, R₄ and R₆, each independently, represent an unsubstituted (C1-C5)alkyl, or an unsubstituted (C5-C18)aryl. For example, R₄ and R₆, each independently, represent methyl, isopropyl, isobutyl, sec-butyl, sec-pentyl, 3-pentyl or phenyl. R₄ and R₆ may be the same or different from each other. More preferably, R₅ represents hydrogen, an unsubstituted (C1-C5)alkyl, or an unsubstituted (C5-C18)aryl. For example, R₅ represents hydrogen, methyl, or phenyl.

In formula 1,

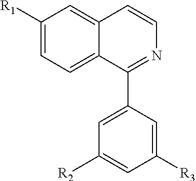

may represent any one selected from the group consisting of the following, but is not limited thereto.

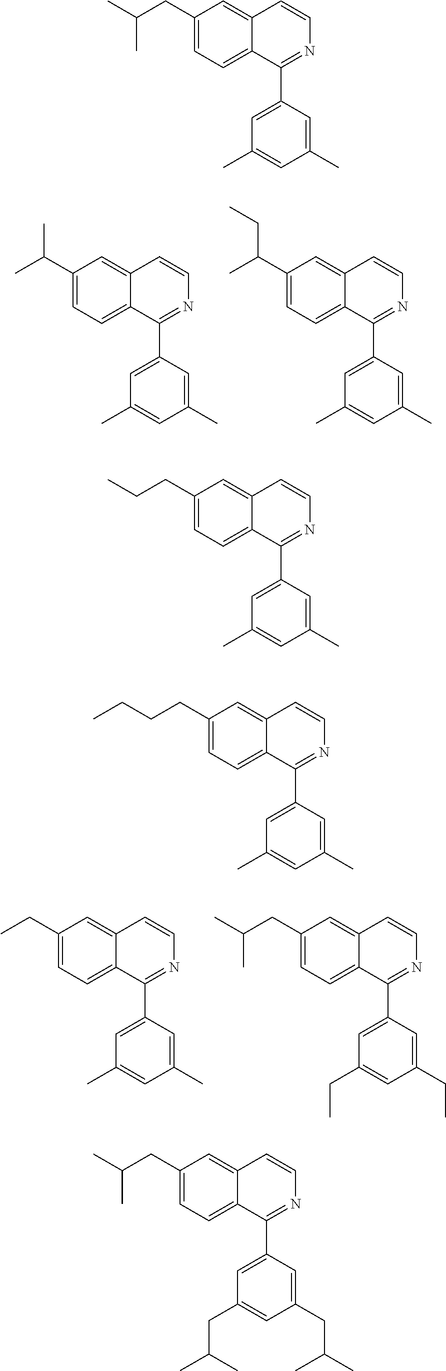

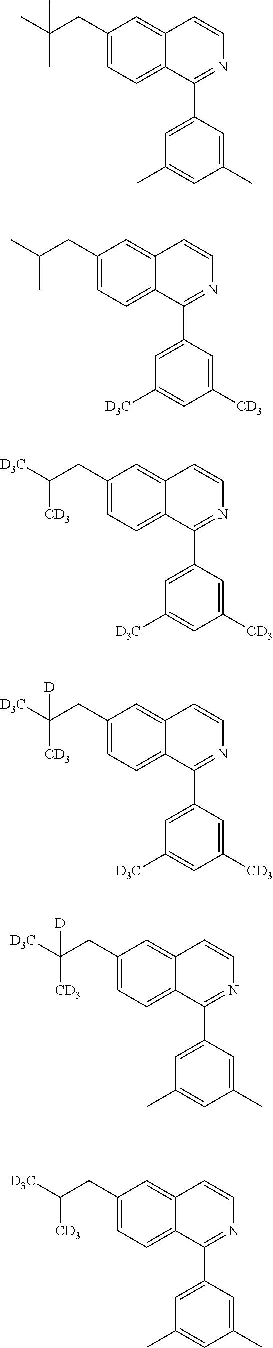

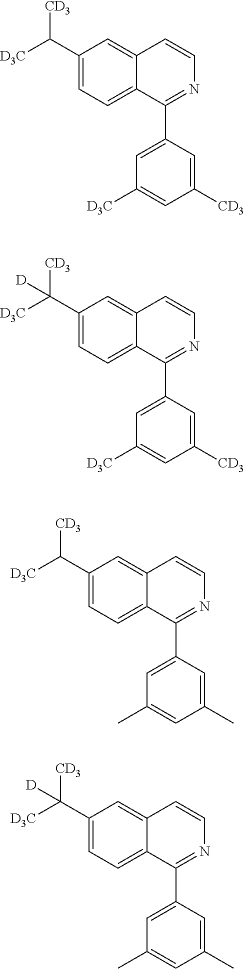 [SMILES: [2H]C([2H])([2H])c1cc(-c2nccc3cc(C(C([2H])([2H])[2H])C([2H])([2H])[2H])ccc23)cc(C([2H])([2H])[2H])c1 ; [2H]C([2H])([2H])c1cc(-c2nccc3cc(C([2H])(C([2H])([2H])[2H])C([2H])([2H])[2H])ccc23)cc(C([2H])([2H])[2H])c1 ; [2H]C([2H])([2H])C(c1ccc2c(-c3cc(C)cc(C)c3)nccc2c1)C([2H])([2H])[2H] ; [2H]C([2H])([2H])C([2H])(c1ccc2c(-c3cc(C)cc(C)c3)nccc2c1)C([2H])([2H])[2H]]

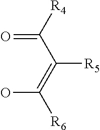

In formula 1, may represent any one selected from the group consisting of the following, but is not limited thereto.

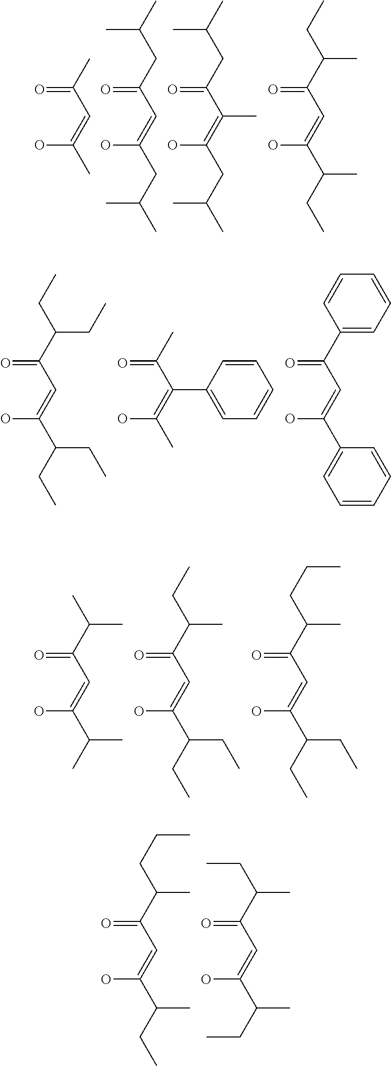

Herein, the term “(C1-C30)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, iso-propyl, n-butyl, iso-butyl, tert-butyl, etc. The term “(C3-C30)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, etc. The term “(3- to 7-membered) heterocycloalkyl” is meant to be a cycloalkyl having 3 to 7, preferably 5 to 7, ring backbone atoms, and including at least one heteroatom selected from the group consisting of B, N, O, S, Si, and P, and preferably the group consisting of 0, S, and N. The above heterocycloalkyl may include tetrahydrofuran, pyrrolidine, thiolan, tetrahydropyran, etc. The term “(C6-C30)aryl(ene)” is meant to be a monocyclic or fused ring radical derived from an aromatic hydrocarbon having 6 to 30 ring backbone carbon atoms, in which the number of the ring backbone carbon atoms is preferably 6 to 25, more preferably 6 to 18. The above aryl(ene) may be partially saturated, and may comprise a spiro structure. The above aryl may include phenyl, biphenyl, terphenyl, naphthyl, binaphthyl, phenylnaphthyl, naphthylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, spirobifluorenyl, etc. The term “(3- to 30-membered)heteroaryl(ene)” is an aryl having 3 to 30 ring backbone atoms, and including at least one, preferably 1 to 4 heteroatoms selected from the group consisting of B, N, O, S, Si, and P. The above heteroaryl(ene) may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, and pyridazinyl, and a fused ring-type heteroaryl such as benzofuranyl, benzothiophenyl, isobenzofuranyl, dibenzofuranyl, dibenzothiophenyl, benzimidazolyl, benzothiazolyl, benzoisothiazolyl, benzoisoxazolyl, benzoxazolyl, isoindolyl, indolyl, benzoindolyl, indazolyl, benzothiadiazolyl, quinolyl, isoquinolyl, cinnolinyl, quinazolinyl, quinoxalinyl, naphthyridinyl, carbazolyl, benzocarbazolyl, dibenzocarbazolyl, phenoxazinyl, phenothiazinyl, phenanthridinyl, benzodioxolyl, and dihydroacridinyl. Furthermore, “halogen” includes F, Cl, Br, and I.

The compound represented by formula 1 includes the following compounds, but is not limited thereto.

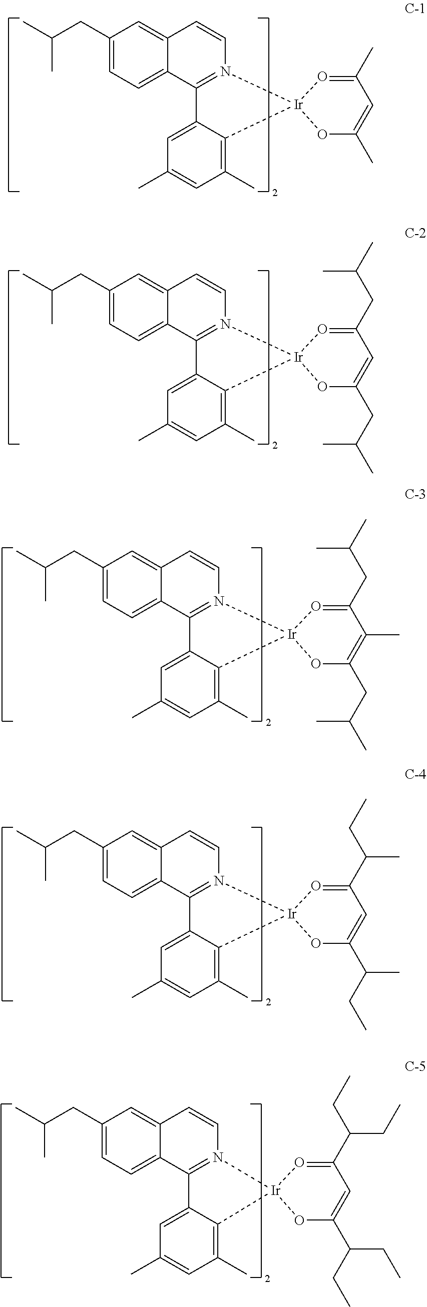

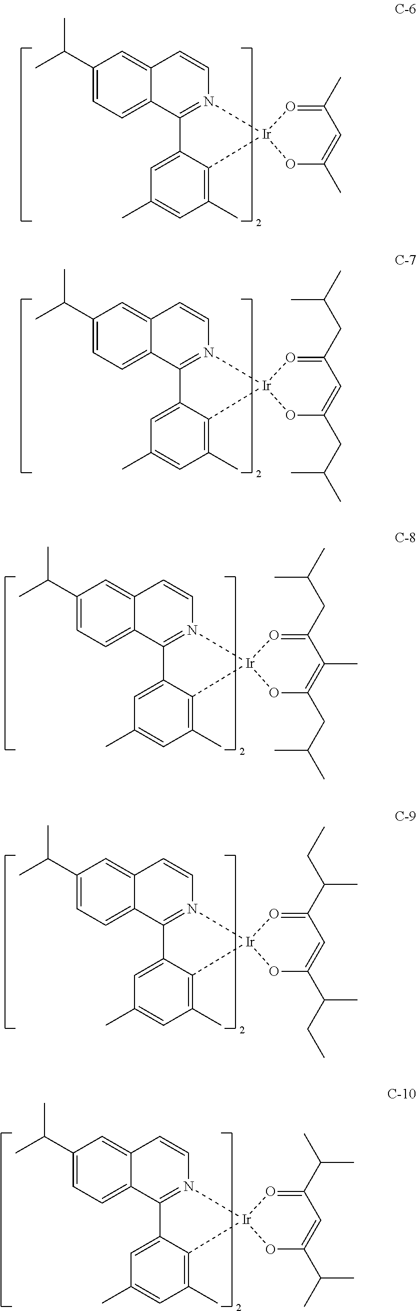

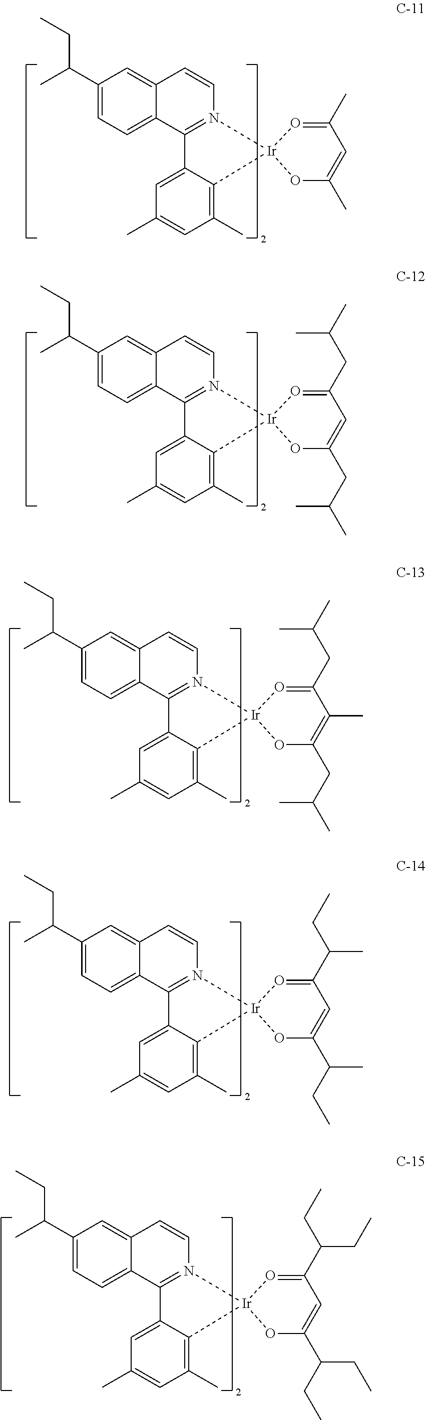

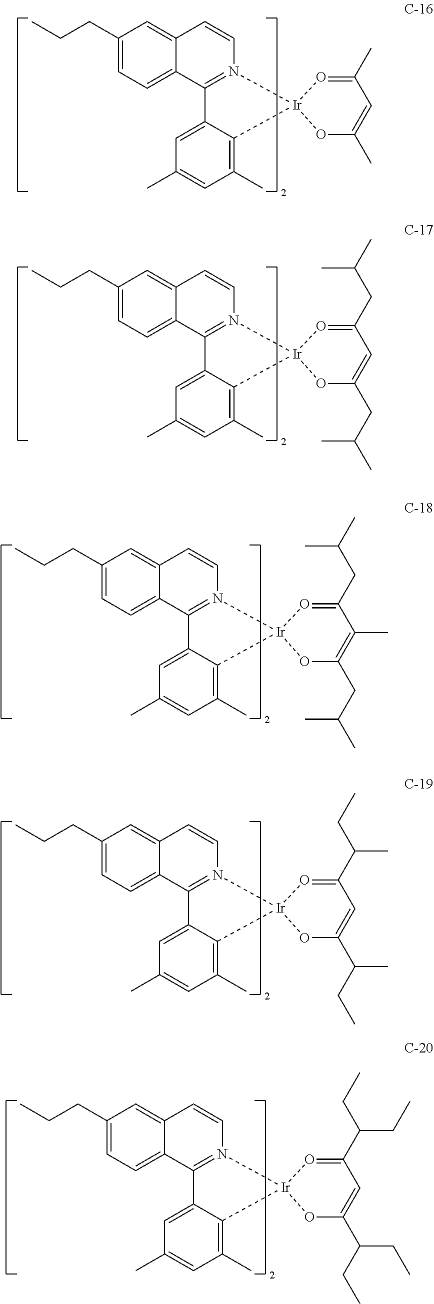

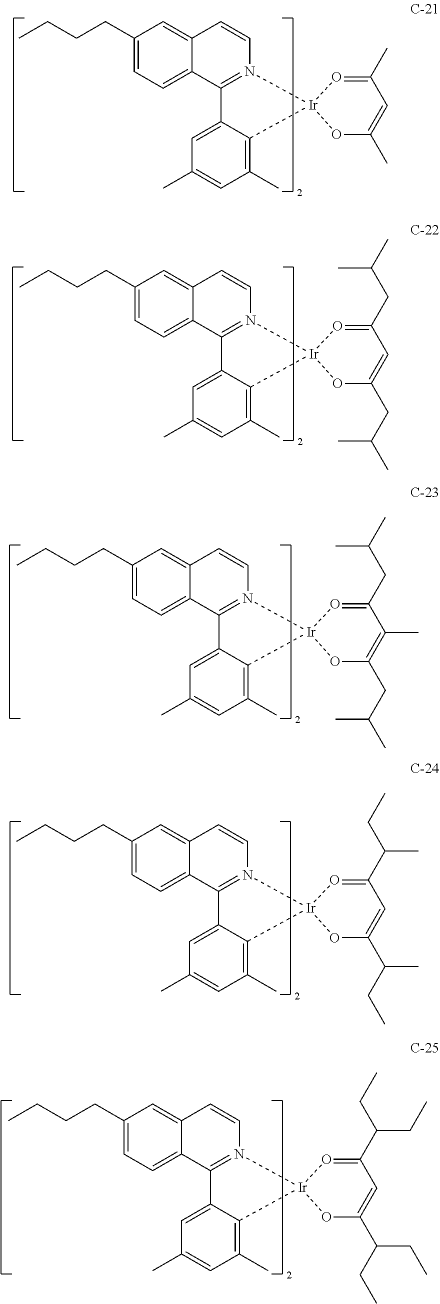

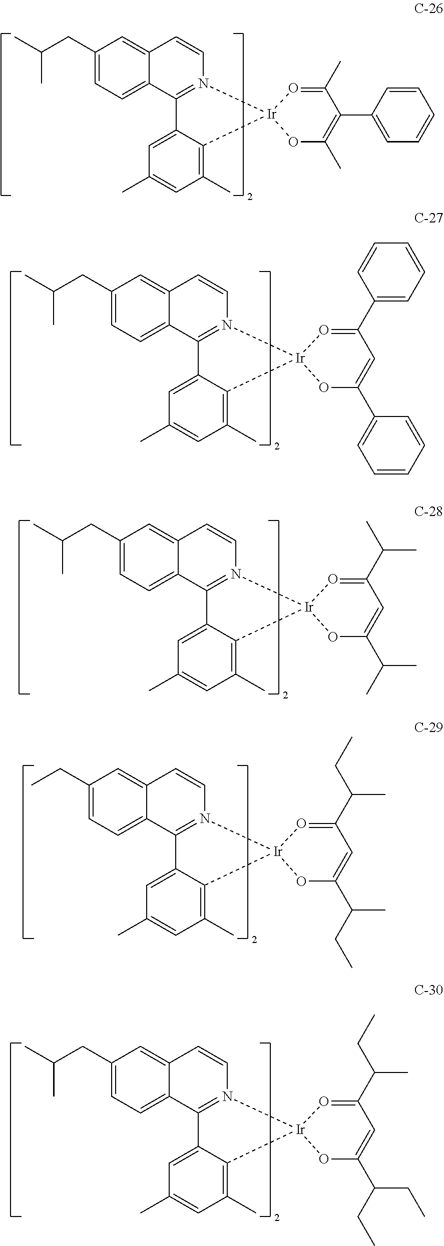

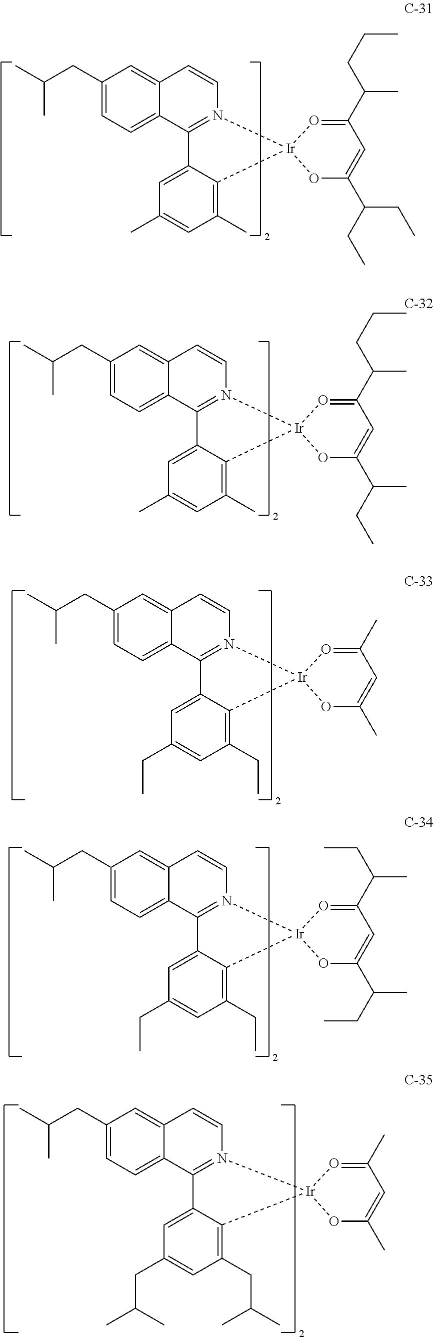

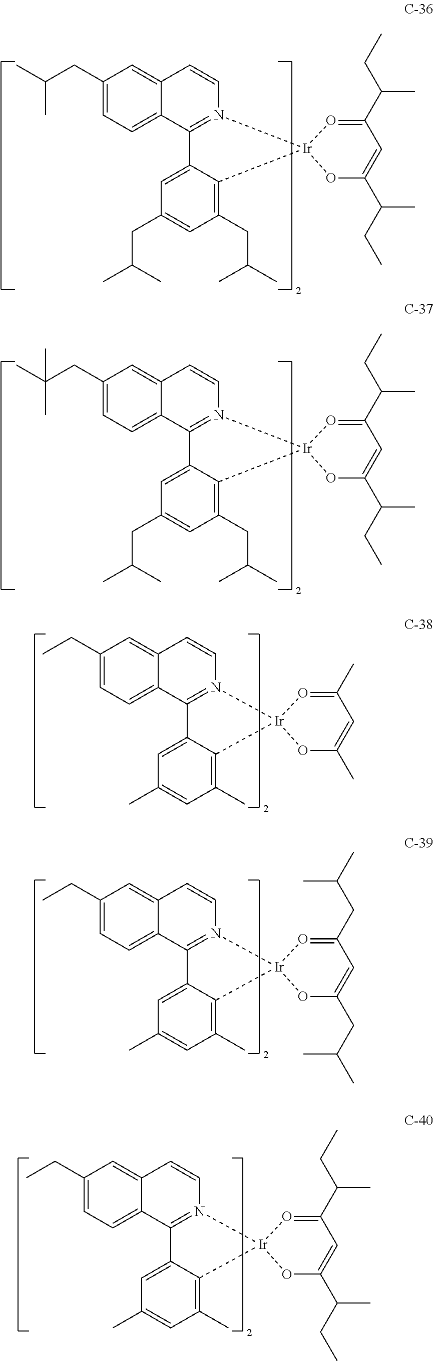

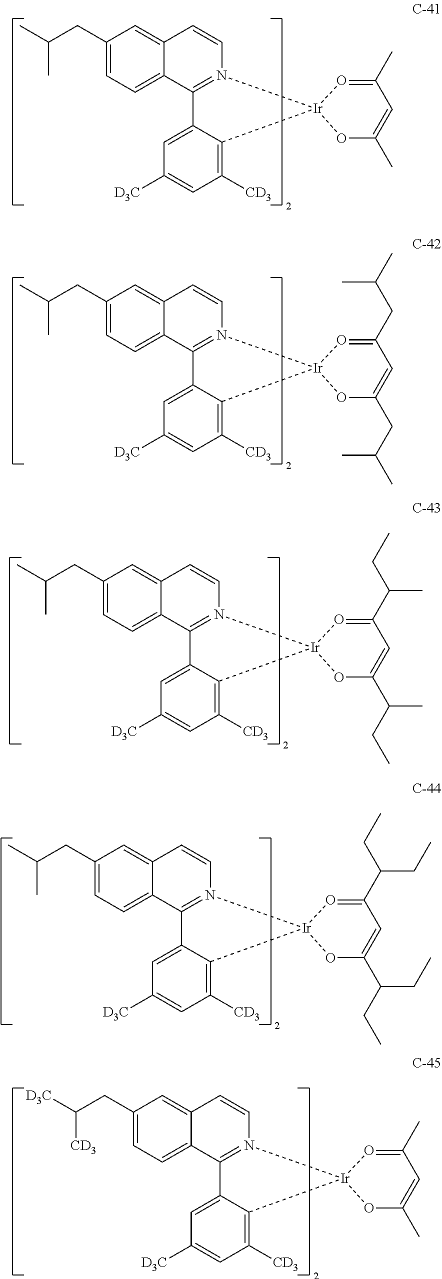

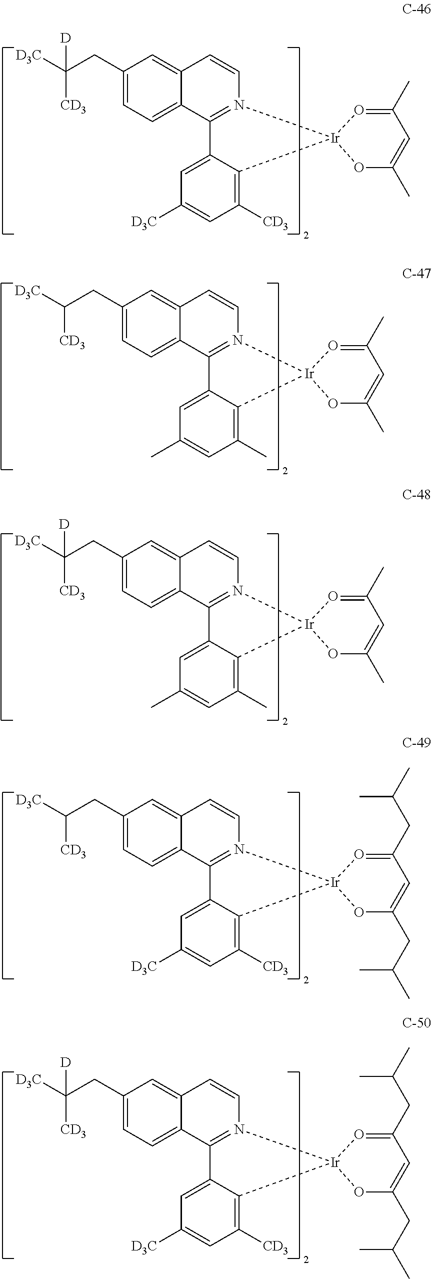

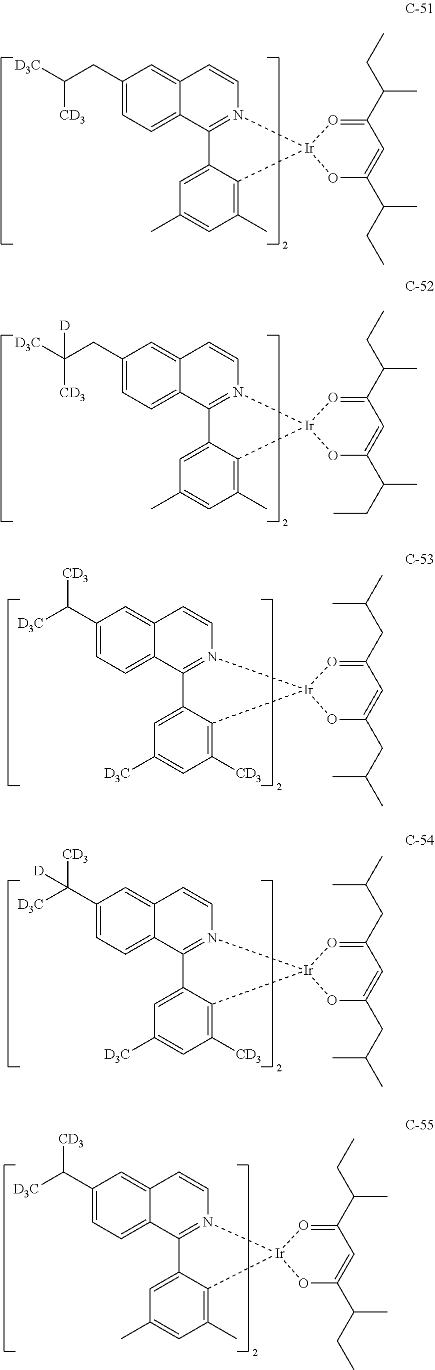

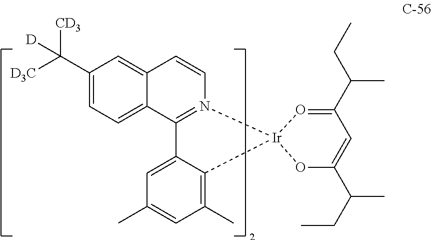

The compound represented by formula 1 of the present disclosure may be produced by a synthetic method known to one skilled in the art. For example, the compound represented by formula 1 may be synthesized as shown in the following reaction scheme 1 or 2, but is not limited thereto.

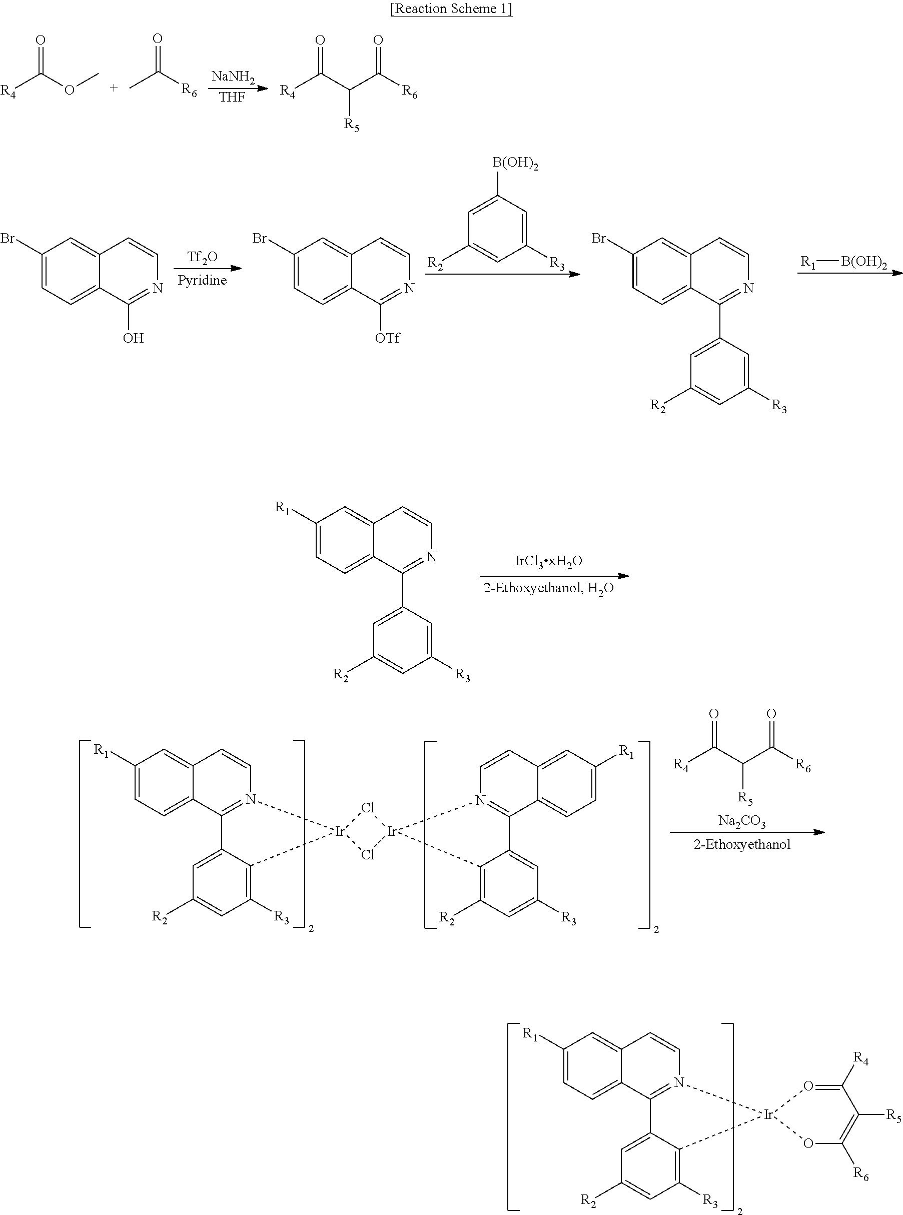

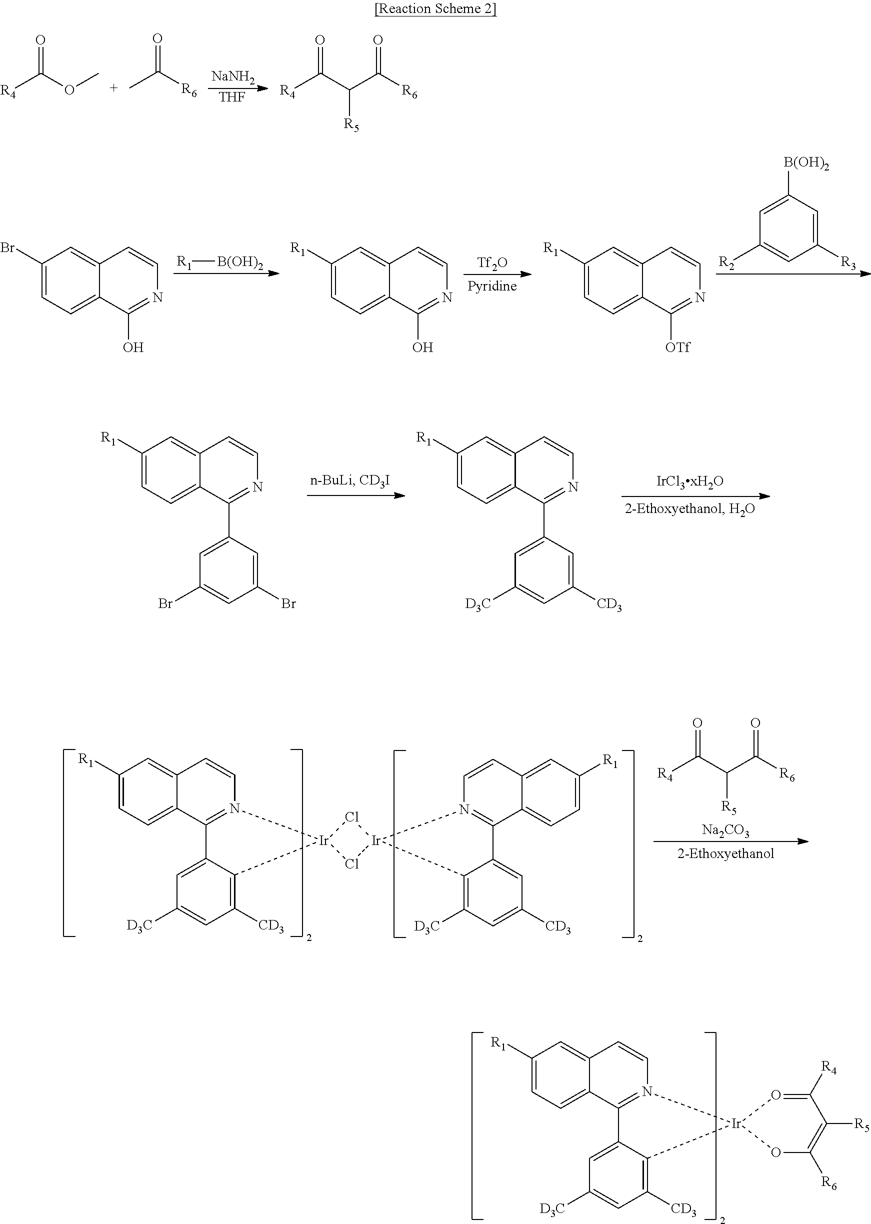

In reaction schemes 1 and 2, R₁ to R₆ are as defined in formula 1. The host compound capable to be used in combination with the compound of the present disclosure may be a compound represented by any one of the following formulas 2 to 4, but is not limited thereto.

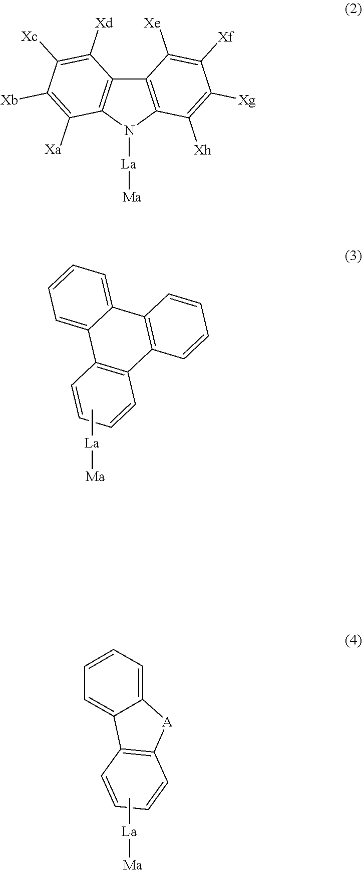

In formulas 2 to 4,

Ma represents a substituted or unsubstituted (C6-C30)aryl, or a substituted or unsubstituted (6- to 30-membered)heteroaryl,

La represents a single bond, a substituted or unsubstituted (C6-C30)arylene, or a substituted or unsubstituted (6- to 30-membered)heteroarylene,

A represents S, O, NRS, or CR₈R₉,

Xa to Xh, each independently, represent hydrogen, deuterium, a halogen, a cyano, a substituted or unsubstituted (C1-C30)alkyl, a substituted or unsubstituted (C2-C30)alkenyl, a substituted or unsubstituted (C2-C30)alkynyl, a substituted or unsubstituted (C3-C30)cycloalkyl, a substituted or unsubstituted (C6-C60)aryl, a substituted or unsubstituted (3- to 30-membered)heteroaryl, a substituted or unsubstituted tri(C1-C30)alkylsilyl, a substituted or unsubstituted tri(C6-C30)arylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted (C1-C30)alkyl(C6-C30)arylamino, or a substituted or unsubstituted mono- or di-(C6-C30)arylamino; or are linked to an adjacent substituent to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom selected from the group consisting of nitrogen, oxygen, and sulfur,

R₇ to R₉, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or R₈ and R₉ are linked to each other to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom selected from the group consisting of nitrogen, oxygen, and sulfur, and the heteroaryl(ene) contains at least one heteroatom selected from the group consisting of B, N, O, S, Si, and P.

In formulas 2 to 4, La preferably represents a single bond, a substituted or unsubstituted (C6-C25)arylene, or a substituted or unsubstituted (6- to 25-membered)heteroarylene; and more preferably represents a single bond, an unsubstituted (C6-C18)arylene, or a (6- to 20-membered)heteroarylene unsubstituted or substituted with phenyl, biphenyl and/or carbazolyl. For example, La may represent a single bond; an unsubstituted phenylene; an unsubstituted naphthylene; an unsubstituted biphenylene; a pyridinylene unsubstituted or substituted with phenyl; a pyrimidinylene unsubstituted or substituted with phenyl, biphenyl and/or carbazolyl; a triazinylene unsubstituted or substituted with phenyl, biphenyl and/or carbazolyl; an unsubstituted quinolinylene; quinazolinylene unsubstituted or substituted with phenyl; an unsubstituted quinoxalinylene; an unsubstituted carbazolylene; an unsubstituted dibenzothiophenylene; an unsubstituted benzofuropyrimidinylene; an unsubstituted benzothienopyrimidinylene; an unsubstituted benzoquinazolinylene; or an unsubstituted N and/or S containing 20-membered heteroarylene.

In formulas 2 to 4, Ma preferably represents a substituted or unsubstituted (C6-C25)aryl, or a substituted or unsubstituted (6- to 25-membered)heteroaryl; and more preferably represents a substituted or unsubstituted (C6-C18)aryl, or a substituted or unsubstituted (6- to 20-membered)heteroaryl. For example, Ma represents a substituted or unsubstituted phenyl, a substituted or unsubstituted naphthylphenyl, an unsubstituted naphthyl, an unsubstituted biphenyl, a fluorenyl substituted with at least one methyl, an unsubstituted terphenyl, an unsubstituted triphenylenyl, a substituted pyrimidinyl, a substituted triazinyl, a substituted quinoxalinyl, a substituted quinazolinyl, a substituted or unsubstituted carbazolyl, an unsubstituted dibenzothiophenyl, a benzofuropyrimidinyl substituted with a phenyl, a benzothienopyrimidinyl substituted with a phenyl, a benzoquinazolinyl substituted with a phenyl, or an indolocarbazolyl substituted with at least one phenyl. The substituent of the substituted phenyl may be at least one selected from the group consisting of a carbazolyl unsubstituted or substituted with a phenyl, a pyrimidinyl substituted with at least one phenyl, a triphenylsilyl, a dibanzothiophenyl, a dimethylfluorenyl and a triphenylenyl; the substituent of the substituted pyrimidinyl may be at least one selected from the group consisting of a phenyl, a biphenyl and a terphenyl; the substituent of the substituted triazinyl may be at least one selected from the group consisting of a phenyl unsubstituted or substituted with a triphenylsilyl, a biphenyl, a naphthyl and a terphenyl; the substituent of the substituted quinoxalinyl may be at least one selected from the group consisting of a phenyl, a naphthyl, a biphenyl, and a naphthylphenyl; the substituent of the substituted quinazolinyl may be at least one selected from the group consisting of a phenyl and a biphenyl; and the substituent of the substituted carbazolyl may be at least one selected from the group consisting of a phenyl unsubstituted or substituted with a diphenyltriazinyl, a biphenyl, a naphthyl, and a terphenyl.

In formula 2, Xa to Xh, each independently, preferably represent hydrogen, a substituted or unsubstituted (C6-C18)aryl, or a substituted or unsubstituted (6- to 20-membered)heteroaryl, or are linked to an adjacent substituent to form a substituted or unsubstituted, mono- or polycyclic, (C6-C20) aromatic ring, wherein the carbon atom(s) of the alicyclic or aromatic ring, or the combination thereof may be replaced with at least one heteroatom selected from the group consisting of nitrogen, oxygen, and sulfur; and more preferably represent hydrogen, a substituted or unsubstituted (C6-C15)aryl, or a (10- to 20-membered)heteroaryl unsubstituted or substituted with a (C6-C18)aryl, or are linked to an adjacent substituent to form a substituted or unsubstituted benzene ring, a substituted or unsubstituted indole ring, a substituted or unsubstituted benzoindole ring, a substituted or unsubstituted indene ring, a substituted or unsubstituted benzofuran ring, or a substituted or unsubstituted benzothiophene ring. For example, Xa to Xh, each independently, represent hydrogen, a substituted or unsubstituted phenyl, an unsubstituted biphenyl, a substituted or unsubstituted carbazolyl, an unsubstituted dibenzofuranyl, or an unsubstituted dibenzothiophenyl; or are linked to an adjacent substituent to form an unsubstituted benzene ring, a substituted indene ring, a substituted indole ring, a substituted or unsubstituted benzothiophene ring, an unsubstituted benzofuran ring, or a substituted benzoindole ring. The substituent of the substituted phenyl may be at least one selected from the group consisting of a carbazolyl unsubstituted or substituted with a phenyl, and a dibenzothiophenyl; the substituent of the substituted carbazolyl may be at least one selected from the group consisting of a phenyl, a biphenyl, a naphthyl and a terphenyl; the substituent of the substituted indene ring may be at least one selected from the group consisting of a methyl and a phenyl; the substituent of the substituted indole ring may be at least one selected from the group consisting of a phenyl, a naphthyl, and a biphenyl; the substituent of the benzothiophene ring may be a triazinyl substituted with at least one phenyl; and the substituent of the substituted benzoindole ring may be at least one selected from the group consisting of a phenyl and a naphthyl.

In formula 4, A preferably represents S or CR₈R₉, wherein R₈ and R₉, each independently, represent hydrogen, a substituted or unsubstituted (C1-C30)alkyl, or a substituted or unsubstituted (C6-C25)aryl, or are linked to each other to form a substituted or unsubstituted, mono- or polycyclic, (C3-C25) alicyclic or aromatic ring, or the combination thereof; preferably represent an unsubstituted (C6-C18)aryl, or are linked to each other to form an unsubstituted, mono- or polycyclic, (C3-C18) alicyclic or aromatic ring, or the combination thereof; and for example, represent a phenyl, or are linked to each other to form a fluorene ring having a spiro structure.

Herein, “substituted” in the expression “substituted or unsubstituted” means that a hydrogen atom in a certain functional group is replaced with another atom or another functional group, i.e. a substituent. The substituents of the substituted alkyl, the substituted alkenyl, the substituted alkynyl, the substituted cycloalkyl, the substituted aryl(ene), the substituted heteroaryl, the substituted trialkylsilyl, the substituted triarylsilyl, the substituted dialkylarylsilyl, the substituted alkyldiarylsilyl, the substituted alkylarylamino, the substituted monoarylamino, the substituted diarylamino, or the substituted mono- or polycyclic, alicyclic or aromatic ring, or the combination thereof in R₁ to R₉, Ma, La, and Xa to Xh of formulas 1 to 4, each independently, may be at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with a tri(C6-C30)arylsilyl, a (C6-C30)aryl, a (C1-C30)alkyl(C6-C30)aryl, and/or a tri(C6-C30)arylsilyl; a (C6-C30)aryl unsubstituted or substituted with a (C1-C30)alkyl, a halogen, a cyano, a tri(C6-C30)arylsilyl, and/or a (3- to 30-membered)heteroaryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl; preferably, at least one selected from the group consisting of (C1-C20)alkyl; a (5- to 25-membered)heteroaryl unsubstituted or substituted with a (C6-C25)aryl; a (C6-C25)aryl unsubstituted or substituted with a (C1-C20)alkyl, (5- to 18-membered)heteroaryl, and/or tri(C6-C25)arylsilyl; a tri(C6-C25)arylsilyl; and a (C1-C20)alkyl(C6-C25)aryl; more preferably, at least one selected from the group consisting of an unsubstituted (C1-C10)alkyl; a (5- to 18-membered)heteroaryl unsubstituted or substituted with a (C6-C12)aryl; a (C6-C18)aryl unsubstituted or substituted with a (C1-C10)alkyl, a (5- to 18-membered)heteroaryl, and/or a tri(C6-C18)arylsilyl; a tri(C6-C18)arylsilyl; and a (C1-C10)alkyl(C6-C18)aryl; and for example, at least one selected from the group consisting of an unsubstituted methyl; a phenyl unsubstituted or substituted with a diphenyltriazinyl and/or a triphenylsilyl; an unsubstituted naphthyl; an unsubstituted biphenyl; a fluorenyl substituted with at least one methyl; an unsubstituted naphthylphenyl; an unsubstituted triphenylenyl; an unsubstituted terphenyl; a pyrimidinyl substituted with at least one phenyl; a triazinyl substituted with at least one phenyl; a carbazolyl unsubstituted or substituted with a phenyl; an unsubstituted dibenzothiophenyl; and an unsubstituted triphenylsilyl.

The compound represented by any one of formulas 2 to 4 includes the following compounds, but is not limited thereto.

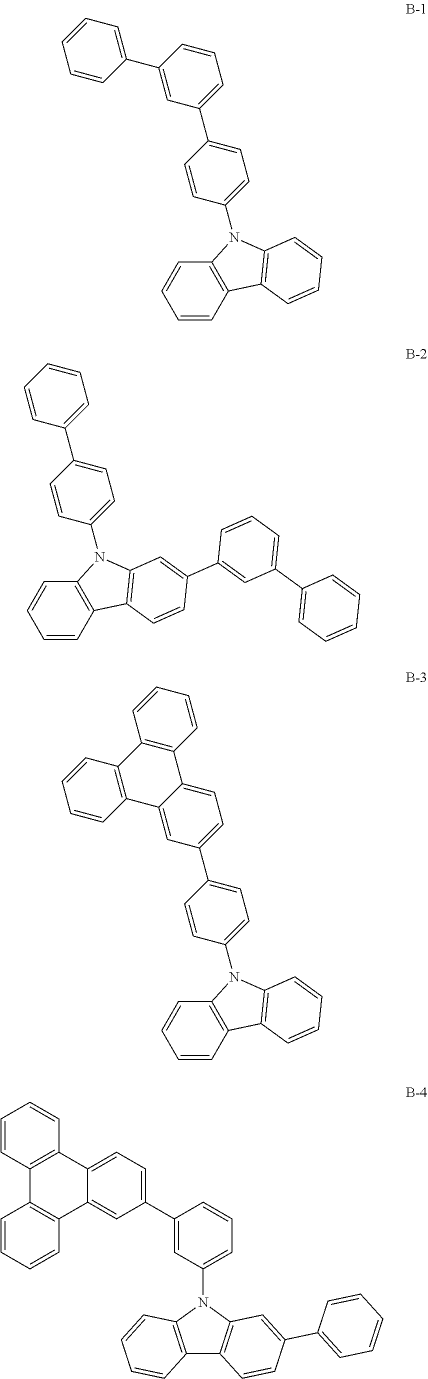 [SMILES: c1ccc(-c2cccc(-c3ccc(-n4c5ccccc5c5ccccc54)cc3)c2)cc1 ; c1ccc(-c2ccc(-n3c4ccccc4c4ccc(-c5cccc(-c6ccccc6)c5)cc43)cc2)cc1 ; c1ccc2c(c1)c1ccccc1c1cc(-c3ccc(-n4c5ccccc5c5ccccc54)cc3)ccc21 ; c1ccc(-c2ccc3c4ccccc4n(-c4cccc(-c5ccc6c7ccccc7c7ccccc7c6c5)c4)c3c2)cc1]

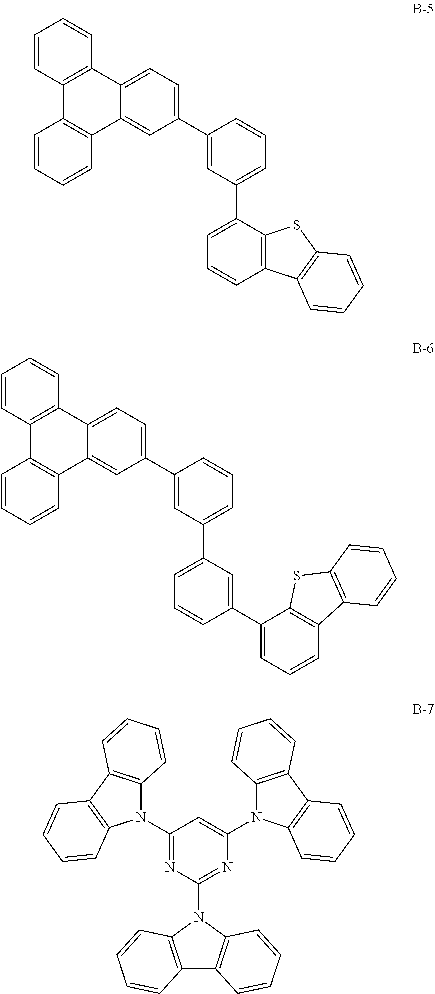 [SMILES: c1cc(-c2ccc3c4ccccc4c4ccccc4c3c2)cc(-c2cccc3c2sc2ccccc23)c1 ; c1cc(-c2cccc(-c3cccc4c3sc3ccccc34)c2)cc(-c2ccc3c4ccccc4c4ccccc4c3c2)c1 ; c1ccc2c(c1)c1ccccc1n2-c1cc(-n2c3ccccc3c3ccccc32)nc(-n2c3ccccc3c3ccccc32)n1]

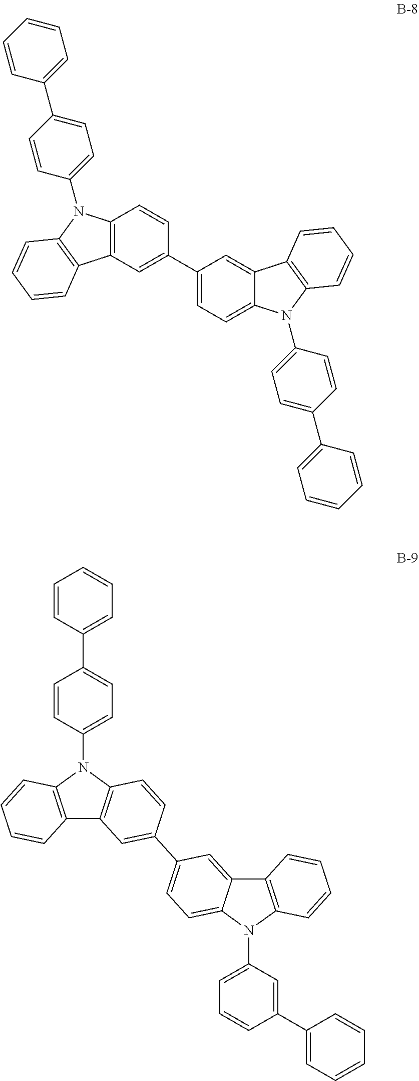 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

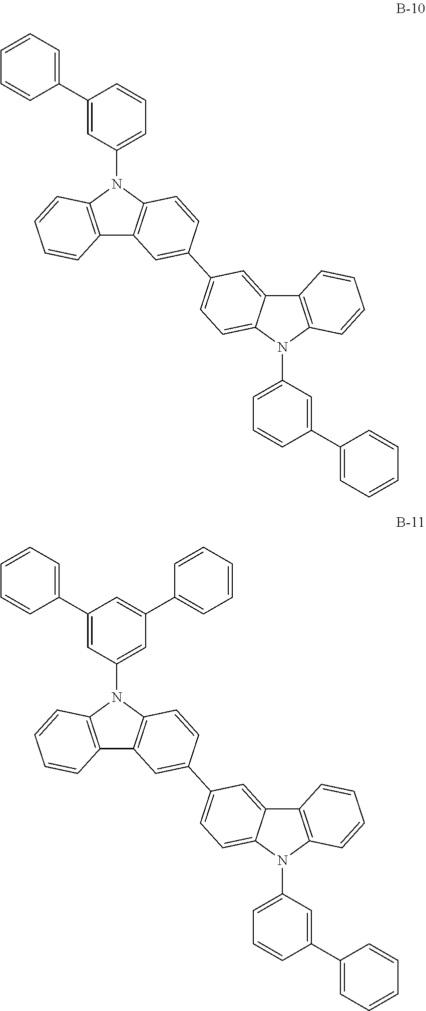 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1]

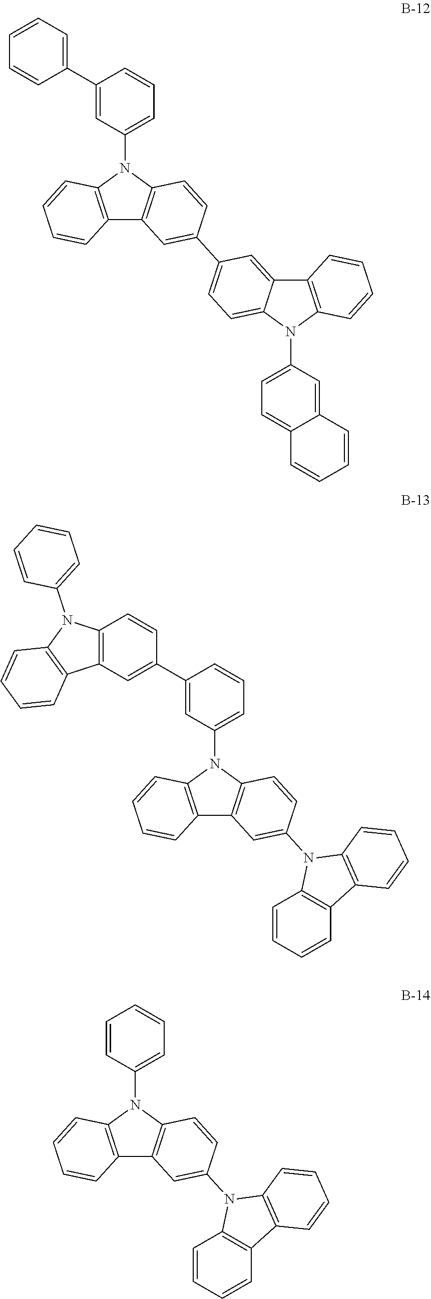 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-n2c3ccccc3c3cc(-c4cccc(-n5c6ccccc6c6cc(-n7c8ccccc8c8ccccc87)ccc65)c4)ccc32)cc1 ; c1ccc(-n2c3ccccc3c3cc(-n4c5ccccc5c5ccccc54)ccc32)cc1]

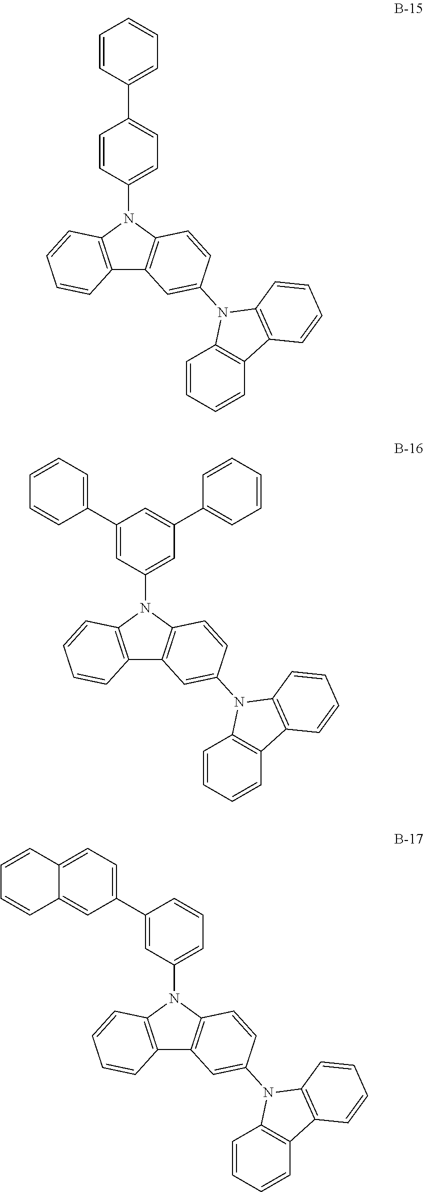 [SMILES: c1ccc(-c2ccc(-n3c4ccccc4c4cc(-n5c6ccccc6c6ccccc65)ccc43)cc2)cc1 ; c1ccc(-c2cc(-c3ccccc3)cc(-n3c4ccccc4c4cc(-n5c6ccccc6c6ccccc65)ccc43)c2)cc1 ; c1cc(-c2ccc3ccccc3c2)cc(-n2c3ccccc3c3cc(-n4c5ccccc5c5ccccc54)ccc32)c1]

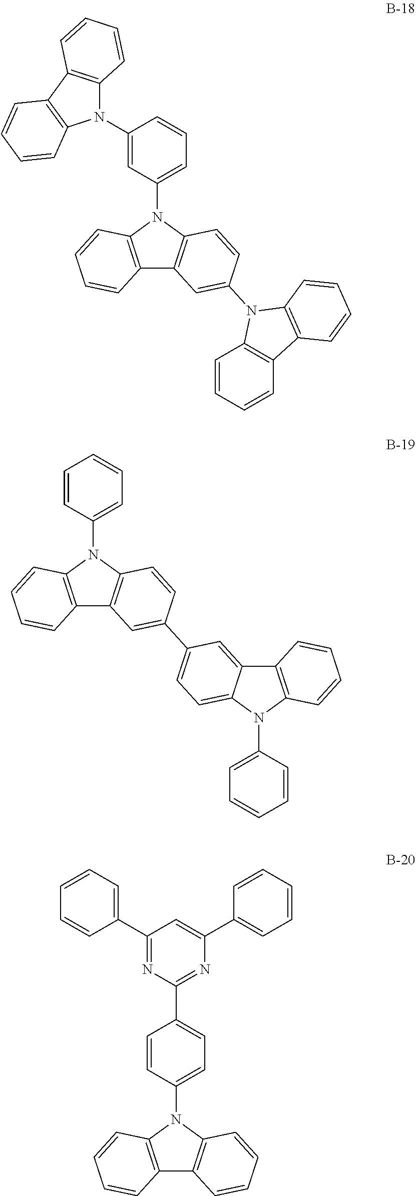 [SMILES: c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-c4ccc5c(c4)c4ccccc4n5-c4ccccc4)ccc32)cc1 ; c1ccc(-c2cc(-c3ccccc3)nc(-c3ccc(-n4c5ccccc5c5ccccc54)cc3)n2)cc1]

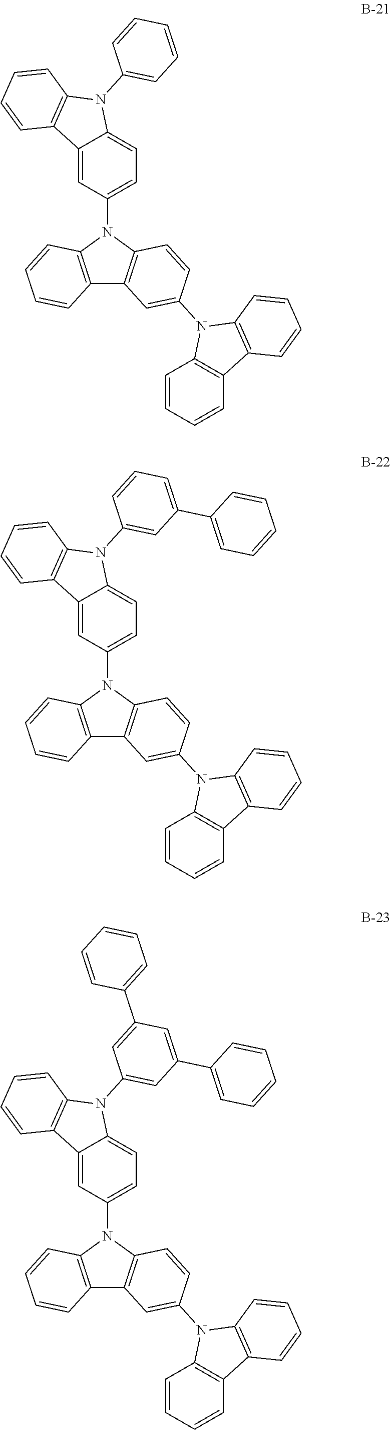 [SMILES: c1ccc(-n2c3ccccc3c3cc(-n4c5ccccc5c5cc(-n6c7ccccc7c7ccccc76)ccc54)ccc32)cc1 ; c1ccc(-c2cccc(-n3c4ccccc4c4cc(-n5c6ccccc6c6cc(-n7c8ccccc8c8ccccc87)ccc65)ccc43)c2)cc1 ; c1ccc(-c2cc(-c3ccccc3)cc(-n3c4ccccc4c4cc(-n5c6ccccc6c6cc(-n7c8ccccc8c8ccccc87)ccc65)ccc43)c2)cc1]

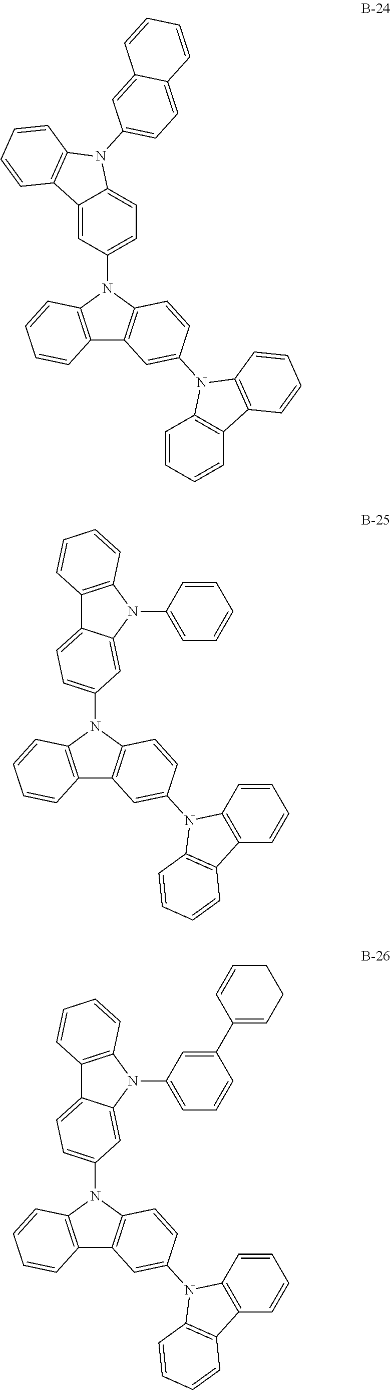 [SMILES: c1ccc2cc(-n3c4ccccc4c4cc(-n5c6ccccc6c6cc(-n7c8ccccc8c8ccccc87)ccc65)ccc43)ccc2c1 ; c1ccc(-n2c3ccccc3c3ccc(-n4c5ccccc5c5cc(-n6c7ccccc7c7ccccc76)ccc54)cc32)cc1 ; C1=CC(c2cccc(-n3c4ccccc4c4ccc(-n5c6ccccc6c6cc(-n7c8ccccc8c8ccccc87)ccc65)cc43)c2)=CCC1]

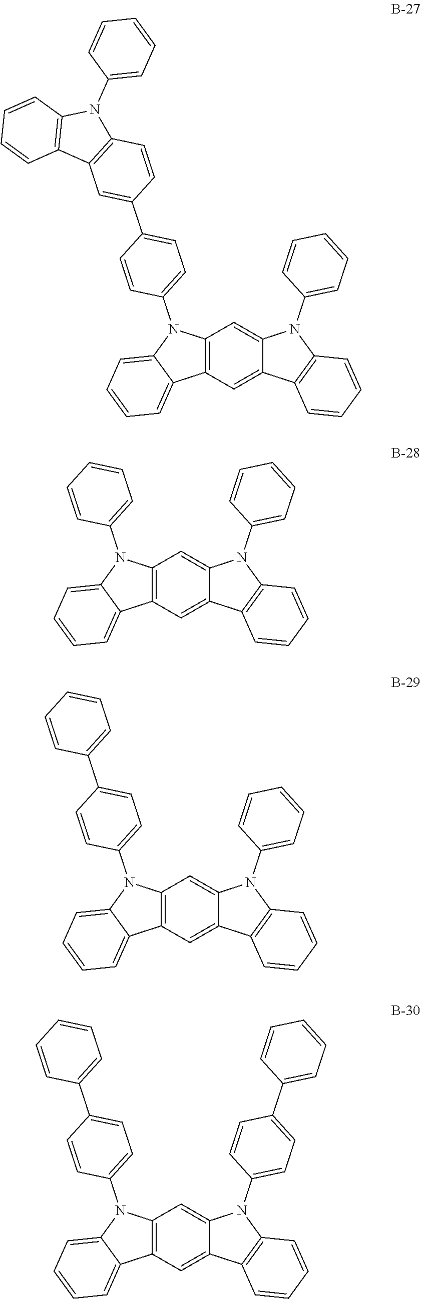 [SMILES: c1ccc(-n2c3ccccc3c3cc(-c4ccc(-n5c6ccccc6c6cc7c8ccccc8n(-c8ccccc8)c7cc65)cc4)ccc32)cc1 ; c1ccc(-n2c3ccccc3c3cc4c5ccccc5n(-c5ccccc5)c4cc32)cc1 ; c1ccc(-c2ccc(-n3c4ccccc4c4cc5c6ccccc6n(-c6ccccc6)c5cc43)cc2)cc1 ; c1ccc(-c2ccc(-n3c4ccccc4c4cc5c6ccccc6n(-c6ccc(-c7ccccc7)cc6)c5cc43)cc2)cc1]

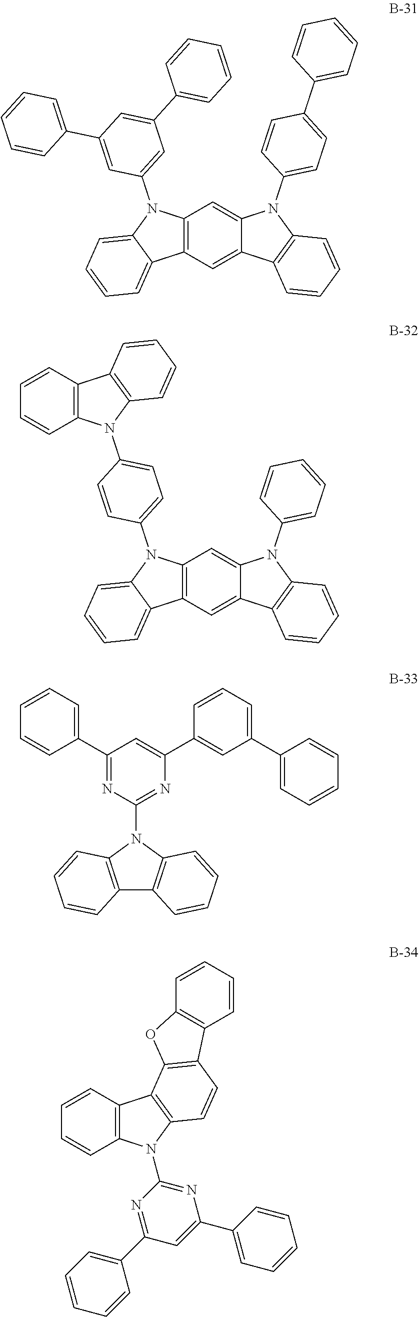 [SMILES: c1ccc(-c2ccc(-n3c4ccccc4c4cc5c6ccccc6n(-c6cc(-c7ccccc7)cc(-c7ccccc7)c6)c5cc43)cc2)cc1 ; c1ccc(-n2c3ccccc3c3cc4c5ccccc5n(-c5ccc(-n6c7ccccc7c7ccccc76)cc5)c4cc32)cc1 ; c1ccc(-c2cccc(-c3cc(-c4ccccc4)nc(-n4c5ccccc5c5ccccc54)n3)c2)cc1 ; c1ccc(-c2cc(-c3ccccc3)nc(-n3c4ccccc4c4c5oc6ccccc6c5ccc43)n2)cc1]

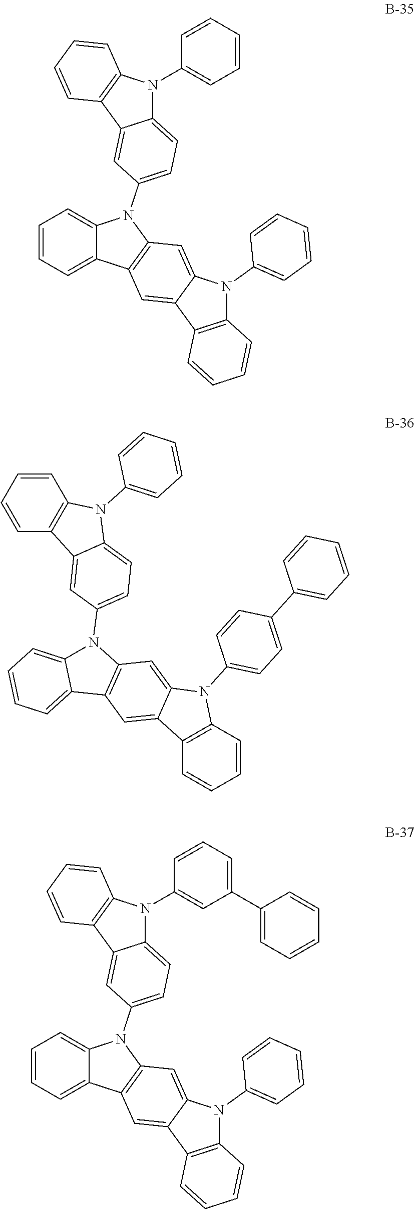 [SMILES: c1ccc(-n2c3ccccc3c3cc(-n4c5ccccc5c5cc6c7ccccc7n(-c7ccccc7)c6cc54)ccc32)cc1 ; c1ccc(-c2ccc(-n3c4ccccc4c4cc5c6ccccc6n(-c6ccc7c(c6)c6ccccc6n7-c6ccccc6)c5cc43)cc2)cc1 ; c1ccc(-c2cccc(-n3c4ccccc4c4cc(-n5c6ccccc6c6cc7c8ccccc8n(-c8ccccc8)c7cc65)ccc43)c2)cc1]

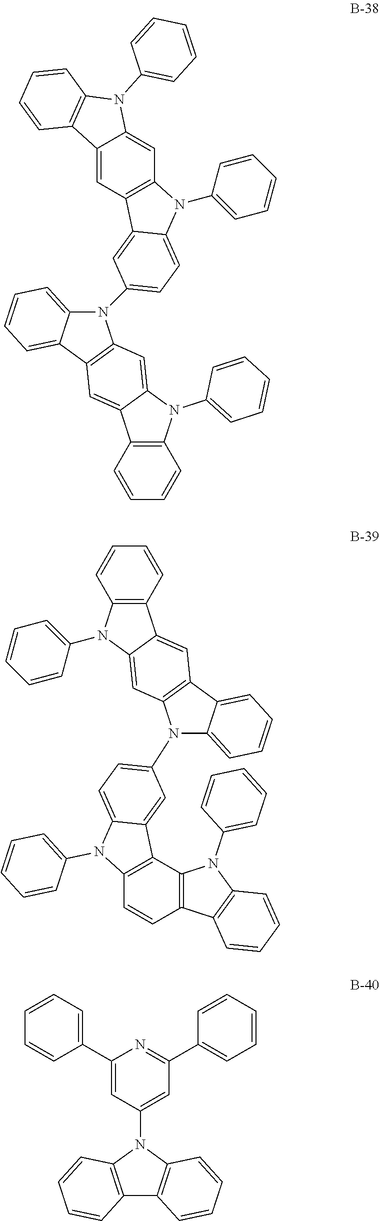

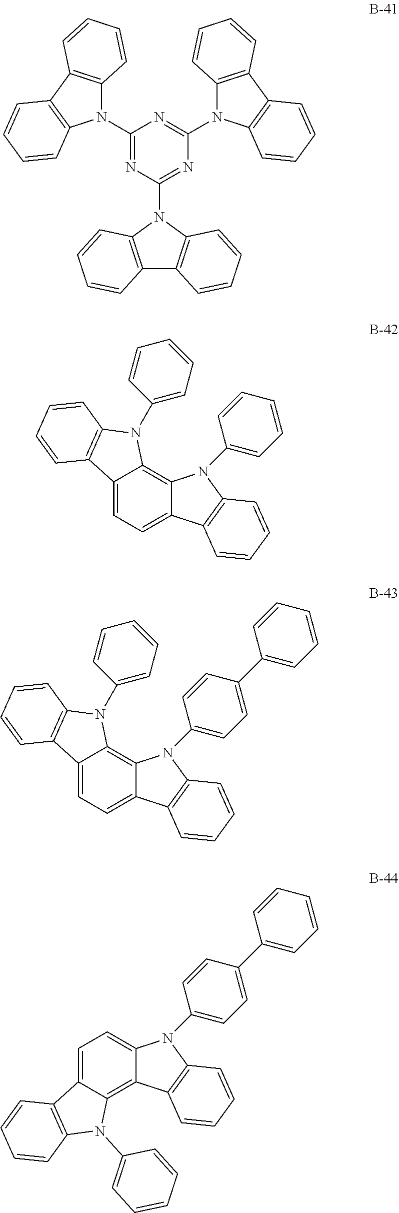 [SMILES: c1ccc2c(c1)c1ccccc1n2-c1nc(-n2c3ccccc3c3ccccc32)nc(-n2c3ccccc3c3ccccc32)n1 ; c1ccc(-n2c3ccccc3c3ccc4c5ccccc5n(-c5ccccc5)c4c32)cc1 ; c1ccc(-c2ccc(-n3c4ccccc4c4ccc5c6ccccc6n(-c6ccccc6)c5c43)cc2)cc1 ; c1ccc(-c2ccc(-n3c4ccccc4c4c3ccc3c5ccccc5n(-c5ccccc5)c34)cc2)cc1]

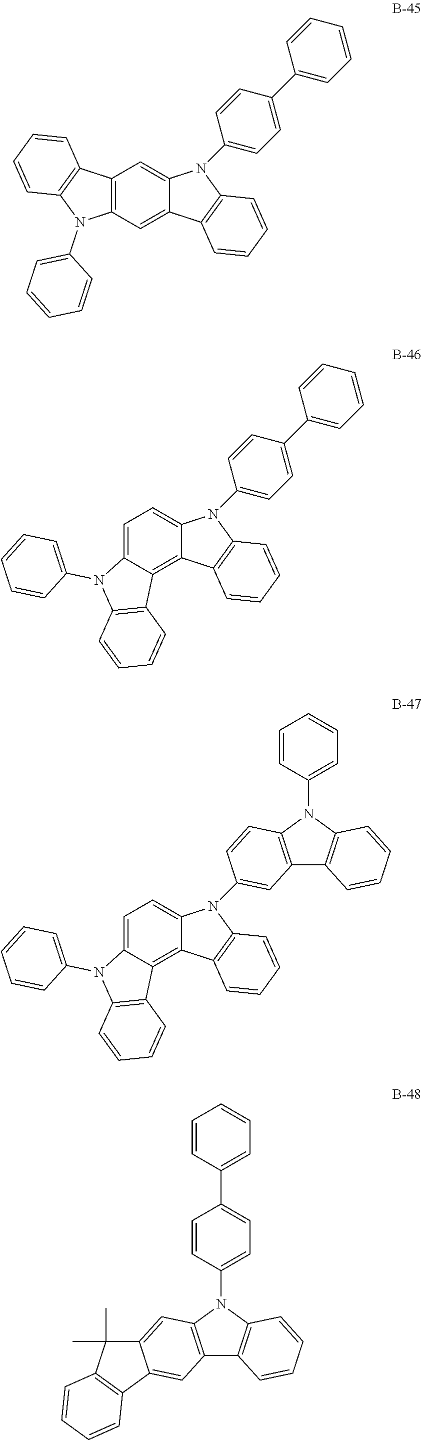 [SMILES: c1ccc(-c2ccc(-n3c4ccccc4c4cc5c(cc43)c3ccccc3n5-c3ccccc3)cc2)cc1 ; c1ccc(-c2ccc(-n3c4ccccc4c4c5c6ccccc6n(-c6ccccc6)c5ccc43)cc2)cc1 ; c1ccc(-n2c3ccccc3c3cc(-n4c5ccccc5c5c6c7ccccc7n(-c7ccccc7)c6ccc54)ccc32)cc1 ; CC1(C)c2ccccc2-c2cc3c4ccccc4n(-c4ccc(-c5ccccc5)cc4)c3cc21]

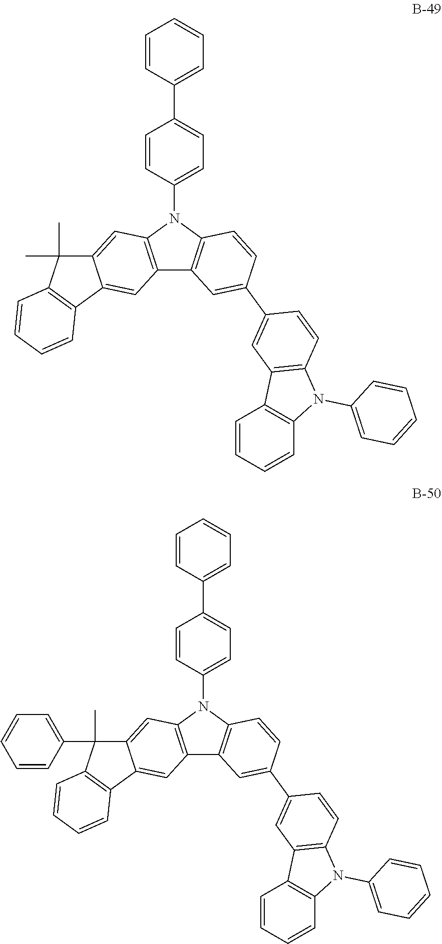 [SMILES: CC1(C)c2ccccc2-c2cc3c4cc(-c5ccc6c(c5)c5ccccc5n6-c5ccccc5)ccc4n(-c4ccc(-c5ccccc5)cc4)c3cc21 ; CC1(c2ccccc2)c2ccccc2-c2cc3c4cc(-c5ccc6c(c5)c5ccccc5n6-c5ccccc5)ccc4n(-c4ccc(-c5ccccc5)cc4)c3cc21]

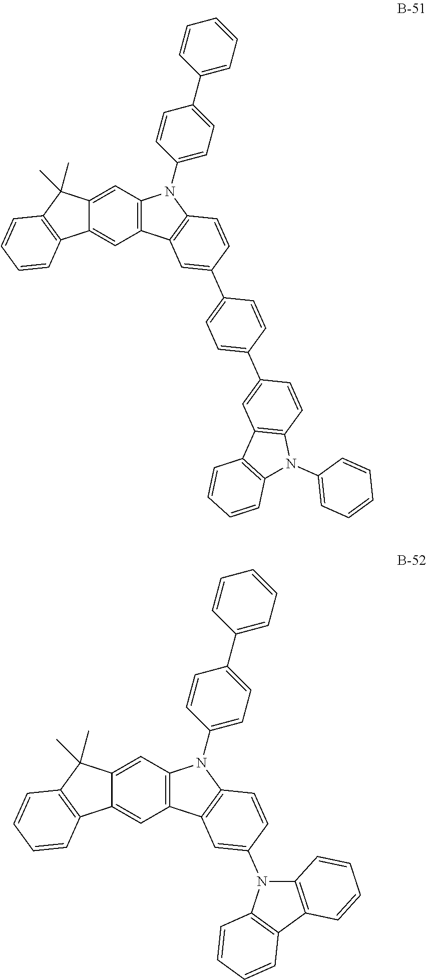 [SMILES: CC1(C)c2ccccc2-c2cc3c4cc(-c5ccc(-c6ccc7c(c6)c6ccccc6n7-c6ccccc6)cc5)ccc4n(-c4ccc(-c5ccccc5)cc4)c3cc21 ; CC1(C)c2ccccc2-c2cc3c4cc(-n5c6ccccc6c6ccccc65)ccc4n(-c4ccc(-c5ccccc5)cc4)c3cc21]

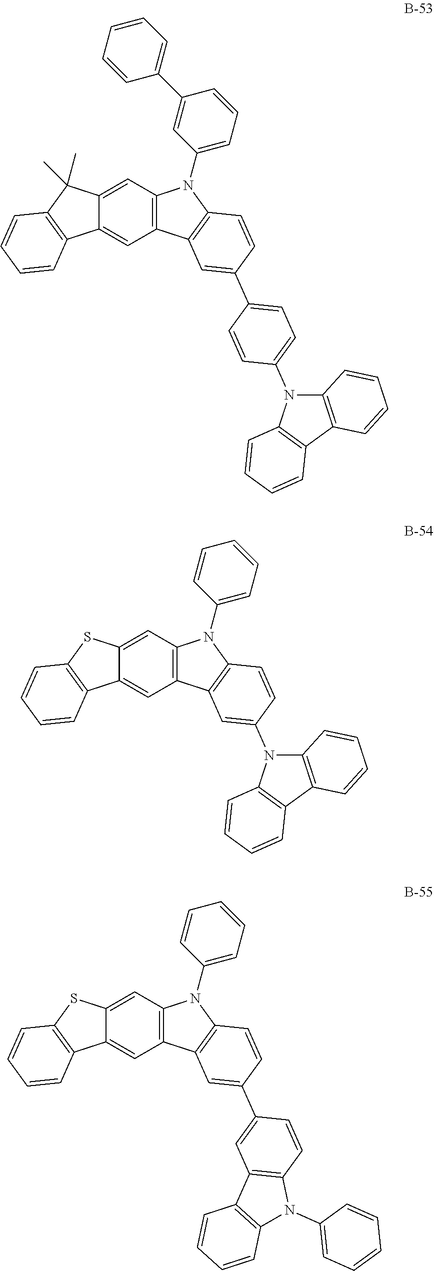 [SMILES: CC1(C)c2ccccc2-c2cc3c4cc(-c5ccc(-n6c7ccccc7c7ccccc76)cc5)ccc4n(-c4cccc(-c5ccccc5)c4)c3cc21 ; c1ccc(-n2c3ccc(-n4c5ccccc5c5ccccc54)cc3c3cc4c(cc32)sc2ccccc24)cc1 ; c1ccc(-n2c3ccccc3c3cc(-c4ccc5c(c4)c4cc6c(cc4n5-c4ccccc4)sc4ccccc46)ccc32)cc1]

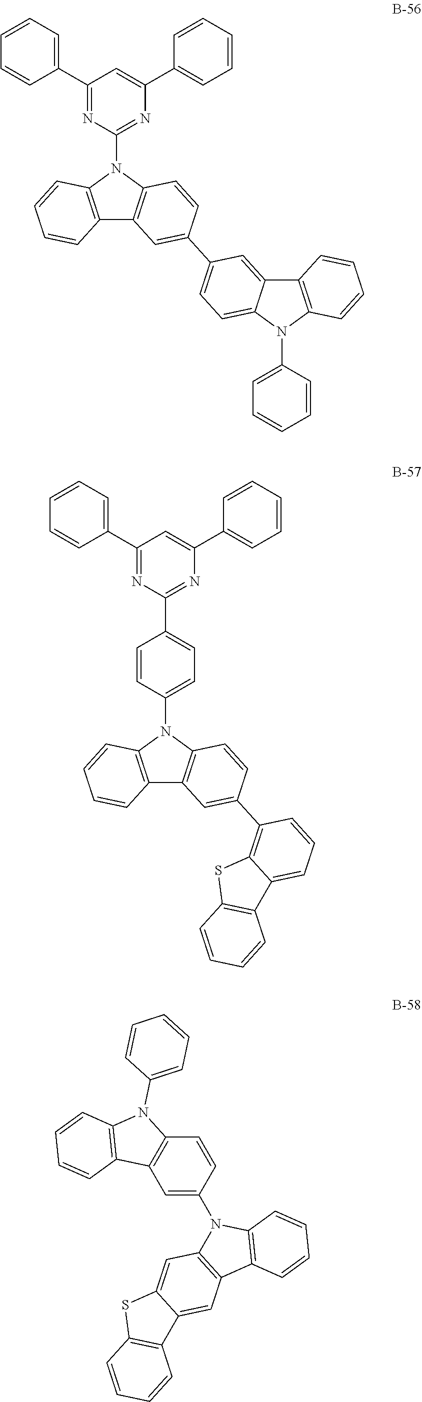 [SMILES: c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2cc(-c3ccccc3)nc(-c3ccc(-n4c5ccccc5c5cc(-c6cccc7c6sc6ccccc67)ccc54)cc3)n2)cc1 ; c1ccc(-n2c3ccccc3c3cc(-n4c5ccccc5c5cc6c(cc54)sc4ccccc46)ccc32)cc1]

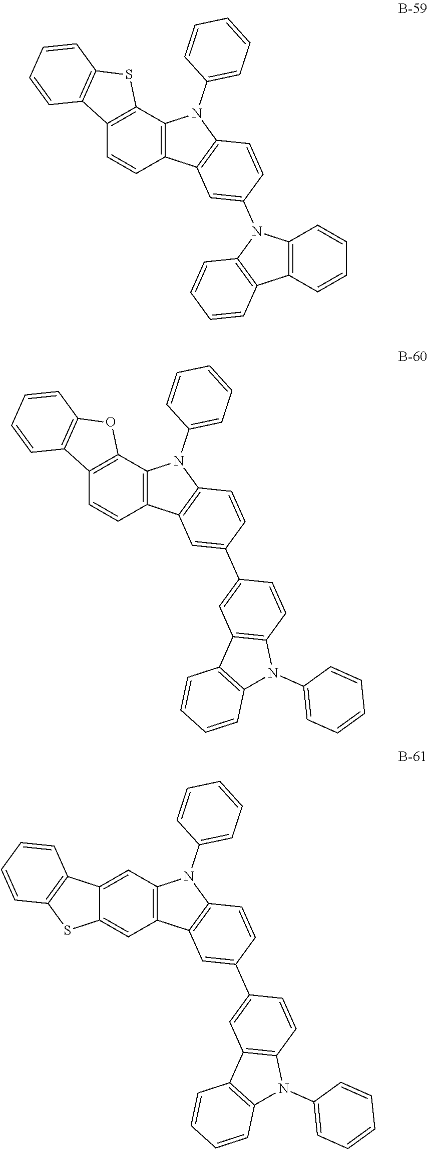

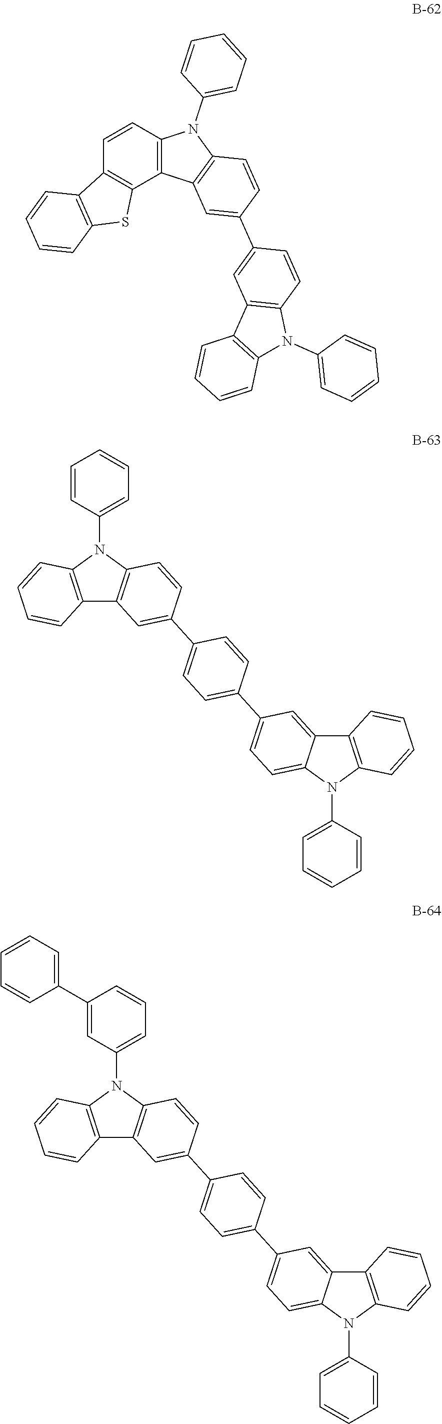 [SMILES: c1ccc(-n2c3ccccc3c3cc(-c4ccc5c(c4)c4c6sc7ccccc7c6ccc4n5-c4ccccc4)ccc32)cc1 ; c1ccc(-n2c3ccccc3c3cc(-c4ccc(-c5ccc6c(c5)c5ccccc5n6-c5ccccc5)cc4)ccc32)cc1 ; c1ccc(-c2cccc(-n3c4ccccc4c4cc(-c5ccc(-c6ccc7c(c6)c6ccccc6n7-c6ccccc6)cc5)ccc43)c2)cc1]

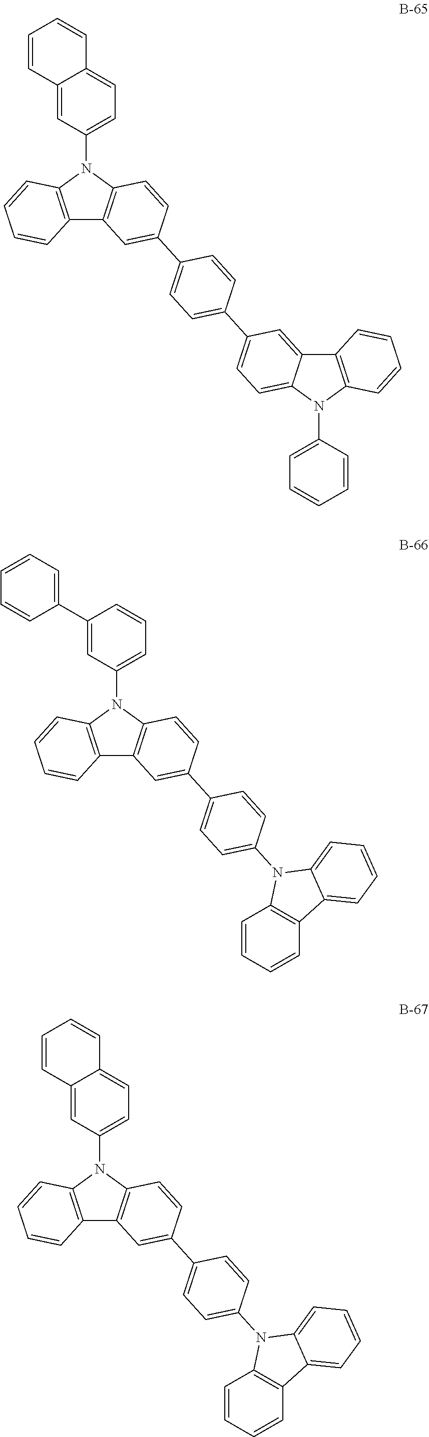 [SMILES: c1ccc(-n2c3ccccc3c3cc(-c4ccc(-c5ccc6c(c5)c5ccccc5n6-c5ccc6ccccc6c5)cc4)ccc32)cc1 ; c1ccc(-c2cccc(-n3c4ccccc4c4cc(-c5ccc(-n6c7ccccc7c7ccccc76)cc5)ccc43)c2)cc1 ; c1ccc2cc(-n3c4ccccc4c4cc(-c5ccc(-n6c7ccccc7c7ccccc76)cc5)ccc43)ccc2c1]

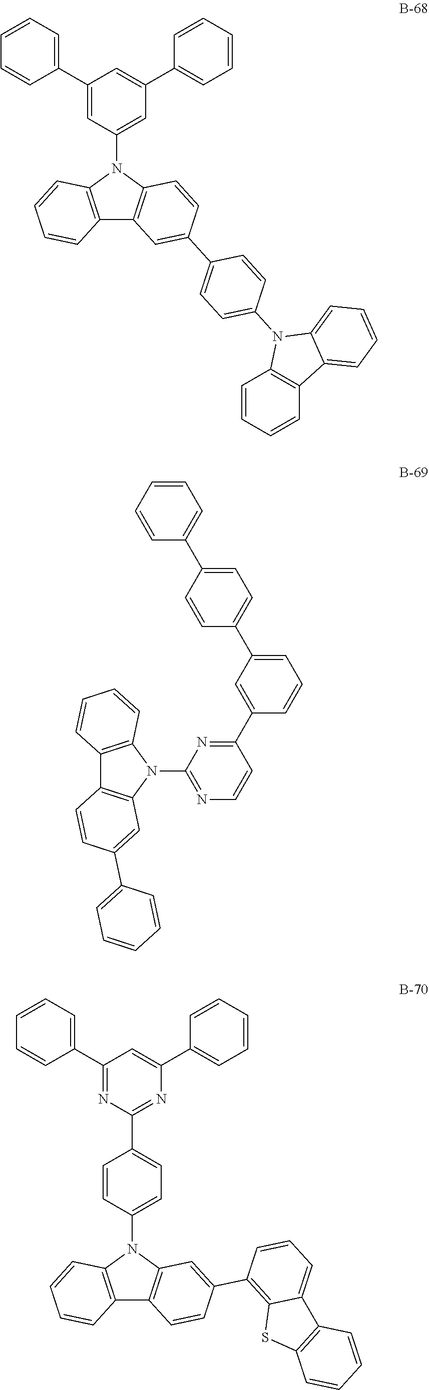 [SMILES: c1ccc(-c2cc(-c3ccccc3)cc(-n3c4ccccc4c4cc(-c5ccc(-n6c7ccccc7c7ccccc76)cc5)ccc43)c2)cc1 ; c1ccc(-c2ccc(-c3cccc(-c4ccnc(-n5c6ccccc6c6ccc(-c7ccccc7)cc65)n4)c3)cc2)cc1 ; c1ccc(-c2cc(-c3ccccc3)nc(-c3ccc(-n4c5ccccc5c5ccc(-c6cccc7c6sc6ccccc67)cc54)cc3)n2)cc1]

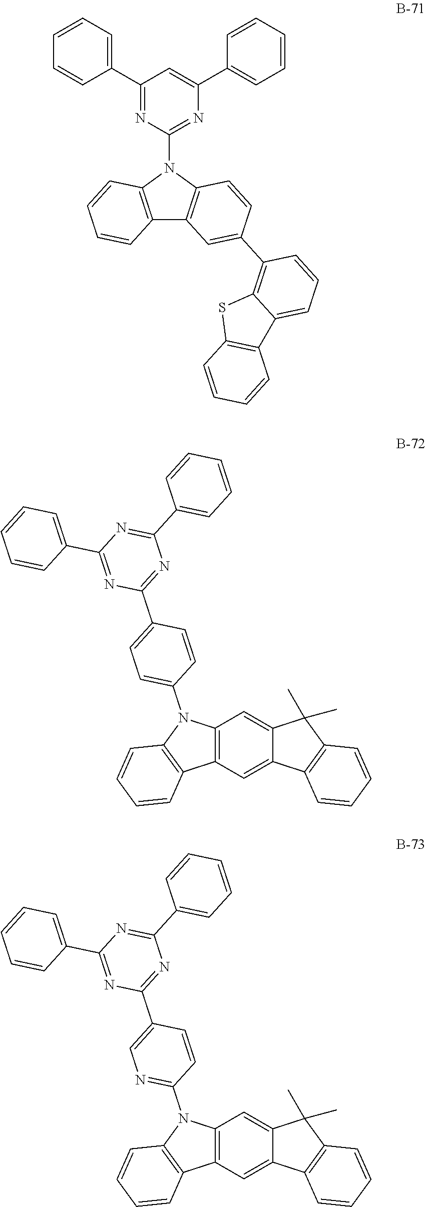 [SMILES: c1ccc(-c2cc(-c3ccccc3)nc(-n3c4ccccc4c4cc(-c5cccc6c5sc5ccccc56)ccc43)n2)cc1 ; CC1(C)c2ccccc2-c2cc3c4ccccc4n(-c4ccc(-c5nc(-c6ccccc6)nc(-c6ccccc6)n5)cc4)c3cc21 ; CC1(C)c2ccccc2-c2cc3c4ccccc4n(-c4ccc(-c5nc(-c6ccccc6)nc(-c6ccccc6)n5)cn4)c3cc21]

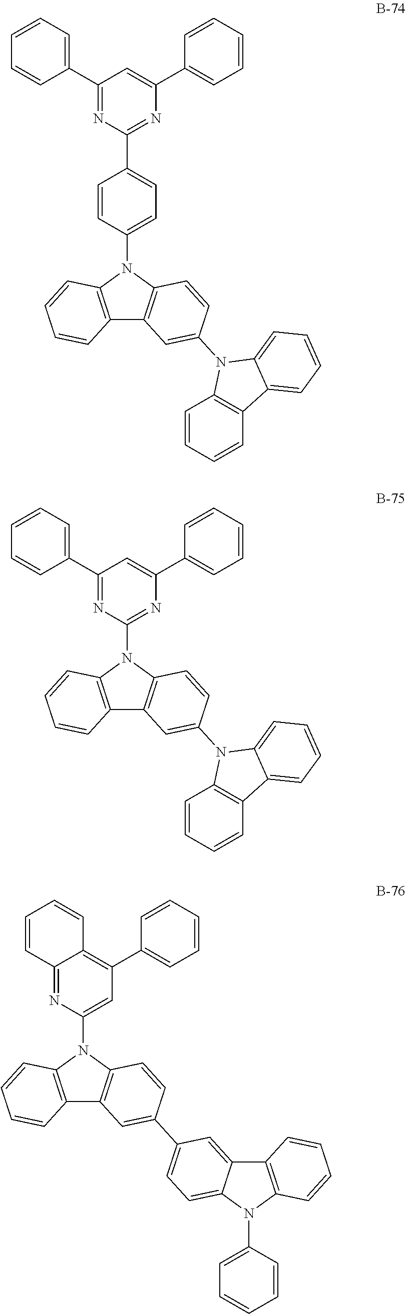 [SMILES: c1ccc(-c2cc(-c3ccccc3)nc(-c3ccc(-n4c5ccccc5c5cc(-n6c7ccccc7c7ccccc76)ccc54)cc3)n2)cc1 ; c1ccc(-c2cc(-c3ccccc3)nc(-n3c4ccccc4c4cc(-n5c6ccccc6c6ccccc65)ccc43)n2)cc1 ; c1ccc(-c2cc(-n3c4ccccc4c4cc(-c5ccc6c(c5)c5ccccc5n6-c5ccccc5)ccc43)nc3ccccc23)cc1]

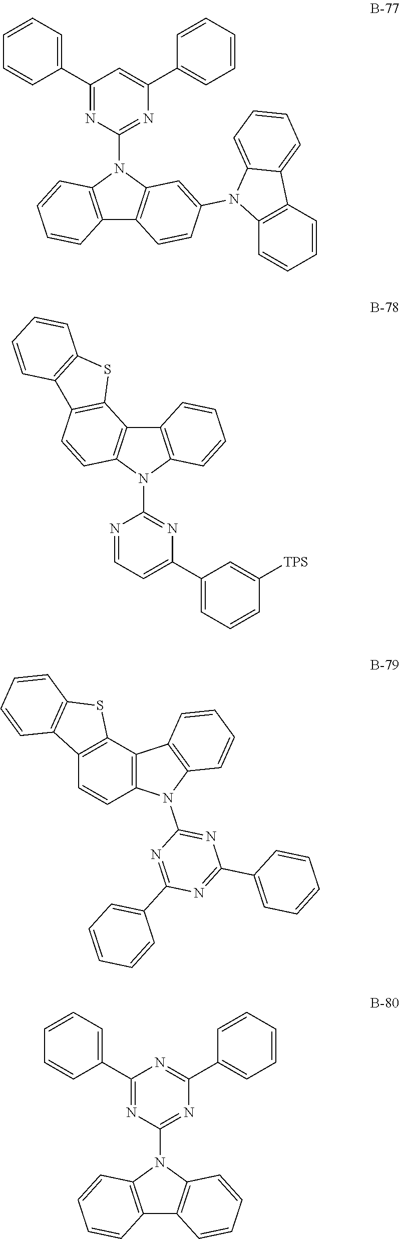

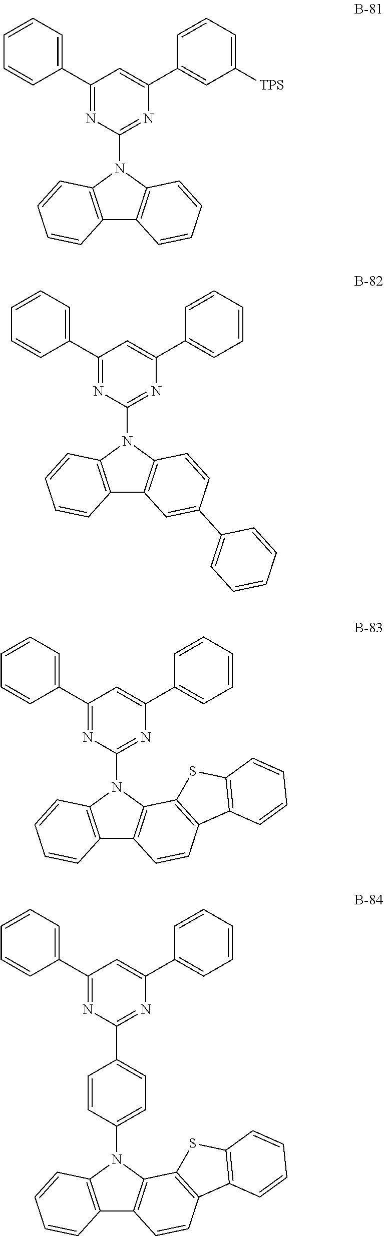

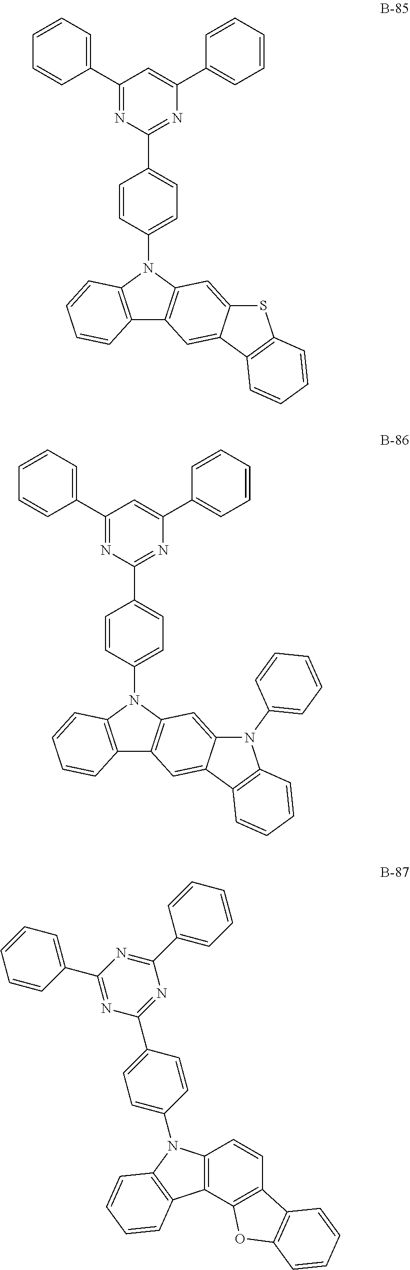 [SMILES: c1ccc(-c2cc(-c3ccccc3)nc(-c3ccc(-n4c5ccccc5c5cc6c(cc54)sc4ccccc46)cc3)n2)cc1 ; c1ccc(-c2cc(-c3ccccc3)nc(-c3ccc(-n4c5ccccc5c5cc6c7ccccc7n(-c7ccccc7)c6cc54)cc3)n2)cc1 ; c1ccc(-c2nc(-c3ccccc3)nc(-c3ccc(-n4c5ccccc5c5c6oc7ccccc7c6ccc54)cc3)n2)cc1]

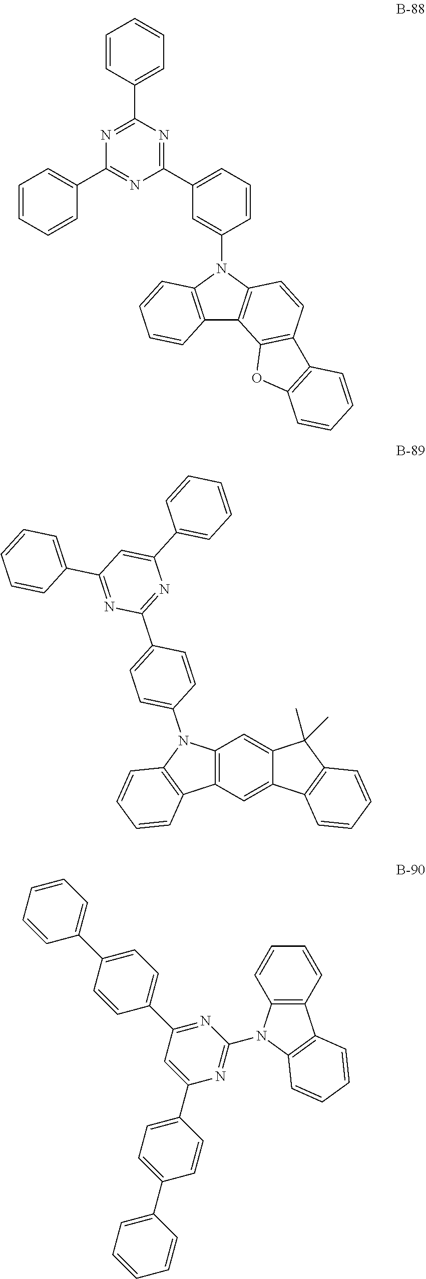 [SMILES: c1ccc(-c2nc(-c3ccccc3)nc(-c3cccc(-n4c5ccccc5c5c6oc7ccccc7c6ccc54)c3)n2)cc1 ; CC1(C)c2ccccc2-c2cc3c4ccccc4n(-c4ccc(-c5nc(-c6ccccc6)cc(-c6ccccc6)n5)cc4)c3cc21 ; c1ccc(-c2ccc(-c3cc(-c4ccc(-c5ccccc5)cc4)nc(-n4c5ccccc5c5ccccc54)n3)cc2)cc1]

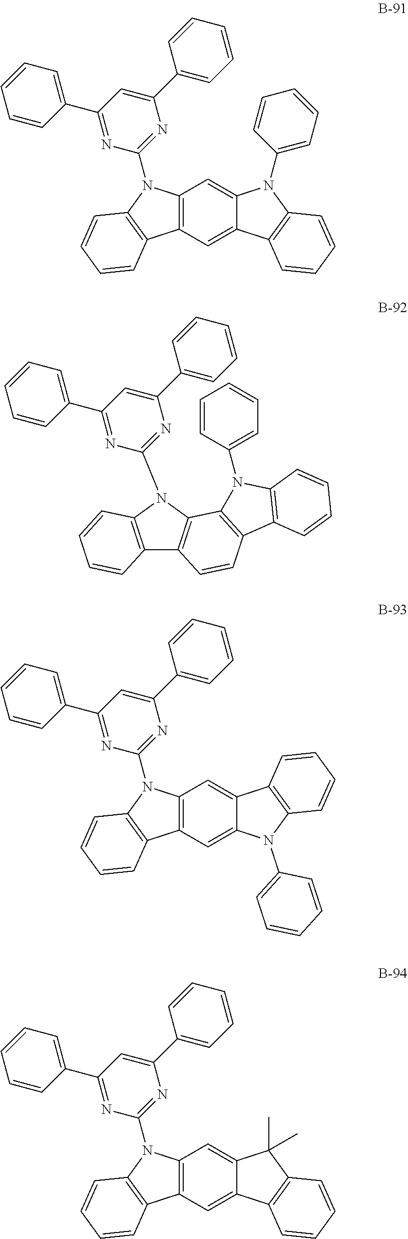

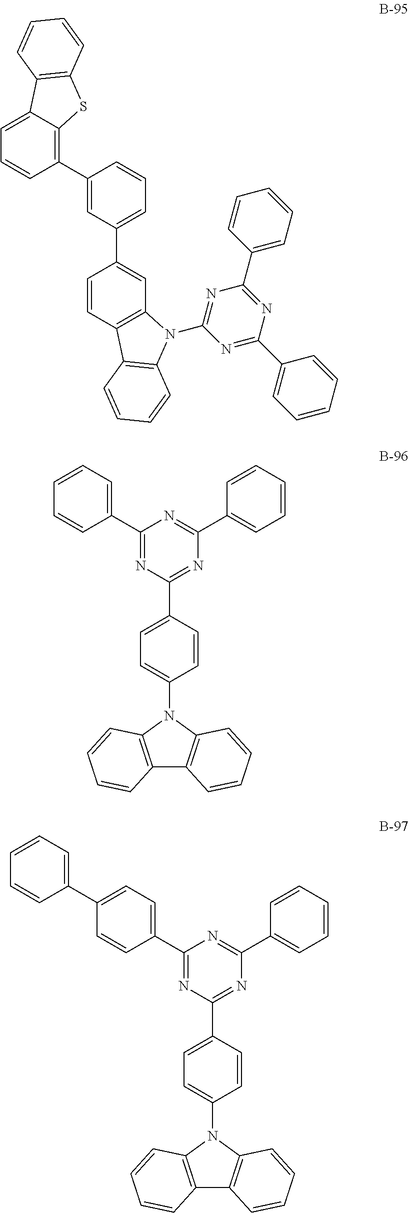 [SMILES: c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3ccc(-n4c5ccccc5c5ccccc54)cc3)n2)cc1 ; c1ccc(-c2ccc(-c3nc(-c4ccccc4)nc(-c4ccc(-n5c6ccccc6c6ccccc65)cc4)n3)cc2)cc1]

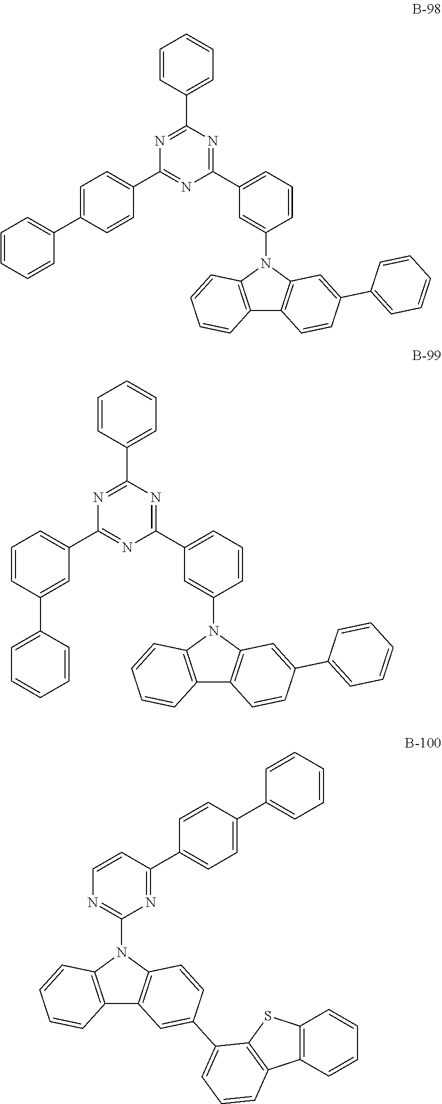 [SMILES: c1ccc(-c2ccc(-c3nc(-c4ccccc4)nc(-c4cccc(-n5c6ccccc6c6ccc(-c7ccccc7)cc65)c4)n3)cc2)cc1 ; c1ccc(-c2cccc(-c3nc(-c4ccccc4)nc(-c4cccc(-n5c6ccccc6c6ccc(-c7ccccc7)cc65)c4)n3)c2)cc1 ; c1ccc(-c2ccc(-c3ccnc(-n4c5ccccc5c5cc(-c6cccc7c6sc6ccccc67)ccc54)n3)cc2)cc1]

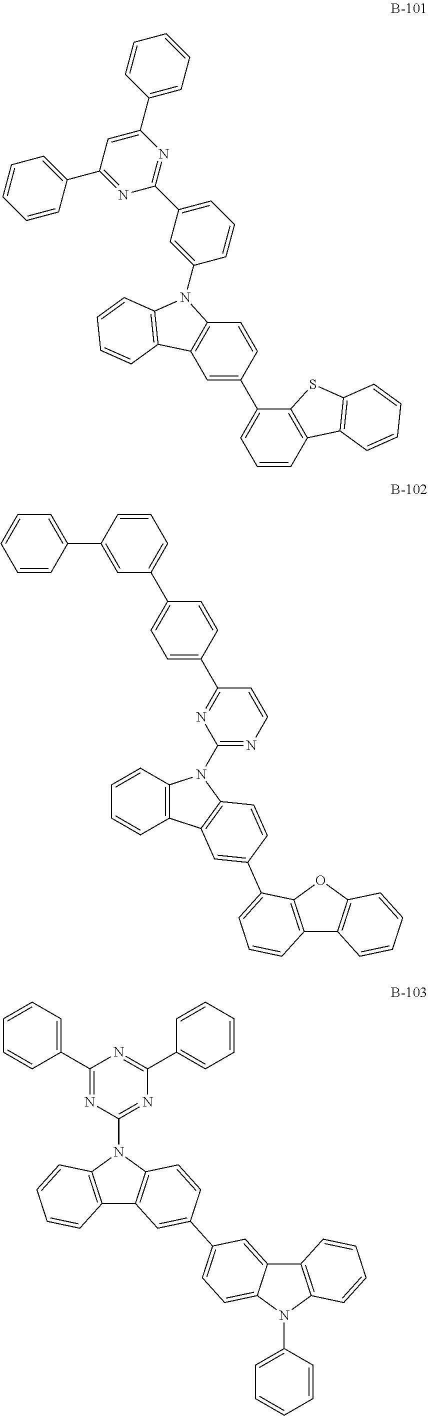 [SMILES: c1ccc(-c2cc(-c3ccccc3)nc(-c3cccc(-n4c5ccccc5c5cc(-c6cccc7c6sc6ccccc67)ccc54)c3)n2)cc1 ; c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

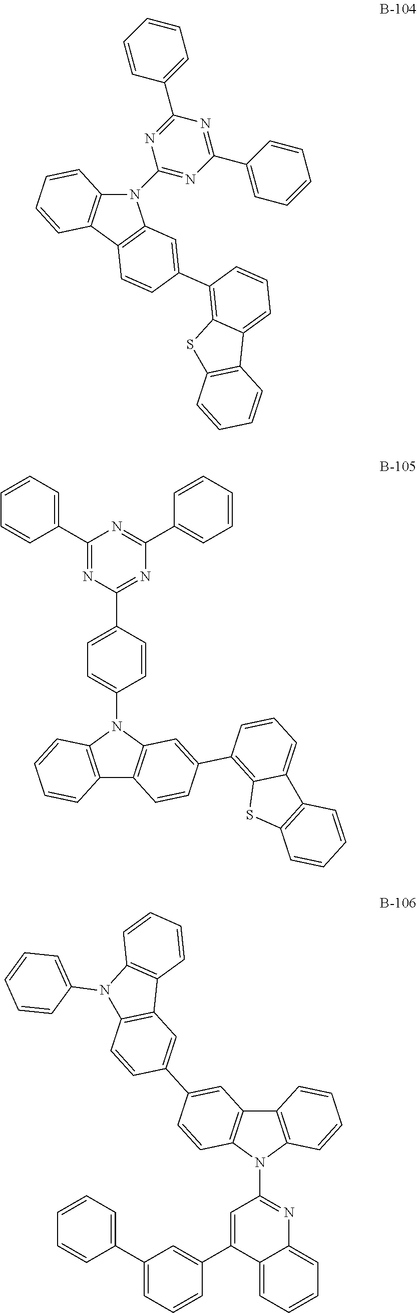 [SMILES: c1ccc(-c2nc(-c3ccccc3)nc(-n3c4ccccc4c4ccc(-c5cccc6c5sc5ccccc56)cc43)n2)cc1 ; c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2cccc(-c3cc(-n4c5ccccc5c5cc(-c6ccc7c(c6)c6ccccc6n7-c6ccccc6)ccc54)nc4ccccc34)c2)cc1]

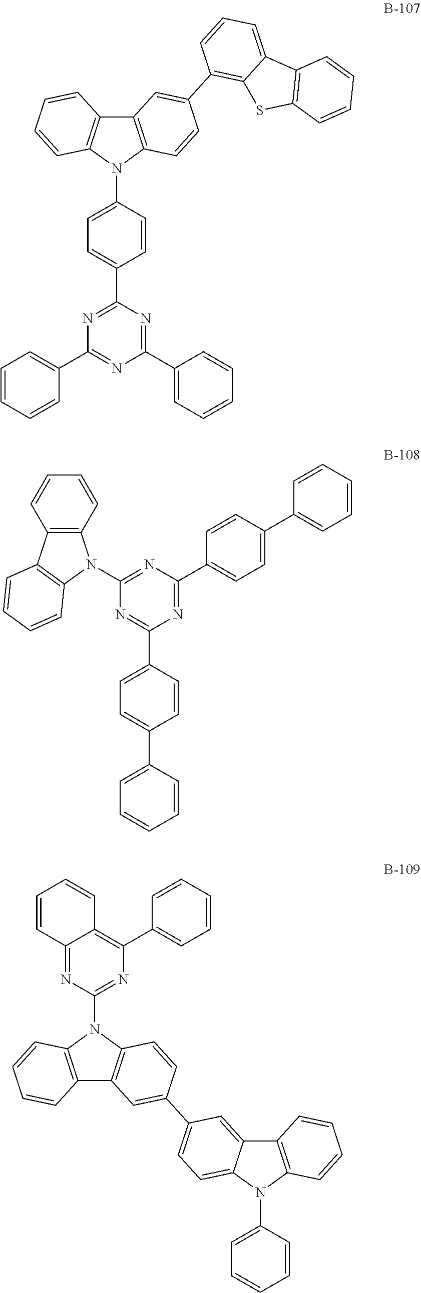 [SMILES: c1ccc(-c2nc(-c3ccccc3)nc(-c3ccc(-n4c5ccccc5c5cc(-c6cccc7c6sc6ccccc67)ccc54)cc3)n2)cc1 ; c1ccc(-c2ccc(-c3nc(-c4ccc(-c5ccccc5)cc4)nc(-n4c5ccccc5c5ccccc54)n3)cc2)cc1 ; c1ccc(-c2nc(-n3c4ccccc4c4cc(-c5ccc6c(c5)c5ccccc5n6-c5ccccc5)ccc43)nc3ccccc23)cc1]

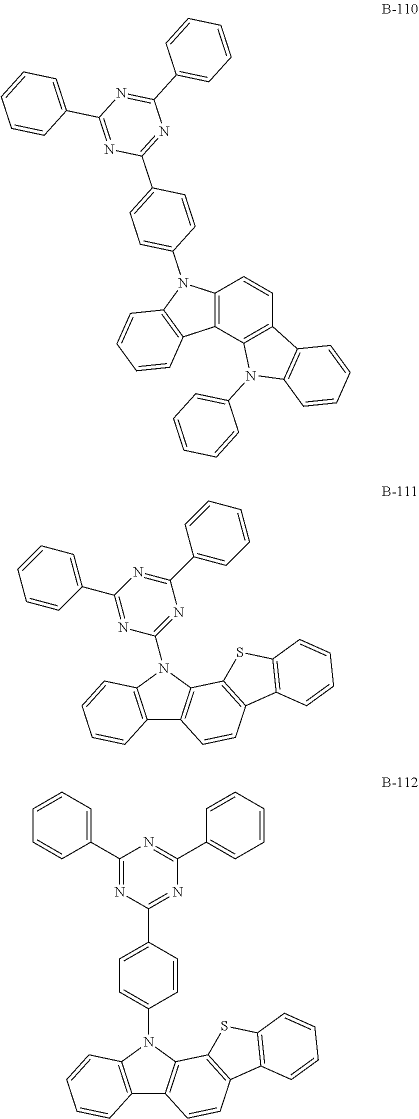

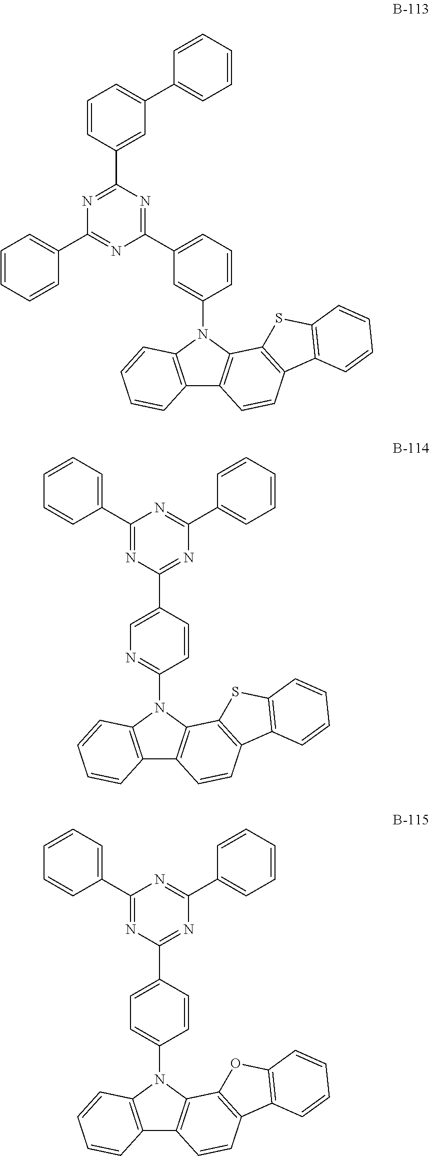 [SMILES: c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2nc(-c3ccccc3)nc(-c3ccc(-n4c5ccccc5c5ccc6c7ccccc7sc6c54)nc3)n2)cc1 ; c1ccc(-c2nc(-c3ccccc3)nc(-c3ccc(-n4c5ccccc5c5ccc6c7ccccc7oc6c54)cc3)n2)cc1]

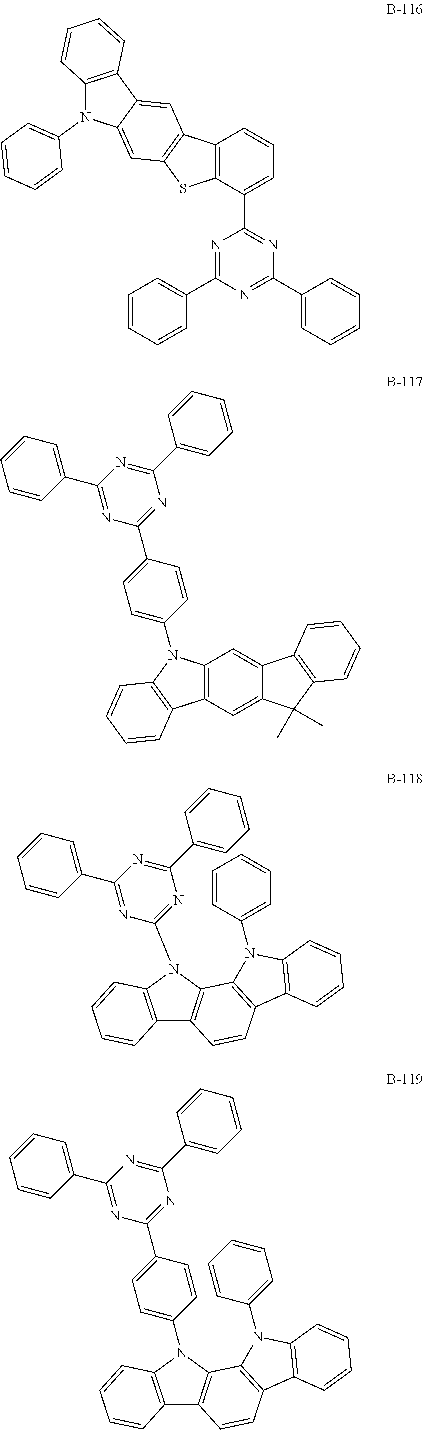

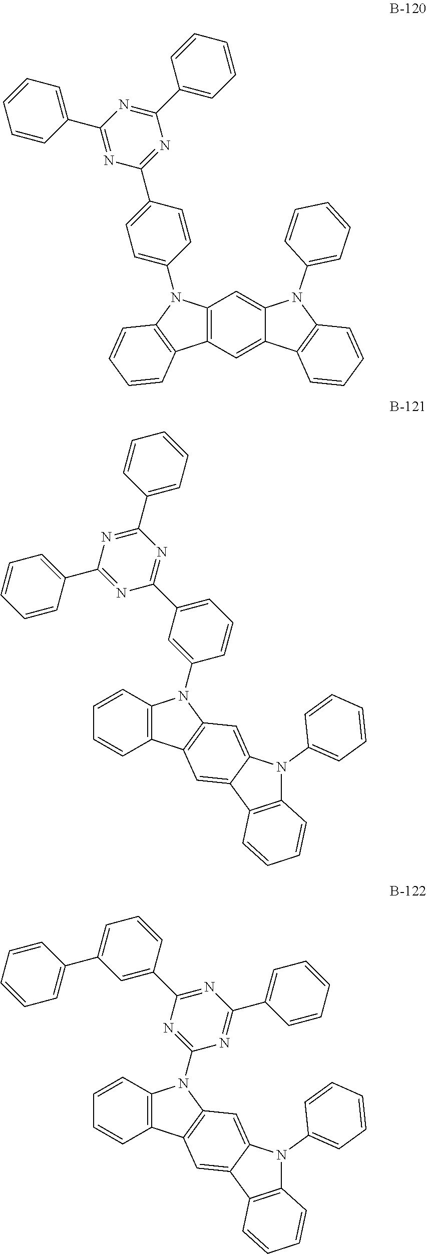 [SMILES: c1ccc(-c2nc(-c3ccccc3)nc(-c3ccc(-n4c5ccccc5c5cc6c7ccccc7n(-c7ccccc7)c6cc54)cc3)n2)cc1 ; c1ccc(-c2nc(-c3ccccc3)nc(-c3cccc(-n4c5ccccc5c5cc6c7ccccc7n(-c7ccccc7)c6cc54)c3)n2)cc1 ; c1ccc(-c2cccc(-c3nc(-c4ccccc4)nc(-n4c5ccccc5c5cc6c7ccccc7n(-c7ccccc7)c6cc54)n3)c2)cc1]

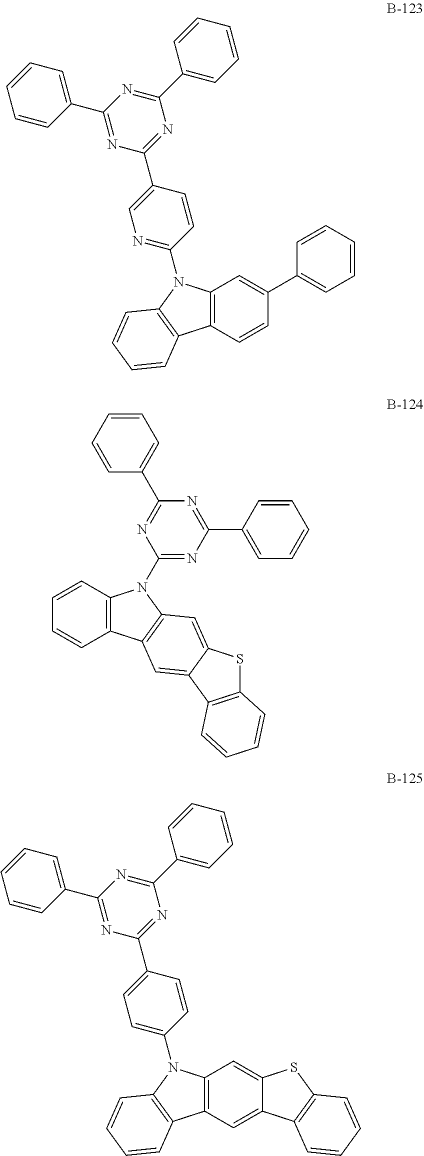

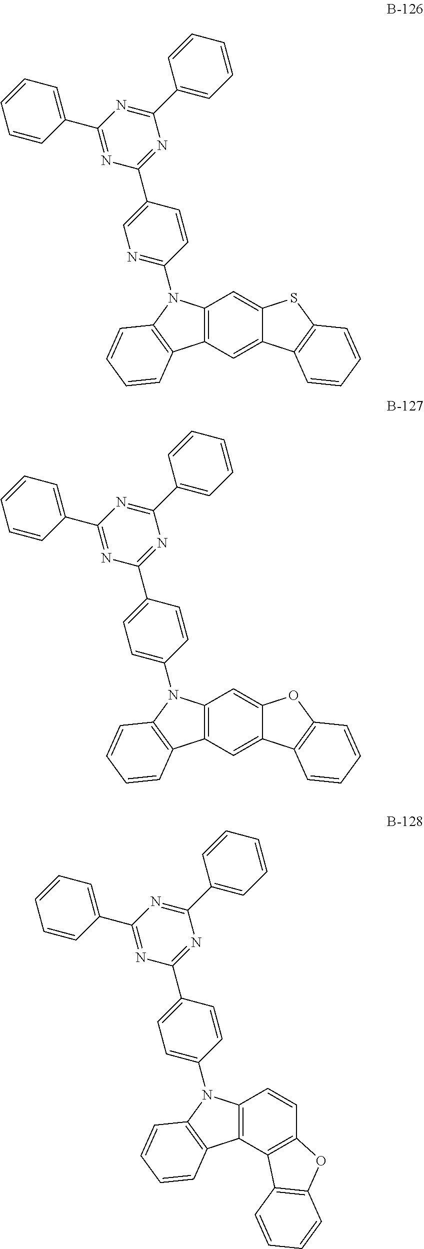 [SMILES: c1ccc(-c2nc(-c3ccccc3)nc(-c3ccc(-n4c5ccccc5c5cc6c(cc54)sc4ccccc46)nc3)n2)cc1 ; c1ccc(-c2nc(-c3ccccc3)nc(-c3ccc(-n4c5ccccc5c5cc6c(cc54)oc4ccccc46)cc3)n2)cc1 ; c1ccc(-c2nc(-c3ccccc3)nc(-c3ccc(-n4c5ccccc5c5c6c(ccc54)oc4ccccc46)cc3)n2)cc1]

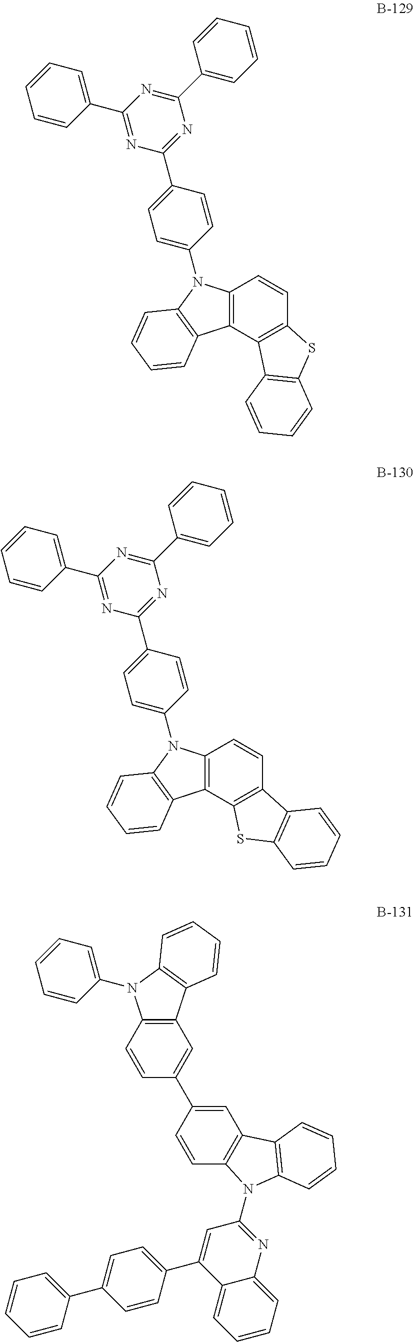 [SMILES: c1ccc(-c2nc(-c3ccccc3)nc(-c3ccc(-n4c5ccccc5c5c6c(ccc54)sc4ccccc46)cc3)n2)cc1 ; c1ccc(-c2nc(-c3ccccc3)nc(-c3ccc(-n4c5ccccc5c5c6sc7ccccc7c6ccc54)cc3)n2)cc1 ; c1ccc(-c2ccc(-c3cc(-n4c5ccccc5c5cc(-c6ccc7c(c6)c6ccccc6n7-c6ccccc6)ccc54)nc4ccccc34)cc2)cc1]

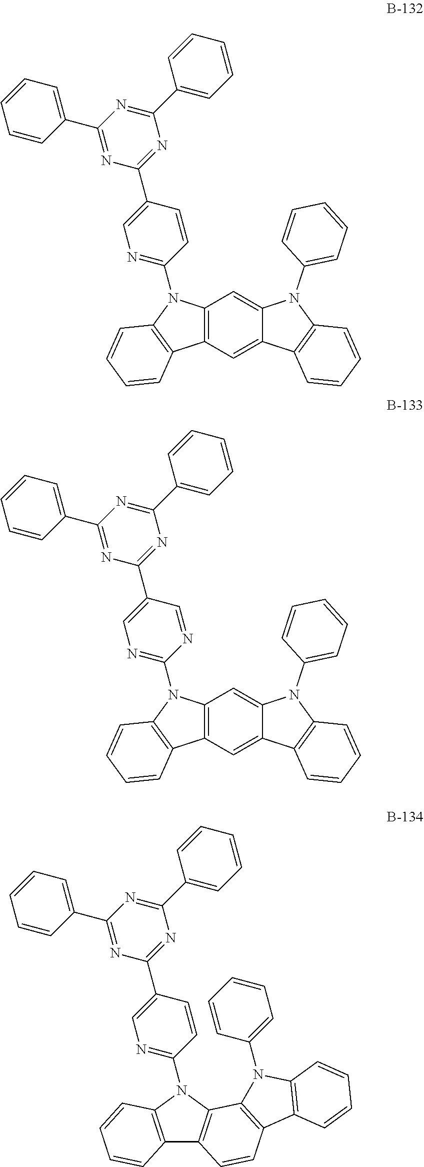 [SMILES: c1ccc(-c2nc(-c3ccccc3)nc(-c3ccc(-n4c5ccccc5c5cc6c7ccccc7n(-c7ccccc7)c6cc54)nc3)n2)cc1 ; c1ccc(-c2nc(-c3ccccc3)nc(-c3cnc(-n4c5ccccc5c5cc6c7ccccc7n(-c7ccccc7)c6cc54)nc3)n2)cc1 ; c1ccc(-c2nc(-c3ccccc3)nc(-c3ccc(-n4c5ccccc5c5ccc6c7ccccc7n(-c7ccccc7)c6c54)nc3)n2)cc1]

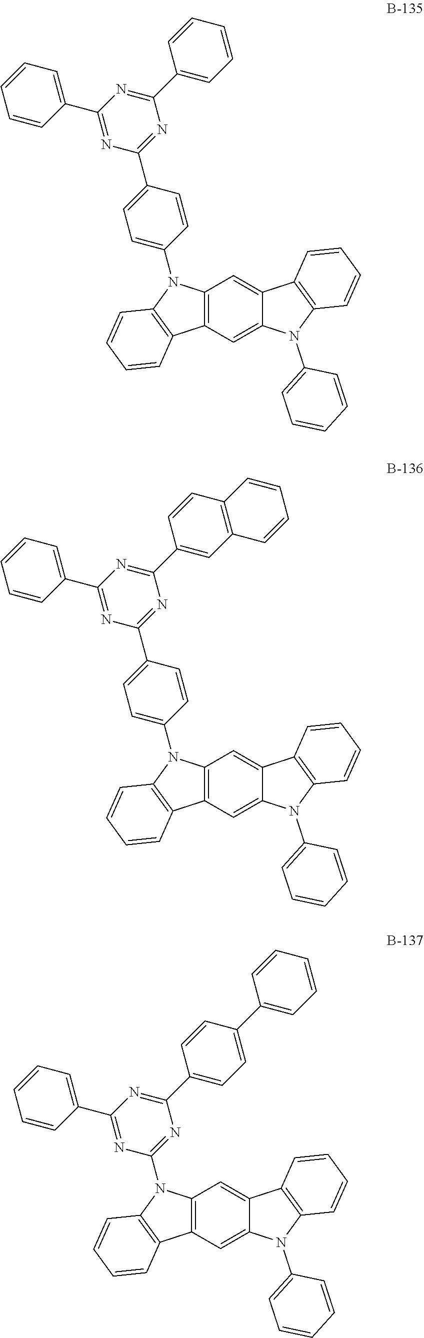 [SMILES: c1ccc(-c2nc(-c3ccccc3)nc(-c3ccc(-n4c5ccccc5c5cc6c(cc54)c4ccccc4n6-c4ccccc4)cc3)n2)cc1 ; c1ccc(-c2nc(-c3ccc(-n4c5ccccc5c5cc6c(cc54)c4ccccc4n6-c4ccccc4)cc3)nc(-c3ccc4ccccc4c3)n2)cc1 ; c1ccc(-c2ccc(-c3nc(-c4ccccc4)nc(-n4c5ccccc5c5cc6c(cc54)c4ccccc4n6-c4ccccc4)n3)cc2)cc1]

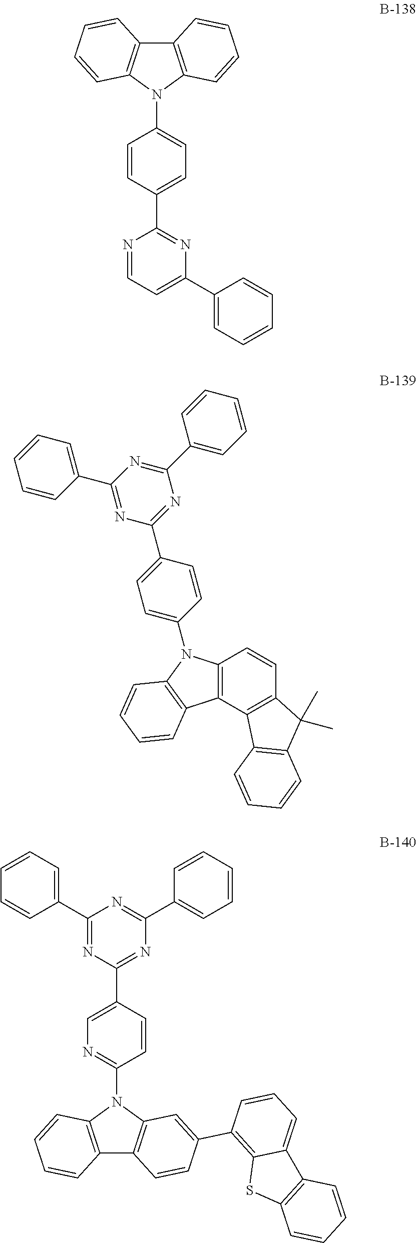 [SMILES: c1ccc(-c2ccnc(-c3ccc(-n4c5ccccc5c5ccccc54)cc3)n2)cc1 ; CC1(C)c2ccccc2-c2c1ccc1c2c2ccccc2n1-c1ccc(-c2nc(-c3ccccc3)nc(-c3ccccc3)n2)cc1 ; c1ccc(-c2nc(-c3ccccc3)nc(-c3ccc(-n4c5ccccc5c5ccc(-c6cccc7c6sc6ccccc67)cc54)nc3)n2)cc1]

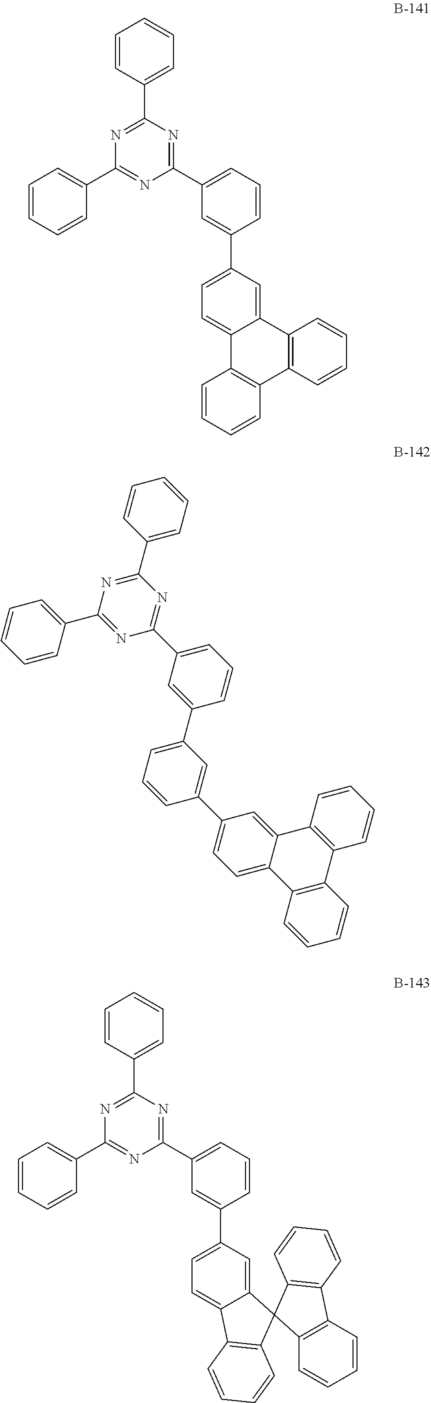 [SMILES: c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4ccc5c(c4)C4(c6ccccc6-c6ccccc64)c4ccccc4-5)c3)n2)cc1]

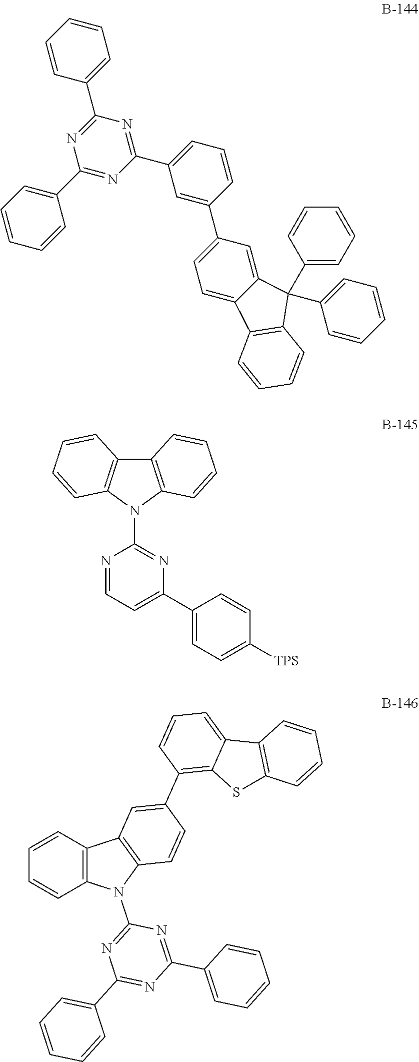

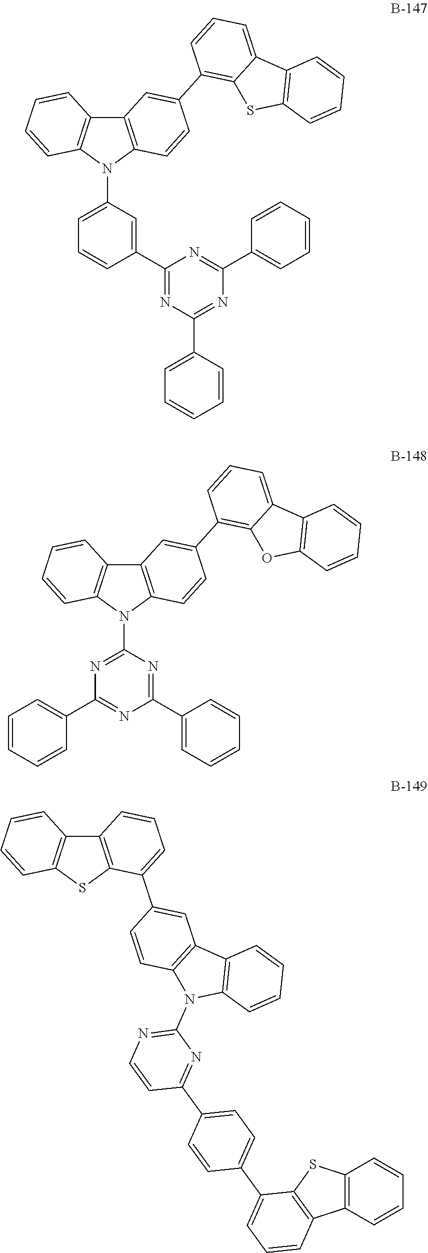

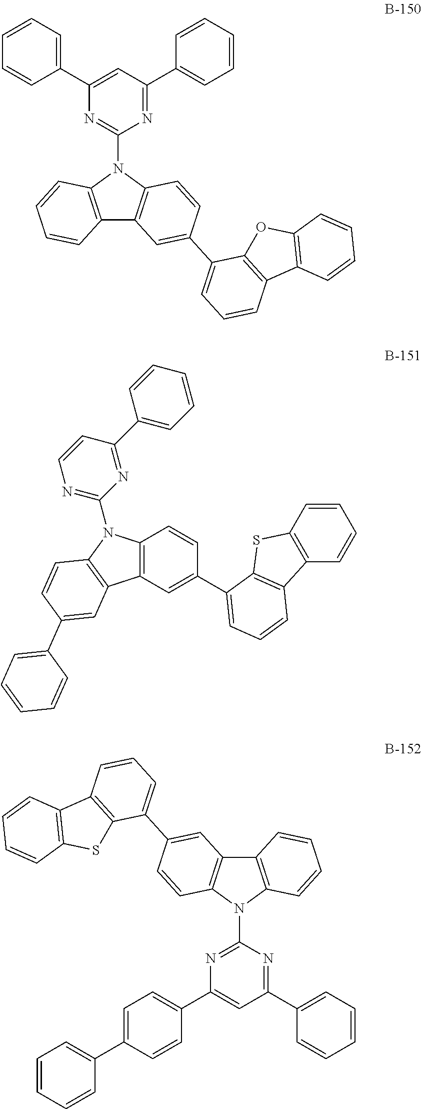 [SMILES: c1ccc(-c2cc(-c3ccccc3)nc(-n3c4ccccc4c4cc(-c5cccc6c5oc5ccccc56)ccc43)n2)cc1 ; c1ccc(-c2ccc3c(c2)c2cc(-c4cccc5c4sc4ccccc45)ccc2n3-c2nccc(-c3ccccc3)n2)cc1 ; c1ccc(-c2ccc(-c3cc(-c4ccccc4)nc(-n4c5ccccc5c5cc(-c6cccc7c6sc6ccccc67)ccc54)n3)cc2)cc1]

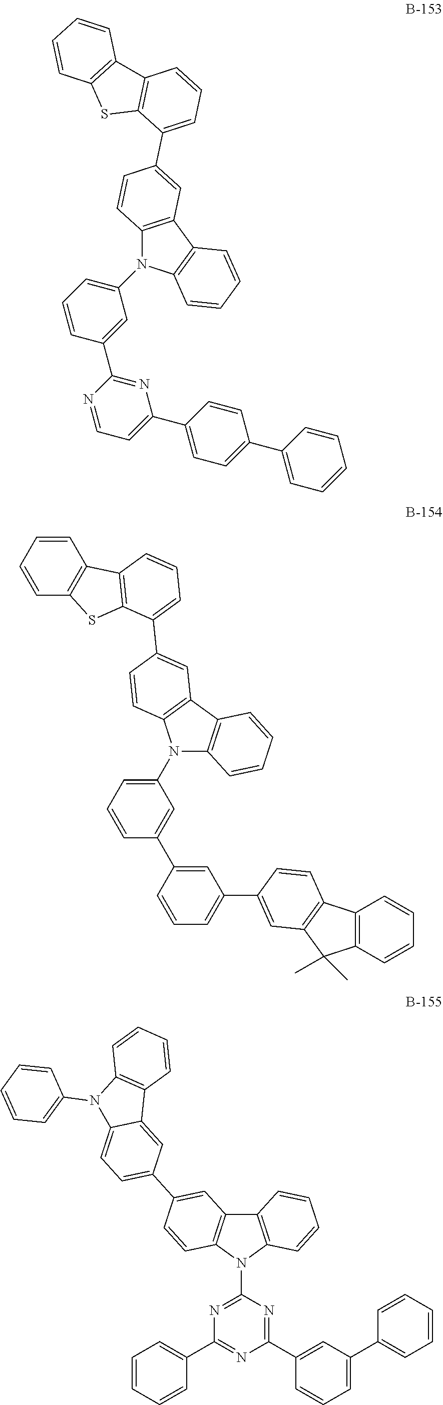 [SMILES: c1ccc(-c2ccc(-c3ccnc(-c4cccc(-n5c6ccccc6c6cc(-c7cccc8c7sc7ccccc78)ccc65)c4)n3)cc2)cc1 ; CC1(C)c2ccccc2-c2ccc(-c3cccc(-c4cccc(-n5c6ccccc6c6cc(-c7cccc8c7sc7ccccc78)ccc65)c4)c3)cc21 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1]

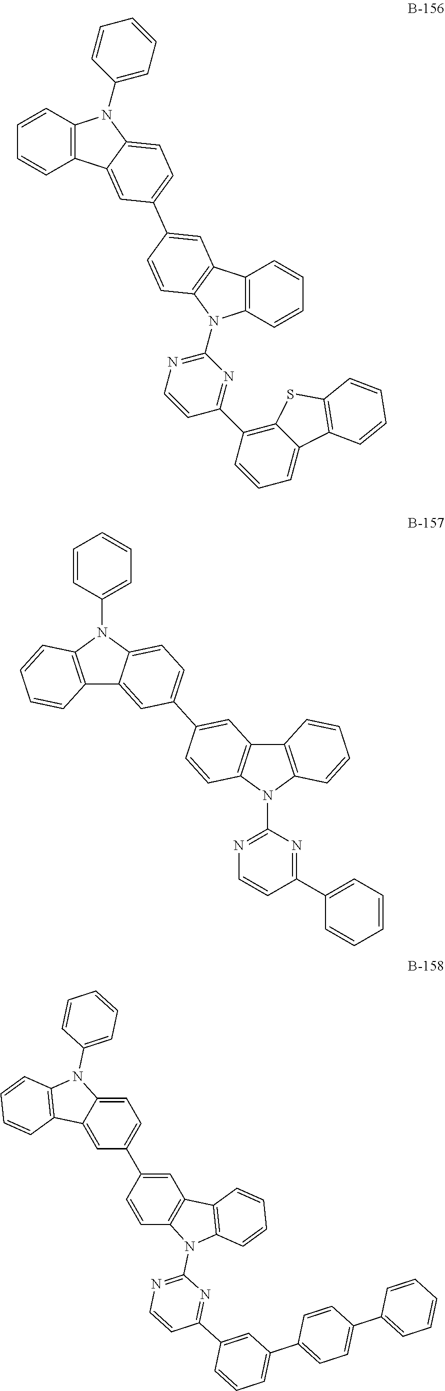 [SMILES: c1ccc(-n2c3ccccc3c3cc(-c4ccc5c(c4)c4ccccc4n5-c4nccc(-c5cccc6c5sc5ccccc56)n4)ccc32)cc1 ; c1ccc(-c2ccnc(-n3c4ccccc4c4cc(-c5ccc6c(c5)c5ccccc5n6-c5ccccc5)ccc43)n2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

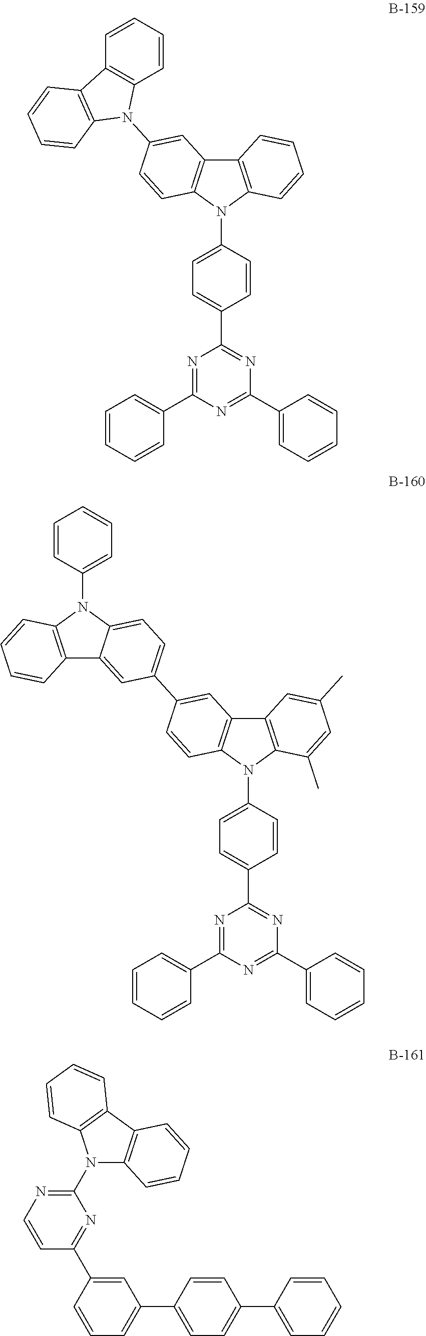 [SMILES: c1ccc(-c2nc(-c3ccccc3)nc(-c3ccc(-n4c5ccccc5c5cc(-n6c7ccccc7c7ccccc76)ccc54)cc3)n2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2ccc(-c3cccc(-c4ccnc(-n5c6ccccc6c6ccccc65)n4)c3)cc2)cc1]

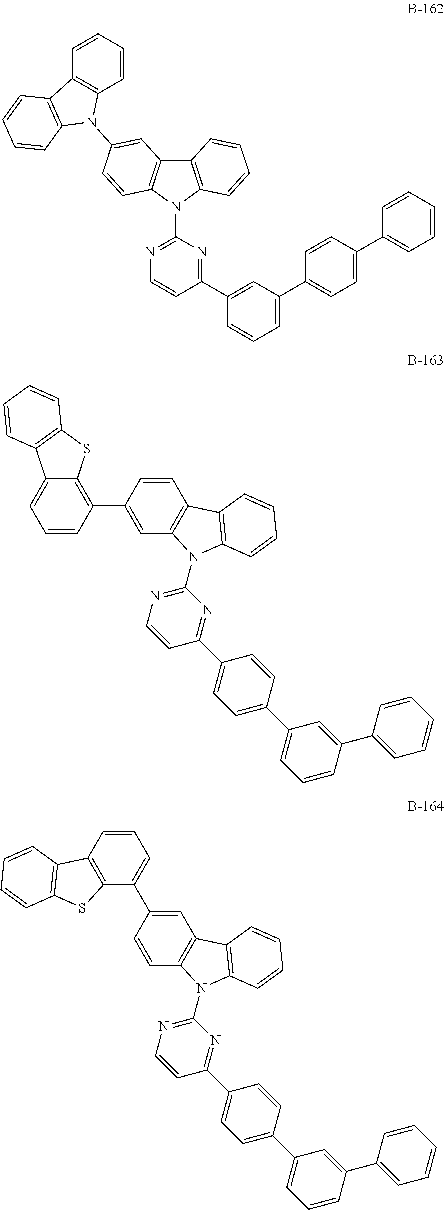 [SMILES: c1ccc(-c2ccc(-c3cccc(-c4ccnc(-n5c6ccccc6c6cc(-n7c8ccccc8c8ccccc87)ccc65)n4)c3)cc2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1]

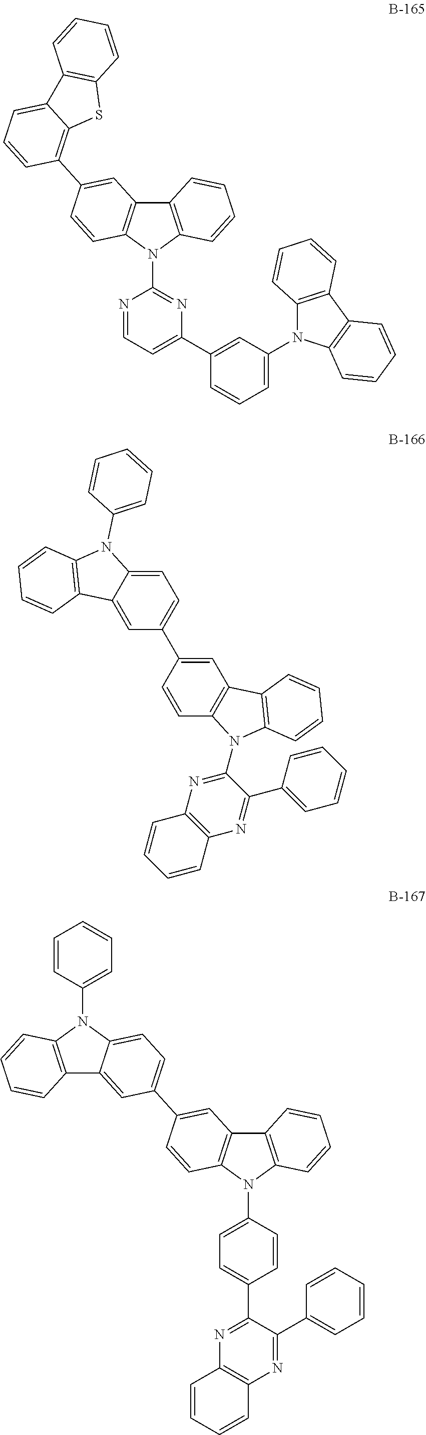 [SMILES: c1cc(-c2ccnc(-n3c4ccccc4c4cc(-c5cccc6c5sc5ccccc56)ccc43)n2)cc(-n2c3ccccc3c3ccccc32)c1 ; c1ccc(-c2nc3ccccc3nc2-n2c3ccccc3c3cc(-c4ccc5c(c4)c4ccccc4n5-c4ccccc4)ccc32)cc1 ; c1ccc(-c2nc3ccccc3nc2-c2ccc(-n3c4ccccc4c4cc(-c5ccc6c(c5)c5ccccc5n6-c5ccccc5)ccc43)cc2)cc1]

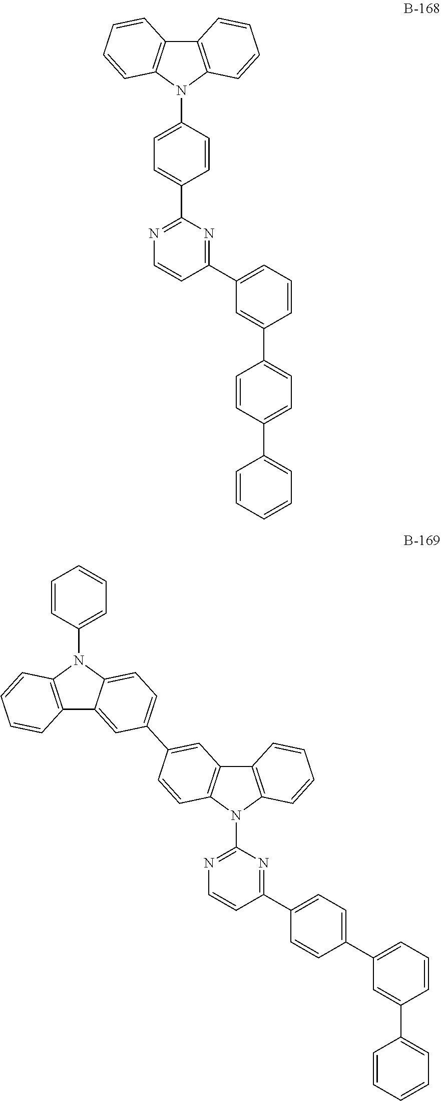 [SMILES: c1ccc(-c2ccc(-c3cccc(-c4ccnc(-c5ccc(-n6c7ccccc7c7ccccc76)cc5)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1]

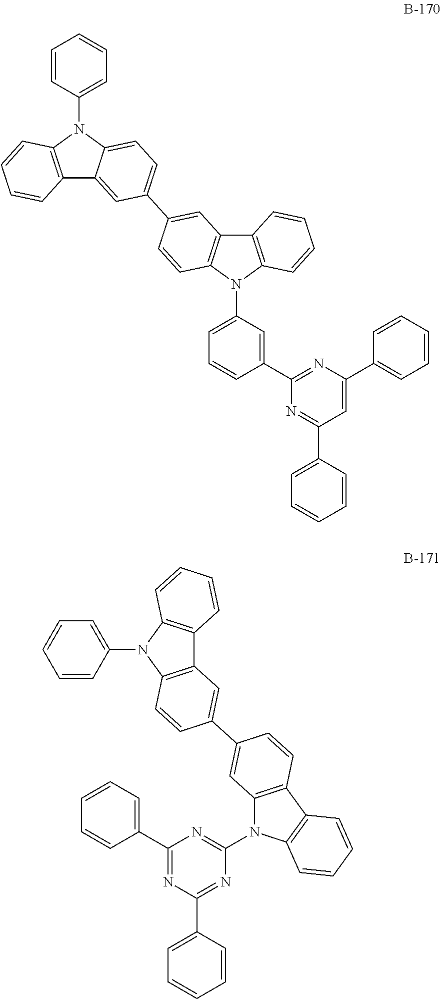 [SMILES: c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1]

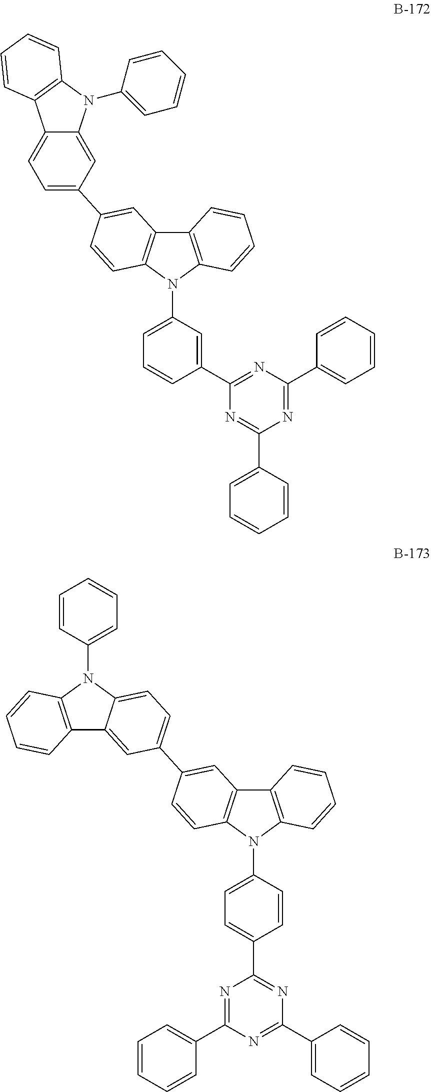 [SMILES: c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

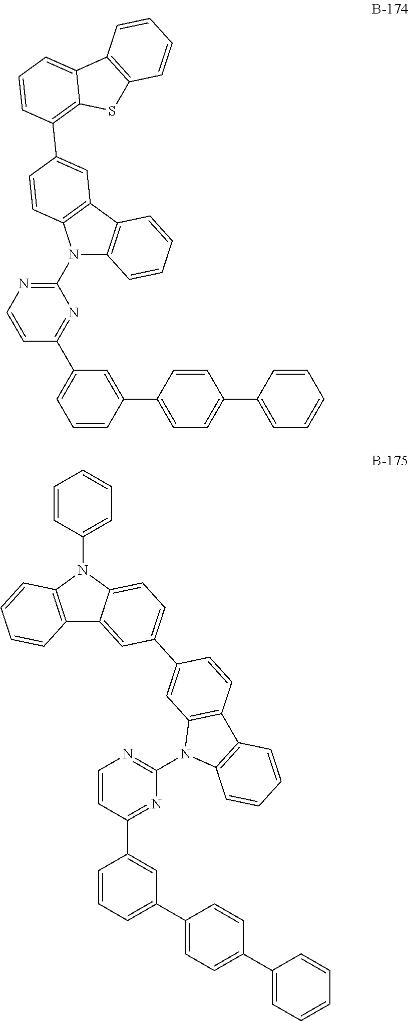

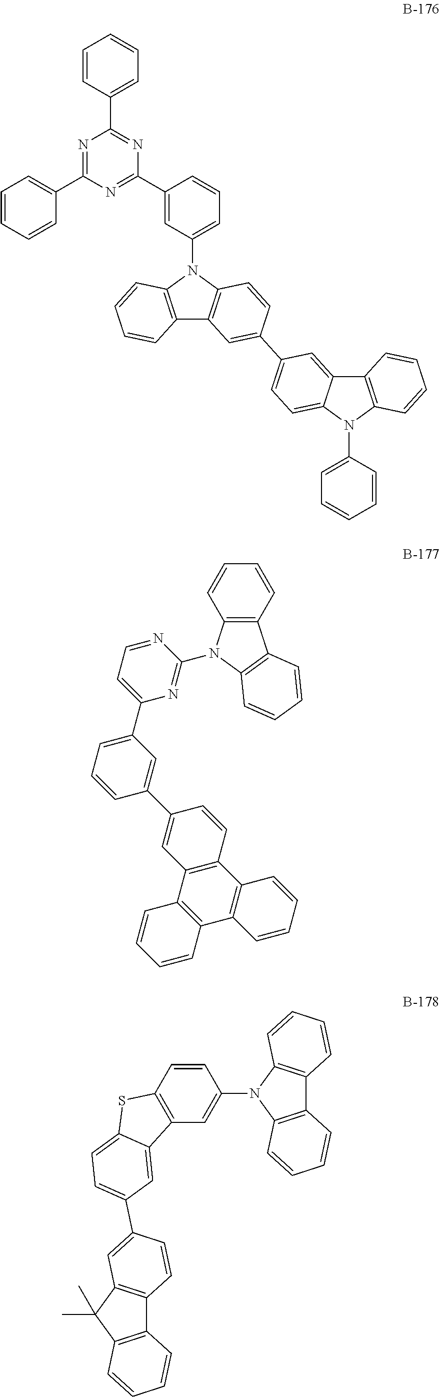 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1cc(-c2ccc3c4ccccc4c4ccccc4c3c2)cc(-c2ccnc(-n3c4ccccc4c4ccccc43)n2)c1 ; CC1(C)c2ccccc2-c2ccc(-c3ccc4sc5ccc(-n6c7ccccc7c7ccccc76)cc5c4c3)cc21]

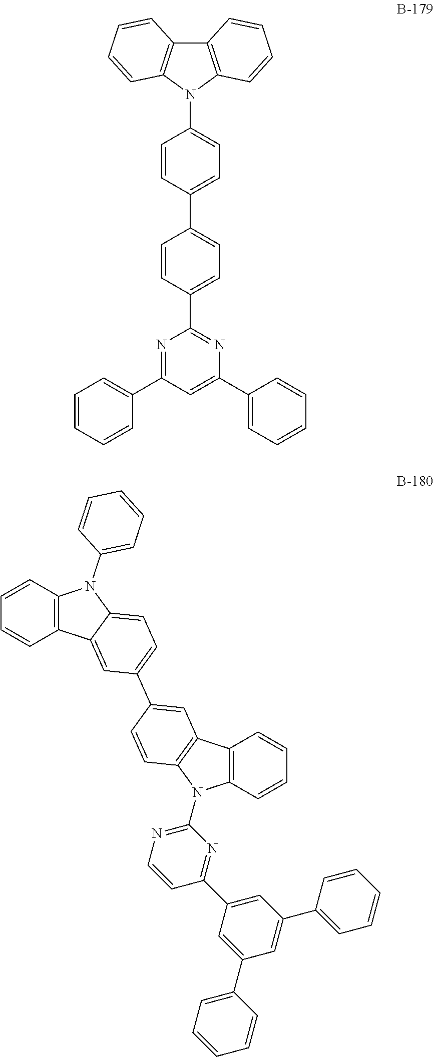 [SMILES: c1ccc(-c2cc(-c3ccccc3)nc(-c3ccc(-c4ccc(-n5c6ccccc6c6ccccc65)cc4)cc3)n2)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

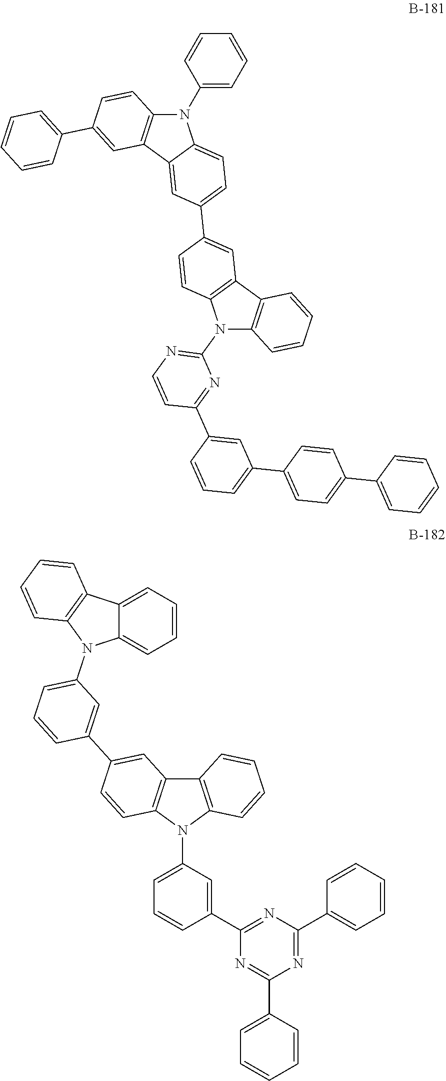 [SMILES: c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1 ; c1ccc(-c2nc(-c3ccccc3)nc(-c3cccc(-n4c5ccccc5c5cc(-c6cccc(-n7c8ccccc8c8ccccc87)c6)ccc54)c3)n2)cc1]

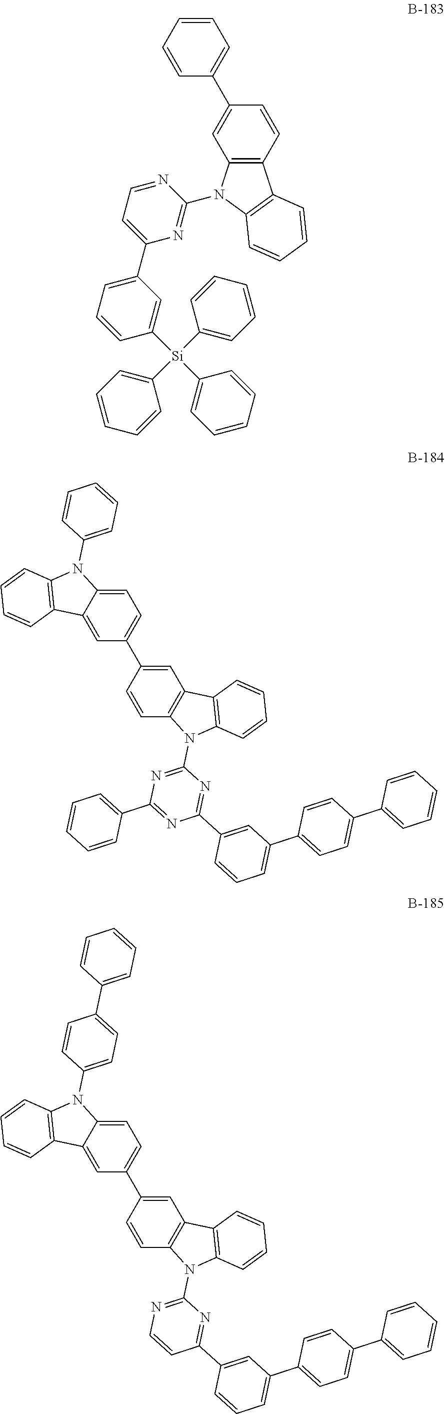 [SMILES: c1ccc(-c2ccc3c4ccccc4n(-c4nccc(-c5cccc([Si](c6ccccc6)(c6ccccc6)c6ccccc6)c5)n4)c3c2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1 ; c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1]

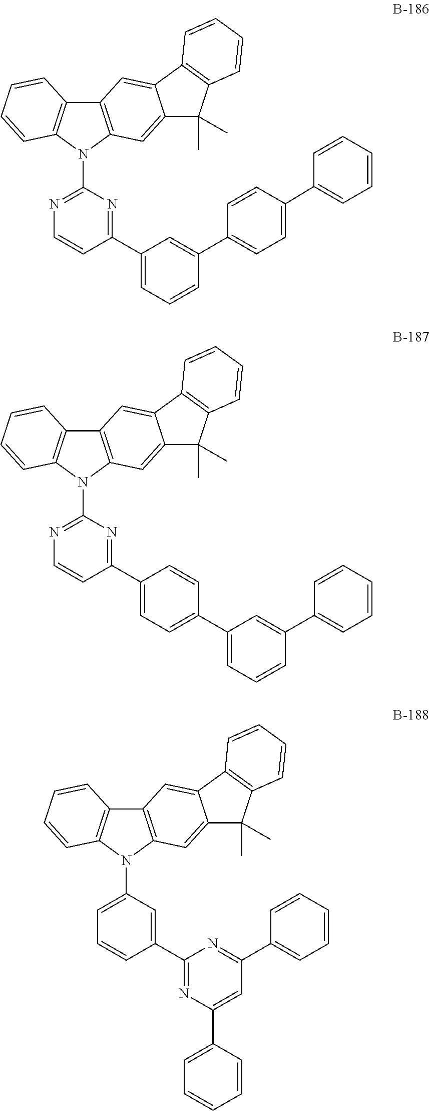

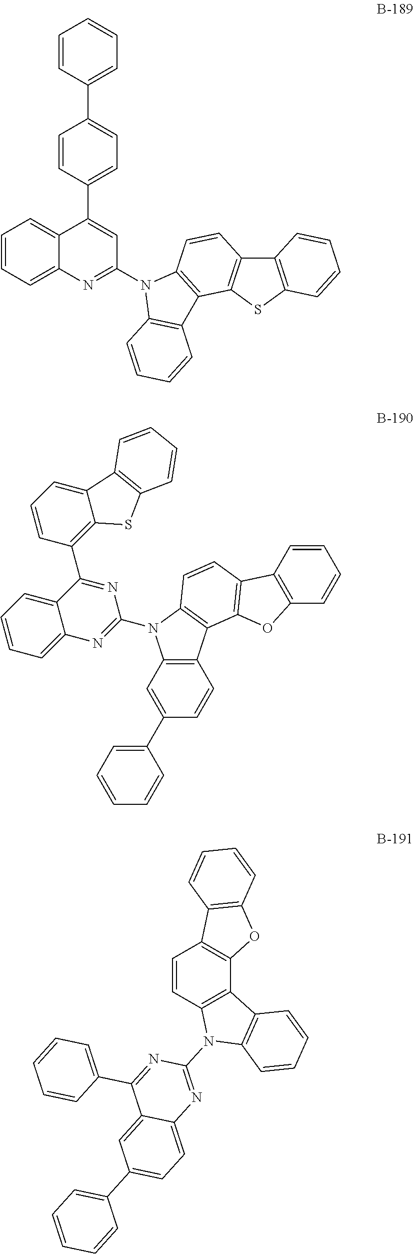 [SMILES: c1ccc(-c2ccc(-c3cc(-n4c5ccccc5c5c6sc7ccccc7c6ccc54)nc4ccccc34)cc2)cc1 ; c1ccc(-c2ccc3c4c5oc6ccccc6c5ccc4n(-c4nc(-c5cccc6c5sc5ccccc56)c5ccccc5n4)c3c2)cc1 ; c1ccc(-c2ccc3nc(-n4c5ccccc5c5c6oc7ccccc7c6ccc54)nc(-c4ccccc4)c3c2)cc1]

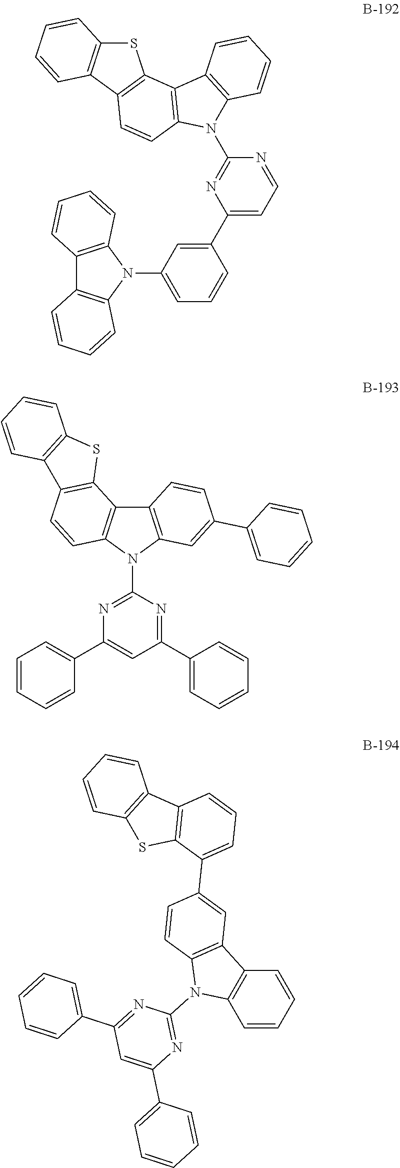 [SMILES: c1cc(-c2ccnc(-n3c4ccccc4c4c5sc6ccccc6c5ccc43)n2)cc(-n2c3ccccc3c3ccccc32)c1 ; c1ccc(-c2ccc3c4c5sc6ccccc6c5ccc4n(-c4nc(-c5ccccc5)cc(-c5ccccc5)n4)c3c2)cc1 ; c1ccc(-c2cc(-c3ccccc3)nc(-n3c4ccccc4c4cc(-c5cccc6c5sc5ccccc56)ccc43)n2)cc1]

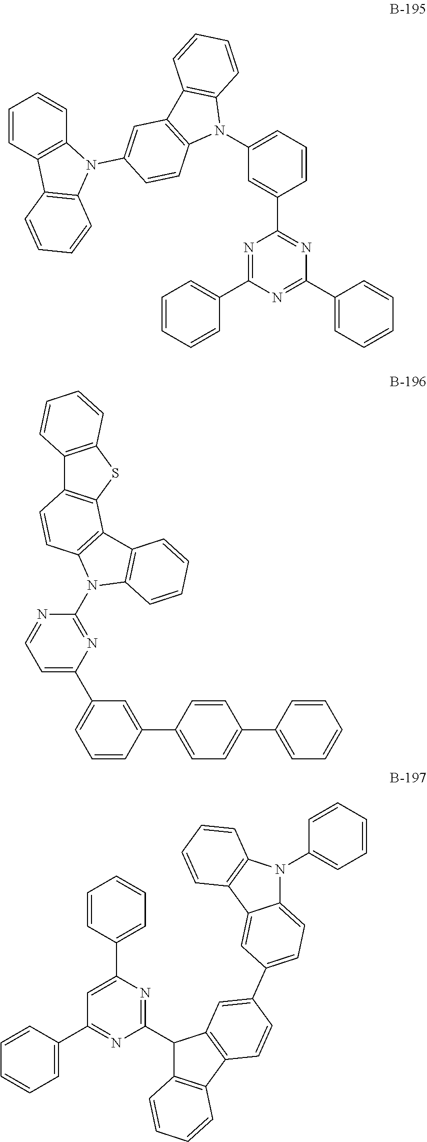

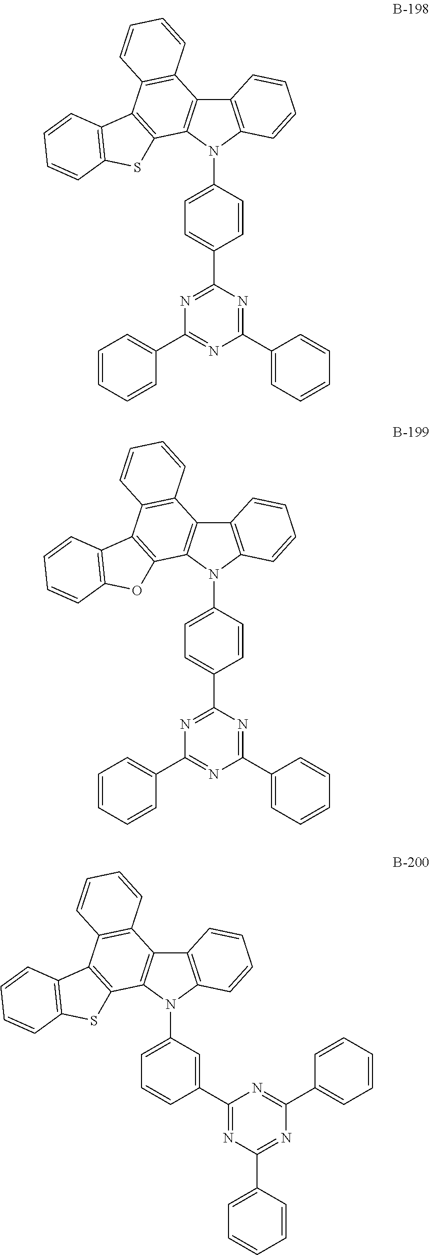 [SMILES: c1ccc(-c2nc(-c3ccccc3)nc(-c3ccc(-n4c5ccccc5c5c6ccccc6c6c7ccccc7sc6c54)cc3)n2)cc1 ; c1ccc(-c2nc(-c3ccccc3)nc(-c3ccc(-n4c5ccccc5c5c6ccccc6c6c7ccccc7oc6c54)cc3)n2)cc1 ; c1ccc(-c2nc(-c3ccccc3)nc(-c3cccc(-n4c5ccccc5c5c6ccccc6c6c7ccccc7sc6c54)c3)n2)cc1]

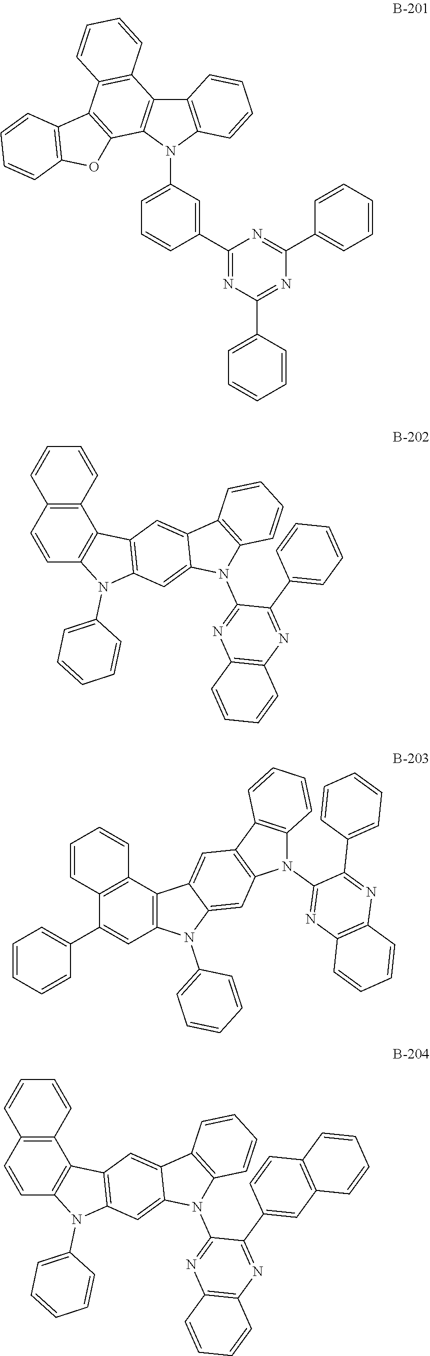 [SMILES: c1ccc(-c2nc(-c3ccccc3)nc(-c3cccc(-n4c5ccccc5c5c6ccccc6c6c7ccccc7oc6c54)c3)n2)cc1 ; c1ccc(-c2nc3ccccc3nc2-n2c3ccccc3c3cc4c5c6ccccc6ccc5n(-c5ccccc5)c4cc32)cc1 ; c1ccc(-c2nc3ccccc3nc2-n2c3ccccc3c3cc4c5c6ccccc6c(-c6ccccc6)cc5n(-c5ccccc5)c4cc32)cc1 ; c1ccc(-n2c3cc4c(cc3c3c5ccccc5ccc32)c2ccccc2n4-c2nc3ccccc3nc2-c2ccc3ccccc3c2)cc1]

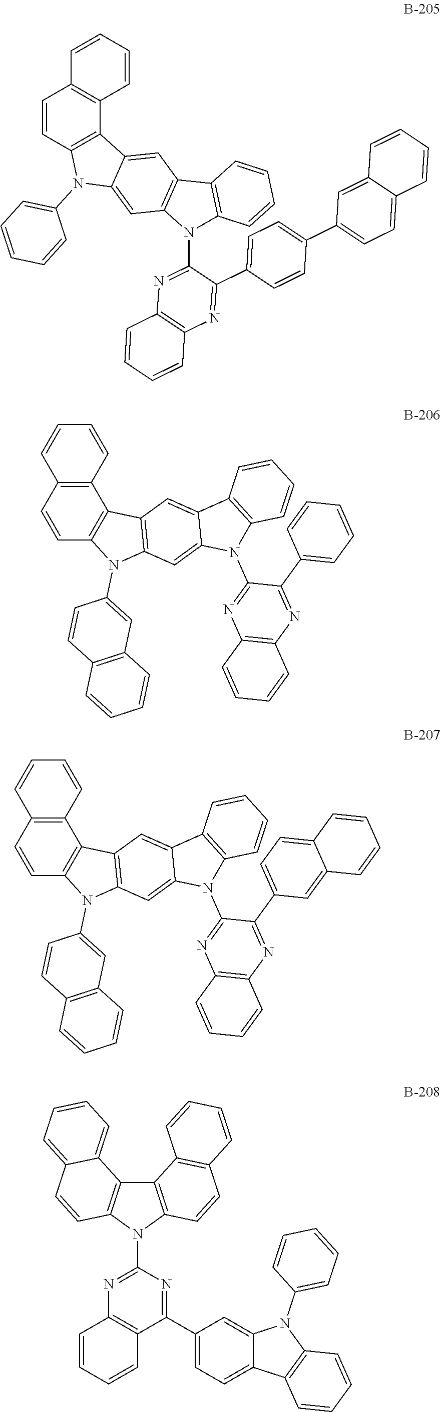 [SMILES: c1ccc(-n2c3cc4c(cc3c3c5ccccc5ccc32)c2ccccc2n4-c2nc3ccccc3nc2-c2ccc(-c3ccc4ccccc4c3)cc2)cc1 ; c1ccc(-c2nc3ccccc3nc2-n2c3ccccc3c3cc4c5c6ccccc6ccc5n(-c5ccc6ccccc6c5)c4cc32)cc1 ; c1ccc2cc(-c3nc4ccccc4nc3-n3c4ccccc4c4cc5c6c7ccccc7ccc6n(-c6ccc7ccccc7c6)c5cc43)ccc2c1 ; c1ccc(-n2c3ccccc3c3ccc(-c4nc(-n5c6ccc7ccccc7c6c6c7ccccc7ccc65)nc5ccccc45)cc32)cc1]

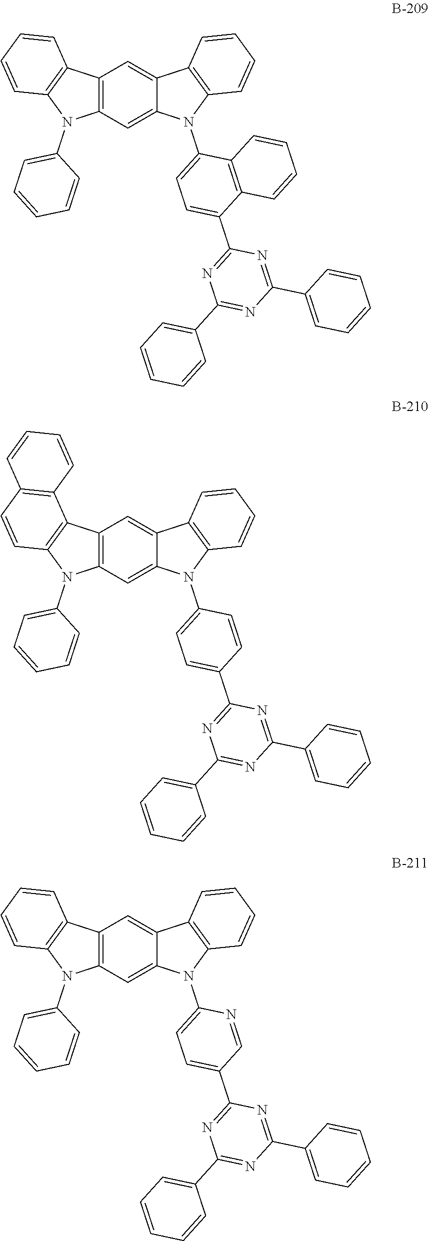 [SMILES: c1ccc(-c2nc(-c3ccccc3)nc(-c3ccc(-n4c5ccccc5c5cc6c7ccccc7n(-c7ccccc7)c6cc54)c4ccccc34)n2)cc1 ; c1ccc(-c2nc(-c3ccccc3)nc(-c3ccc(-n4c5ccccc5c5cc6c7c8ccccc8ccc7n(-c7ccccc7)c6cc54)cc3)n2)cc1 ; c1ccc(-c2nc(-c3ccccc3)nc(-c3ccc(-n4c5ccccc5c5cc6c7ccccc7n(-c7ccccc7)c6cc54)nc3)n2)cc1]

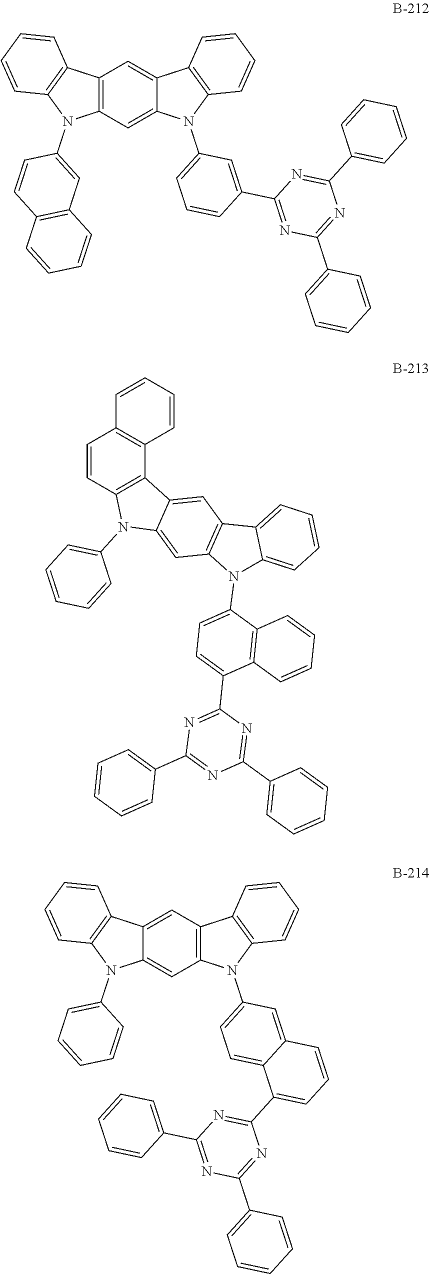 [SMILES: c1ccc(-c2nc(-c3ccccc3)nc(-c3cccc(-n4c5ccccc5c5cc6c7ccccc7n(-c7ccc8ccccc8c7)c6cc54)c3)n2)cc1 ; c1ccc(-c2nc(-c3ccccc3)nc(-c3ccc(-n4c5ccccc5c5cc6c7c8ccccc8ccc7n(-c7ccccc7)c6cc54)c4ccccc34)n2)cc1 ; c1ccc(-c2nc(-c3ccccc3)nc(-c3cccc4cc(-n5c6ccccc6c6cc7c8ccccc8n(-c8ccccc8)c7cc65)ccc34)n2)cc1]

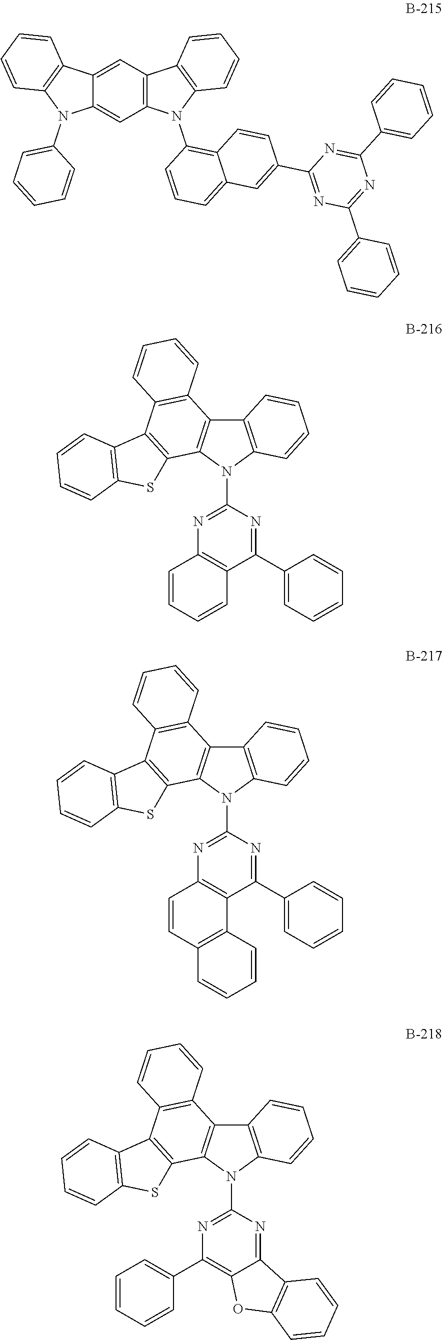 [SMILES: c1ccc(-c2nc(-c3ccccc3)nc(-c3ccc4c(-n5c6ccccc6c6cc7c8ccccc8n(-c8ccccc8)c7cc65)cccc4c3)n2)cc1 ; c1ccc(-c2nc(-n3c4ccccc4c4c5ccccc5c5c6ccccc6sc5c43)nc3ccccc23)cc1 ; c1ccc(-c2nc(-n3c4ccccc4c4c5ccccc5c5c6ccccc6sc5c43)nc3ccc4ccccc4c23)cc1 ; c1ccc(-c2nc(-n3c4ccccc4c4c5ccccc5c5c6ccccc6sc5c43)nc3c2oc2ccccc23)cc1]

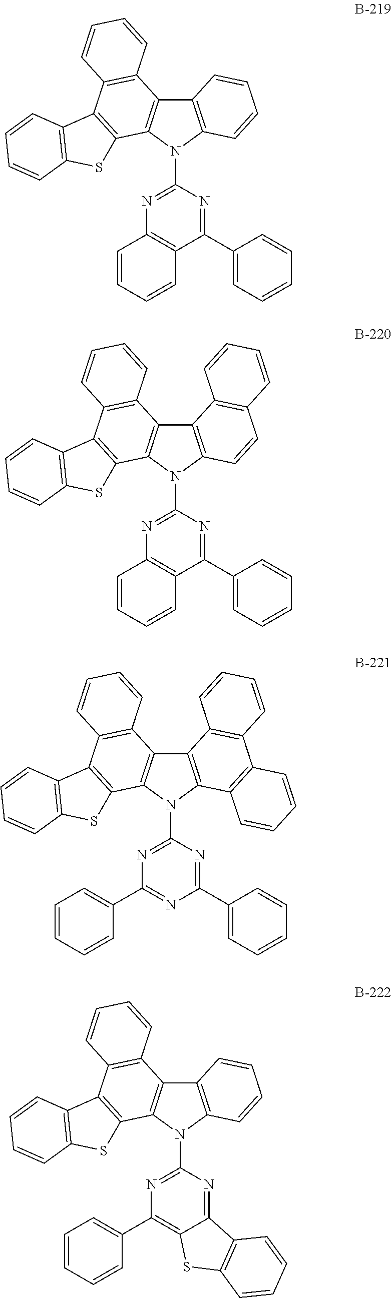 [SMILES: c1ccc(-c2nc(-n3c4ccccc4c4c5ccccc5c5c6ccccc6sc5c43)nc3ccccc23)cc1 ; c1ccc(-c2nc(-n3c4ccc5ccccc5c4c4c5ccccc5c5c6ccccc6sc5c43)nc3ccccc23)cc1 ; c1ccc(-c2nc(-c3ccccc3)nc(-n3c4c5ccccc5c5ccccc5c4c4c5ccccc5c5c6ccccc6sc5c43)n2)cc1 ; c1ccc(-c2nc(-n3c4ccccc4c4c5ccccc5c5c6ccccc6sc5c43)nc3c2sc2ccccc23)cc1]

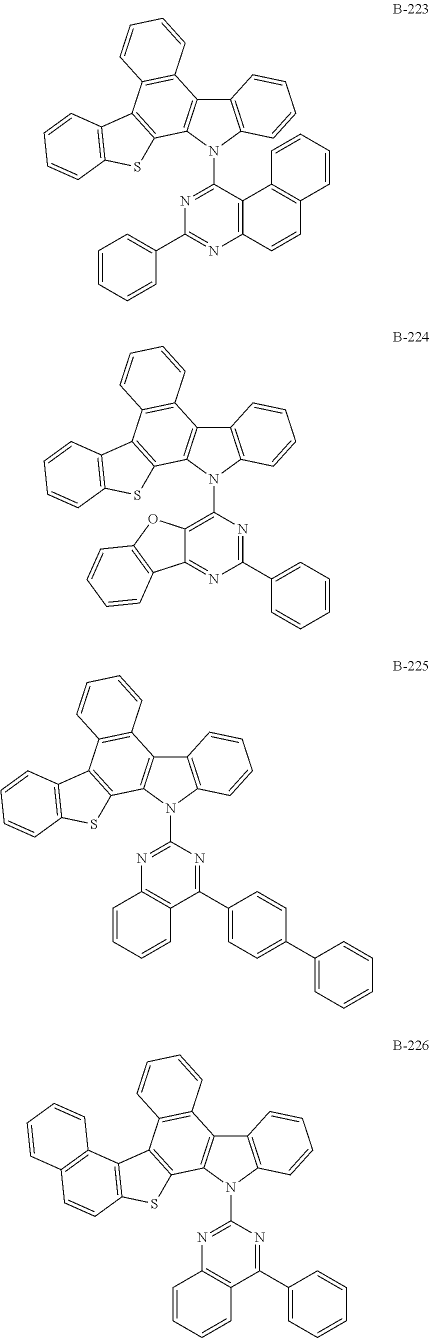 [SMILES: c1ccc(-c2nc(-n3c4ccccc4c4c5ccccc5c5c6ccccc6sc5c43)c3c(ccc4ccccc43)n2)cc1 ; c1ccc(-c2nc(-n3c4ccccc4c4c5ccccc5c5c6ccccc6sc5c43)c3oc4ccccc4c3n2)cc1 ; c1ccc(-c2ccc(-c3nc(-n4c5ccccc5c5c6ccccc6c6c7ccccc7sc6c54)nc4ccccc34)cc2)cc1 ; c1ccc(-c2nc(-n3c4ccccc4c4c5ccccc5c5c(sc6ccc7ccccc7c65)c43)nc3ccccc23)cc1]

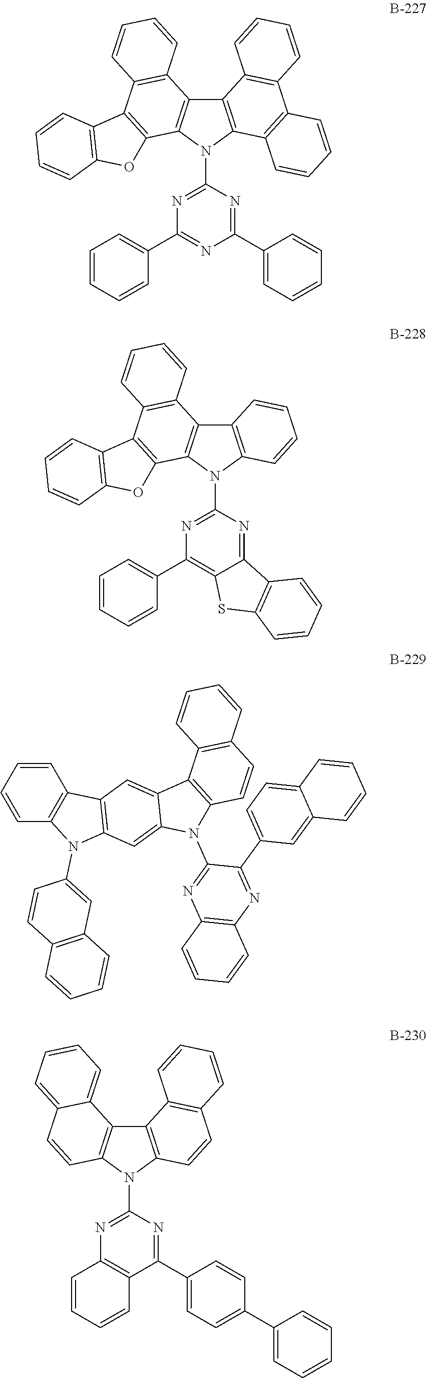 [SMILES: c1ccc(-c2nc(-c3ccccc3)nc(-n3c4c5ccccc5c5ccccc5c4c4c5ccccc5c5c6ccccc6oc5c43)n2)cc1 ; c1ccc(-c2nc(-n3c4ccccc4c4c5ccccc5c5c6ccccc6oc5c43)nc3c2sc2ccccc23)cc1 ; c1ccc2cc(-c3nc4ccccc4nc3-n3c4cc5c(cc4c4c6ccccc6ccc43)c3ccccc3n5-c3ccc4ccccc4c3)ccc2c1 ; c1ccc(-c2ccc(-c3nc(-n4c5ccc6ccccc6c5c5c6ccccc6ccc54)nc4ccccc34)cc2)cc1]

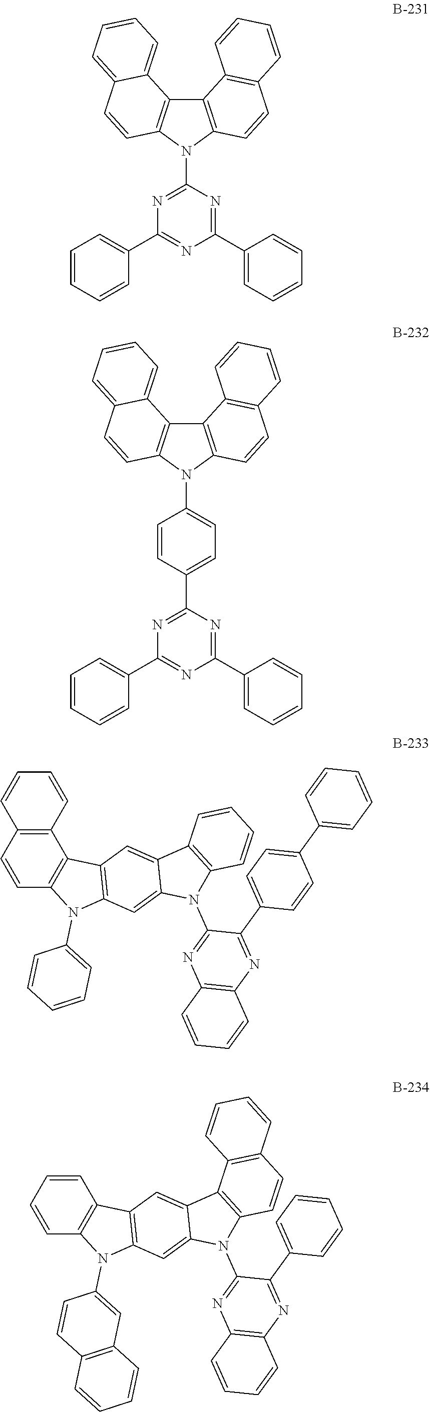 [SMILES: c1ccc(-c2nc(-c3ccccc3)nc(-n3c4ccc5ccccc5c4c4c5ccccc5ccc43)n2)cc1 ; c1ccc(-c2nc(-c3ccccc3)nc(-c3ccc(-n4c5ccc6ccccc6c5c5c6ccccc6ccc54)cc3)n2)cc1 ; c1ccc(-c2ccc(-c3nc4ccccc4nc3-n3c4ccccc4c4cc5c6c7ccccc7ccc6n(-c6ccccc6)c5cc43)cc2)cc1 ; c1ccc(-c2nc3ccccc3nc2-n2c3cc4c(cc3c3c5ccccc5ccc32)c2ccccc2n4-c2ccc3ccccc3c2)cc1]

The compound represented by any one of formulas 2 to 4 of the present disclosure may be produced by a synthetic method known to one skilled in the art, but is not limited thereto.

The organic electroluminescent device of the present disclosure may comprise a first electrode, a second electrode, and at least one organic layer between the first and second electrodes. One of the first and second electrodes may be an anode, and the other may be a cathode. The organic layer may comprise at least one light-emitting layer, and may further comprise at least one layer selected from the group consisting of a hole injection layer, a hole transport layer, a hole auxiliary layer, a light-emitting auxiliary layer, an electron transport layer, an electron buffer layer, an electron injection layer, an interlayer, a hole blocking layer, and an electron blocking layer.

The light-emitting layer is a layer from which light is emitted, and can be a single layer or a multi-layer of which two or more layers are stacked. In the light-emitting layer, it is preferable that the doping concentration of the dopant compound based on the host compound is less than 20 wt %.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. Also, the hole auxiliary layer may be placed between the hole transport layer (or hole injection layer) and the light-emitting layer, and may be effective to promote or block the hole transport rate (or the hole injection rate), thereby enabling the charge balance to be controlled. In addition, the electron blocking layer may be placed between the hole transport layer (or hole injection layer) and the light-emitting layer, and may block overflowing electrons from the light-emitting layer and confine the excitons in the light-emitting layer to prevent light leakage. When an organic electroluminescent device includes two or more hole transport layers, the hole transport layer, which is further included, may be used as a hole auxiliary layer or an electron blocking layer. The light-emitting auxiliary layer, the hole auxiliary layer or the electron blocking layer may have an effect of improving the efficiency and/or the lifespan of the organic electroluminescent device.

According to one embodiment of the present disclosure, the organic layer comprising a combination of at least one compound represented by formula 1 and at least one compound represented by any one of formulas 2 to 4 may be provided. The organic layer may be a single layer or a plurality of layers. The compound represented by formula 1 and the compound represented by any one of formulas 2 to 4 may be comprised in the same layer or different layers, respectively. Also, the present disclosure provides an organic electroluminescent device comprising the organic layer.

According to another embodiment of the present disclosure, the combination of the dopant and the host, which is a combination of at least one dopant compound represented by formula 1 and at least one host compound represented by any one of formulas 2 to 4, may be provided. Also, the present disclosure may provide an organic electroluminescent device comprising the combination of the dopant and the host.

According to a further embodiment of the present disclosure, an organic electroluminescent material comprising a combination of at least one compound represented by formula 1 and at least one compound represented by any one of formulas 2 to 4, and an organic electroluminescent device comprising the material may be provided. The material may consist of only the combination of the compound of formula 1 and the compound of any one of formulas 2 to 4, and may further comprise conventional materials comprised in an organic electroluminescent material.

Also, the organic electroluminescent device of the present disclosure may comprise the compound represented by formula 1, and the compounds represented by any one of formulas 2 to 4, and may further comprise at least one compound selected from the group consisting of arylamine-based compounds and styrylarylamine-based compounds.

In addition, in the organic electroluminescent device of the present disclosure, the organic layer may further comprise at least one metal selected from the group consisting of metals of Group 1, metals of Group 2, transition metals of the 4th period, transition metals of the 5th period, lanthanides and organic metals of d-transition elements of the Periodic Table, or at least one complex compound comprising said metal, besides the compound of formula 1, and the compound of any one of formulas 2 to 4. Further, the organic layer may further comprise a light-emitting layer and a charge generating layer.

Further, the organic electroluminescent device of the present disclosure may emit white light by further including at least one light-emitting layer containing a blue, red or green light-emitting compound, which is known in the art. Also, it may further comprise a yellow or orange light-emitting layer, if necessary.

In the organic electroluminescent device of the present disclosure, at least one layer selected from the group consisting of a chalcogenide layer, a metal halide layer and a metal oxide layer (hereinafter, “a surface layer”) may be preferably placed on an inner surface(s) of one or both electrodes. Specifically, a chalcogenide (including oxides) layer of silicon or aluminum is preferably placed on an anode surface of an electroluminescent medium layer, and a metal halide layer or a metal oxide layer is preferably placed on a cathode surface of an electroluminescent medium layer. Such a surface layer may provide operation stability for the organic electroluminescent device. Preferably, the chalcogenide includes SiO_{X} (1≤X≤2), Al_{X}(1≤X≤1.5), SiON, SiAlON, etc.; the metal halide includes LiF, MgF₂, CaF₂, a rare earth metal fluoride, etc.; and the metal oxide includes Cs₂O, Li₂O, MgO, SrO, BaO, CaO, etc.

In the organic electroluminescent device of the present disclosure, a mixed region of an electron transport compound and a reductive dopant, or a mixed region of a hole transport compound and an oxidative dopant is preferably placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge-generating layer to prepare an organic electroluminescent device having two or more light-emitting layers and emitting white light.

In order to form each layer of the organic electroluminescent device of the present disclosure, dry film-forming methods such as vacuum evaporation, sputtering, plasma and ion plating methods, or wet film-forming methods such as ink jet printing, nozzle printing, slot coating, spin coating, dip coating, and flow coating methods may be used. The dopant and host compounds of the present disclosure may be co-evaporated or mixture-evaporated.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

The co-evaporation is a mixed deposition method in which two or more isomer materials are placed in a respective individual crucible source and a current is applied to both cells at the same time to evaporate the materials. The mixture-evaporation is a mixed deposition method in which two or more isomer materials are mixed in one crucible source before evaporating them, and a current is applied to the cell to evaporate the materials.

Further, a display system or a lighting system can be produced by using the organic electroluminescent device of the present disclosure.

Hereinafter, the synthesis method of the compounds of the present disclosure will be explained in detail with reference to the representative compounds of the present disclosure. However, the present disclosure is not limited by the following examples.

### [Synthesis Example 1] Preparation of Compound C-4

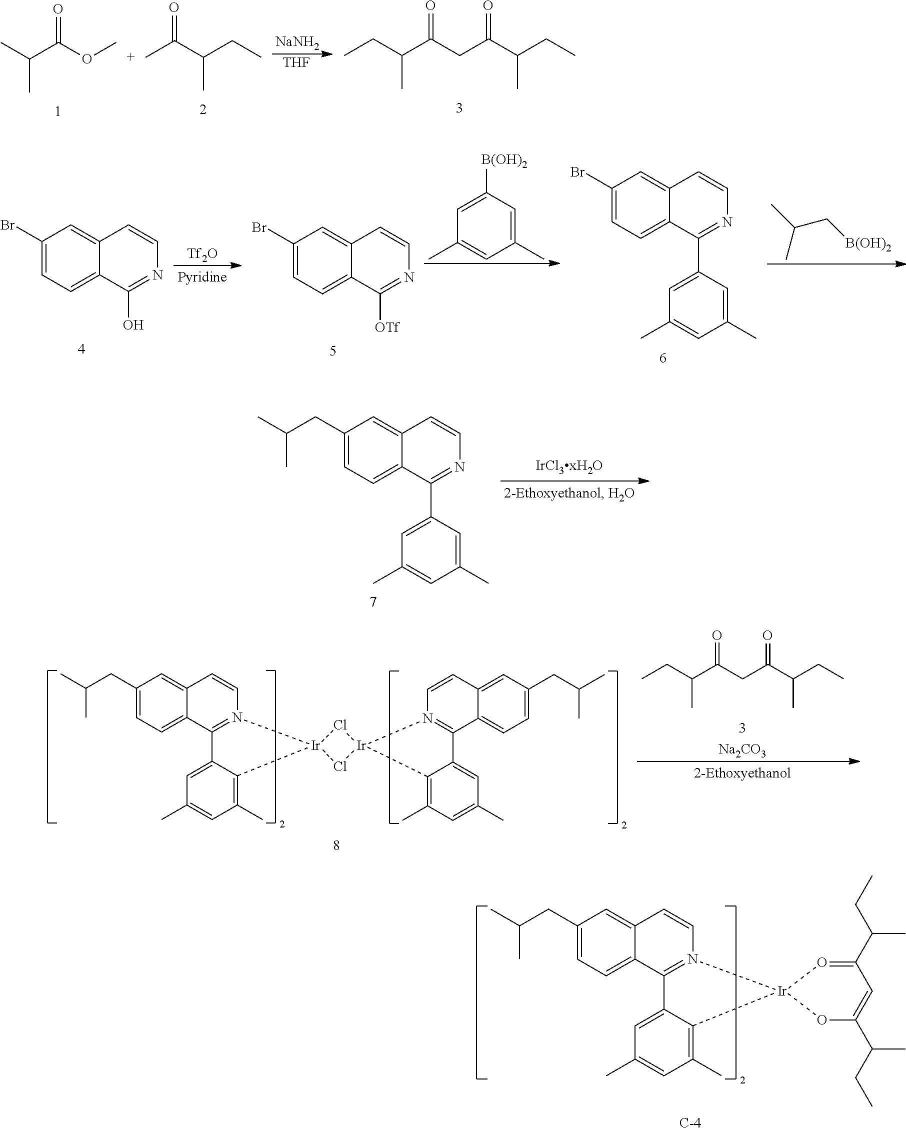

Synthesis of Compound 3

39.43 g of NaNH₂ (1010.88 mmol) was added to a 1 L round bottom flask filled with nitrogen gas, and 202.18 mL of THF (1.0 M) was added slowly, and 40.5 g of compound 2 (404.35 mmol) was slowly added dropwise. After stirring for 30 minutes, 23.48 g of compound 1 (202.18 mmol) was slowly added dropwise, and the mixture was stirred under reflux for 21 hours. After the reaction was completed, the mixture was cooled to room temperature, neutralized with 6 N HCl, extracted with ethyl acetate, and washed with aqueous NaHCO₃ solution. The reaction mixture was purified by column chromatography to obtain 43.7 g of compound 3 (99%).

Synthesis of Compound 5

100 g of compound 4 (446.33 mmol) and 893 mL of pyridine (0.5 M) were added to a 2 L round bottom flask, and the mixture was cooled to 0° C. 157.41 g of Tf₂O (557.91 mmol) was added dropwise and stirred for 4 hours. After the reaction, the reaction mixture was slowly added to a bath containing 3 L of water and stirred. The reaction mixture was filtered and dissolved in CHCl₃, and the aqueous layer was removed. The resulting residue was purified by column chromatography to obtain 152.4 g of compound 5 (96%).

Synthesis of Compound 6

152.4 g of compound 5 (427.95 mmol), 42.79 g of 3,5-dimethylphenylboronic acid (329.19 mmol), 11.41 g of Pd(PPh₃)₄ (9.88 mmol), 82.97 g of NaHCO₃ (987.10 mmol), 1646 mL of THF (0.2 M) and 494 mL of water were added to a 5 L round bottom flask, and the mixture was stirred under reflux at 110° C. After the reaction, the reaction mixture was cooled to room temperature and extracted with MC (dichloromethane). The reaction mixture was purified by column chromatography to obtain 45.5 g of compound 6 (44%).

Synthesis of Compound 7

44.5 g of compound 6 (142.54 mmol), 29.06 g of isobutylboronic acid (285.07 mmol), 148.26 g of K₃PO₄ (698.45 mmol), 4.68 g of S-Phos (11.40 mmol) and 950 mL of toluene (0.15 M) were added to a 2 L round bottom flask, and the mixture was stirred at 130° C. for 30 minutes. 5.22 g of Pd₂(dba)₃ (5.70 mmol) was added and the mixture was stirred under reflux for 3 hours. The reaction mixture was cooled to room temperature and purified by column chromatography to obtain 34.6 g of compound 7 (84%).

Synthesis of Compound 8

34.6 g of compound 7 (119.65 mmol), 16.24 g of IrCl₃.xH₂O (54.39 mmol), 418 mL of 2-ethoxyethanol (0.13 M) and 139.3 mL of H₂O were added to a 1 L round bottom flask under nitrogen, and the mixture was stirred under reflux for 24 hours. The reaction mixture was cooled to room temperature, the solvent was removed to the utmost, 500 mL of water was added, and the mixture was stirred for 30 minutes. The reaction mixture was washed with MeOH and Hexane, and dried to obtain 19.3 g of compound 8 (44%).

Synthesis of Compound C-4

5.0 g of compound 8 (3.11 mmol), 5.73 g of compound 3 (31.08 mmol), 6.59 g of Na₂CO₃ (62.15 mmol), and 52 mL of 2-ethoxyethanol (0.08 M) were added to a 250 mL round bottom flask under nitrogen, and the mixture was stirred at room temperature for 3 days. After the reaction, 330 mL of water was added and stirred for 30 minutes, and then filtered. The reaction mixture obtained after filtration was purified by column chromatography to obtain 2.8 g of compound C-4 (47%).

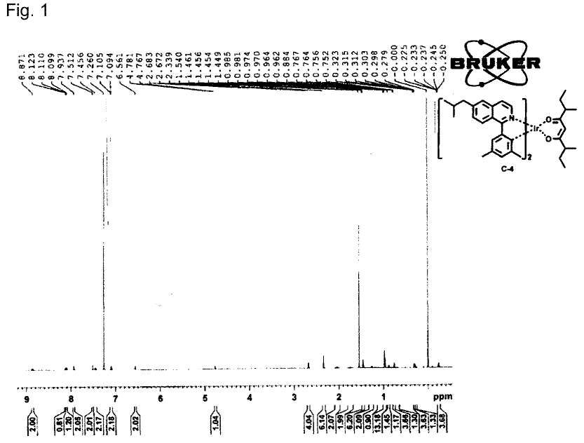

The physical properties and NMR data of compound C-4 prepared as described above are shown in Table 1 and FIG. 1.

TABLE 1

| Compound | MW | UV | PL | M.P. |
|---|---|---|---|---|
| C-4 | 952.32 | 294 nm | 619 nm | 290° C. |

### Synthesis Example 21 Preparation of Compound C-2

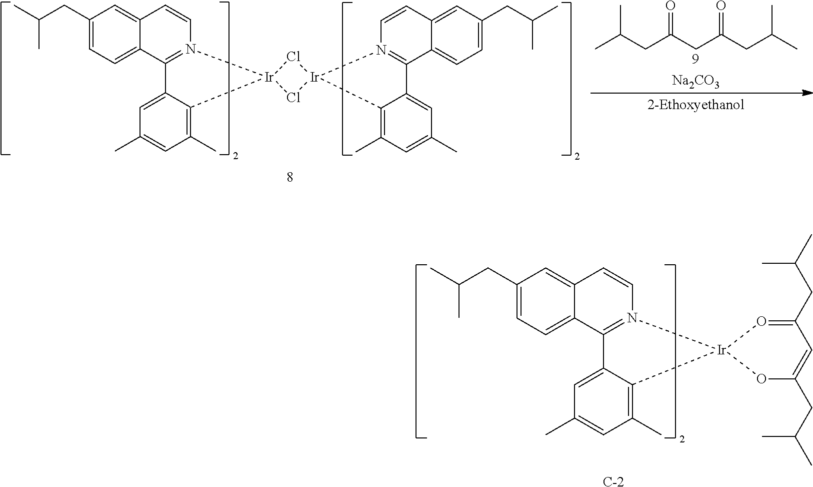

5.0 g of compound 8 (3.11 mmol), 5.73 g of compound 9 (31.08 mmol), 6.59 g of Na₂CO₃ (62.15 mmol), and 52 mL of 2-ethoxyethanol (0.08 M) were added to a 250 mL round bottom flask under nitrogen, and the mixture was stirred at room temperature for 3 days. After the reaction, 330 mL of water was added and stirred for 30 minutes, and then filtered. The reaction mixture obtained after filtration was purified by column chromatography to obtain 2.4 g of compound C-2 (21%).

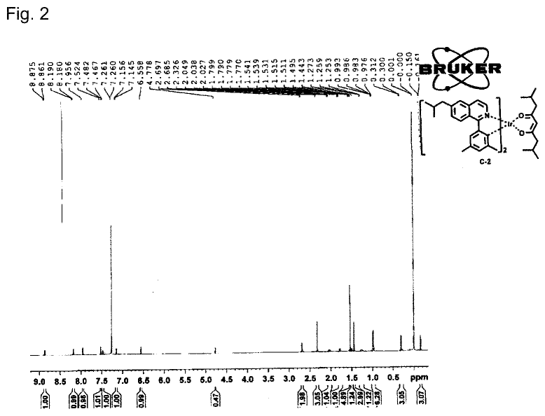

The physical properties and NMR data of compound C-2 prepared as described above are shown in Table 2 and FIG. 2.

TABLE 2

| Compound | MW | UV | PL | M.P. |
|---|---|---|---|---|
| C-2 | 952.32 | 294 nm | 619 nm | 338° C. |

### [Synthesis Example 3] Preparation of Compound C-16

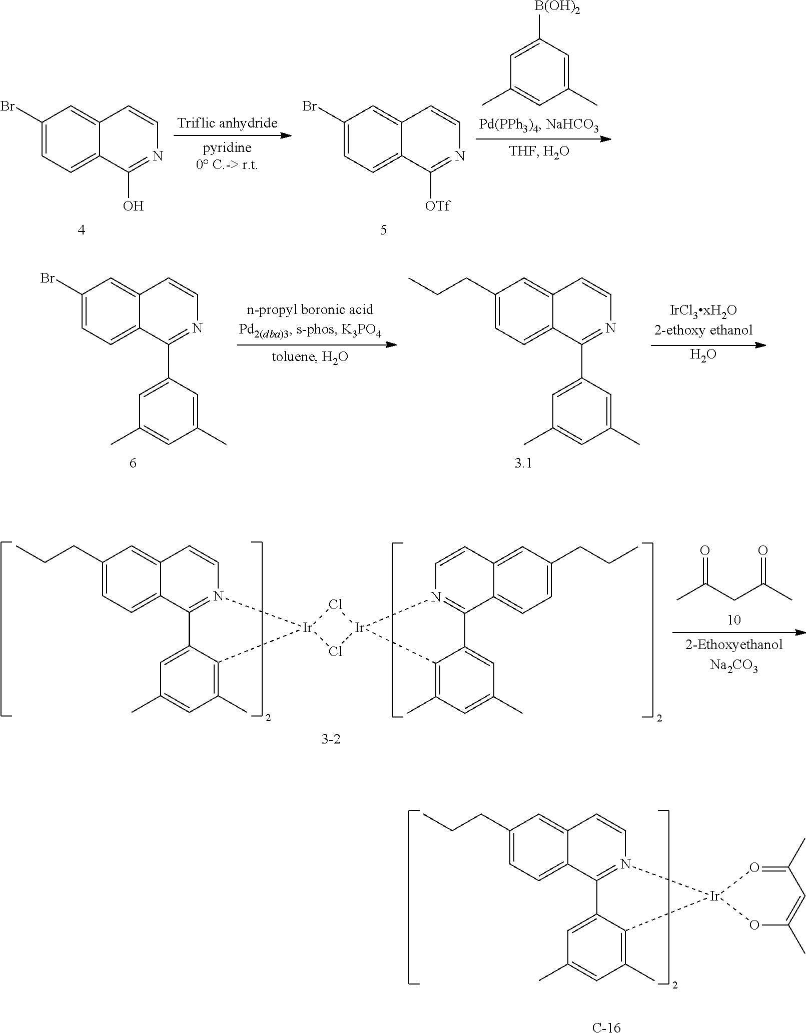

Synthesis of Compound 5

200 g of compound 4 (893 mmol) and 1700 mL of pyridine were added to a 3 L round bottom flask at 0° C., and 188 mL of trifluoromethanesulfonic anhydride (1116 mmol) was slowly added dropwise thereto, and then the mixture was stirred at room temperature for 20 hours. The reaction mixture was added dropwise to H₂O, and the solid was filtered and purified by column chromatography to obtain 289 g of compound 5 (90%).

Synthesis of Compound 6

331.4 g of compound 5 (930 mmol), 107.4 g of 3,5-dimethylphenylboronic acid (720 mmol), 25 g of Pd(PPh₃)₄ (22 mmol), and 181 g of NaHCO₃ (2160 mmol) were added to 3600 mL of THF and 1200 mL of H₂O, and the mixture was stirred under reflux for 20 hours. After completion of the reaction, the reaction mixture was cooled to room temperature and extracted with MC, and then treated with MgSO₄. The reaction mixture was purified by column chromatography to obtain 49 g of compound 6 (23%).

Synthesis of Compound 3-1

20 g of compound 6 (64.06 mmol), 11.26 g of n-propylboronic acid (128.12 mmol), 2.35 g of Pd₂(dba)₃ (2.56 mmol), 2.10 g of s-phos (5.12 mmol), 66.63 g of K₃PO₄ (313.89 mmol) and 427 mL of toluene were added to a 1 L round bottom flask, and the mixture was stirred under reflux for 3 hours. The reaction mixture was extracted with ethyl acetate and treated with MgSO₄. The reaction mixture was purified by column chromatography to obtain 13.5 g of compound 3-1 (77%).

Synthesis of Compound 3-2

13.5 g of compound 3-1 (49.02 mmol), 6.66 g of IrCl₃.xH₂O (22.28 mmol), 170 mL of 2-ethoxyethanol (0.13 M) and 57 mL of H₂O were added to a 500 mL round bottom flask under nitrogen, and the mixture was stirred under reflux for 24 hours. The reaction mixture was cooled to room temperature, the solvent was removed to the utmost, 500 mL of water was added, and the mixture was stirred for 30 minutes. The reaction mixture was washed with MeOH and Hexane and dried to obtain 9.2 g of compound 3-2 (53%).

Synthesis of Compound C-16

4.5 g of compound 3-2 (2.90 mmol), 3 mL of compound 10 (29.00 mmol), 3.0 g of Na₂CO₃ (29.00 mmol), and 36 mL of 2-ethoxyethanol (0.08 M) were added to a 100 mL round bottom flask under nitrogen, and the mixture was stirred at room temperature for 24 hours. After the reaction, 100 mL of water was added stirred for 30 minutes, and then filtered. The reaction mixture obtained after filtration was purified by column chromatography to obtain 3.4 g of compound C-16 (70%).

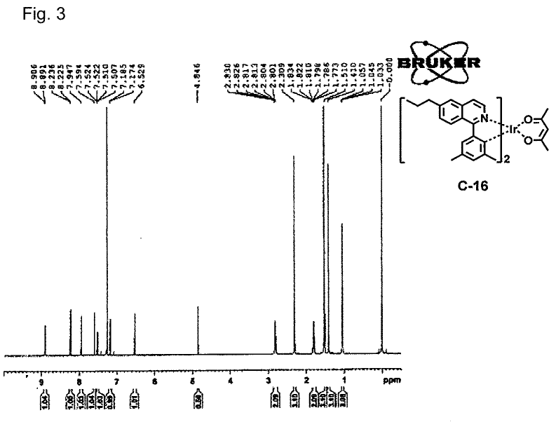

The physical properties and NMR data of compound C-16 prepared as described above are shown in Table 3 and FIG. 3.

TABLE 3

| Compound | MW | UV | PL | M.P. |
|---|---|---|---|---|
| C-16 | 840.08 | 294 nm | 619 nm | 380° C. |

### [Synthesis Example 4] Preparation of Compound C-21

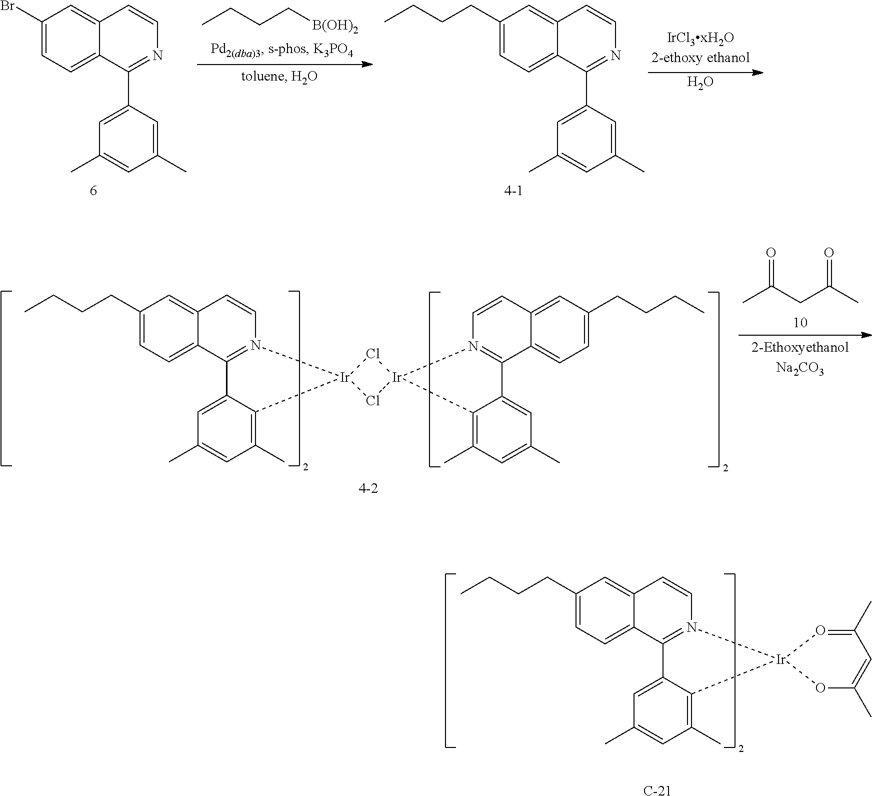

Synthesis of Compound 4-1

9 g of compound 6 (28.83 mmol), 5.88 g of n-butyl boronic acid (57.66 mmol), 1.06 g of Pd₂(dba)₃ (1.15 mmol), 0.95 g of s-phos (2.31 mmol), 30 g of K₃PO₄ (141.27 mmol) and 192 mL of toluene were added to a 500 mL round bottom flask, and the mixture was stirred under reflux for 1 hour. The reaction mixture was extracted with ethyl acetate and treated with MgSO₄. The reaction mixture was purified by column chromatography to obtain 7.6 g of compound 4-1 (92%).

Synthesis of Compound 4-2

7.6 g of compound 4-1 (26.26 mmol), 3.57 g of IrCl₃.xH₂O (11.94 mmol), 92 mL of 2-ethoxyethanol (0.13 M) and 30 mL of H₂O were added to a 250 mL round bottom flask under nitrogen, and the mixture was stirred under reflux for 24 hours. The reaction mixture was cooled to room temperature, the solvent was removed to the utmost, 500 mL of water was added, and the mixture was stirred for 30 minutes. The reaction mixture was washed with MeOH and Hexane and dried to obtain 5.8 g of compound 4-2 (60%).

Synthesis of Compound C-21

5.8 g of compound 4-2 (3.60 mmol), 3.7 mL of compound 10 (36.05 mmol), 3.8 g of Na₂CO₃ (36.05 mmol), and 45 mL of 2-ethoxyethanol (0.08 M) were added to a 100 mL round bottom flask under nitrogen, and the mixture was stirred at room temperature for 24 hours. After the reaction, 100 mL of water was added and stirred for 30 minutes, and then filtered. The reaction mixture obtained after filtration was purified by column chromatography to obtain 0.4 g of compound C-21 (6%).

The physical properties of compound C-21 prepared as described above are shown in Table 4 below.

TABLE 4

| Compound | MW | UV | PL | M.P. |
|---|---|---|---|---|
| C-21 | 868.14 | 246 nm | 623 nm | 345° C. |

### [Synthesis Example 5] Preparation of Compound C-1

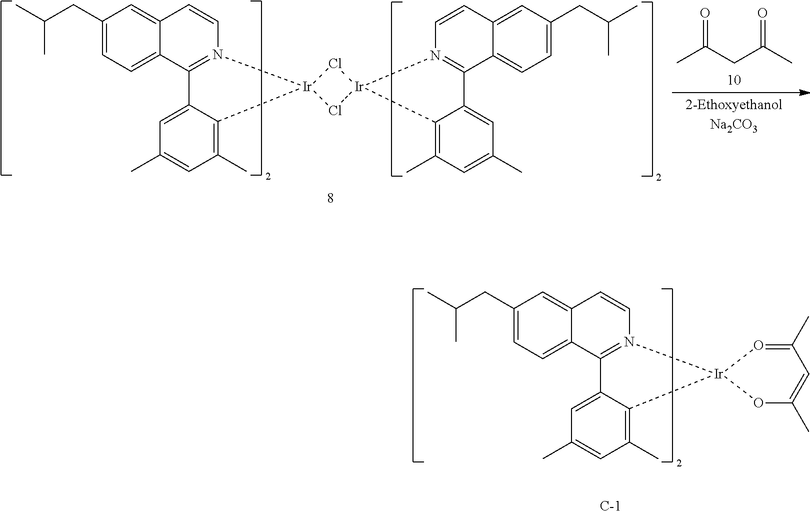

3 g of compound 8 (1.87 mmol), 3.44 g of compound 10 (18.65 mmol), 3.95 g of Na₂CO₃ (37.29 mmol) and 31.2 mL of 2-ethoxyethanol (0.08 M) were added to a 250 mL round bottom flask under nitrogen, and the mixture was stirred at room temperature for 3 days. After the reaction, 200 mL of water was added and stirred for 30 minutes, and then filtered. The reaction mixture obtained after filtration was purified by column chromatography to obtain 1.3 g of compound C-1 (20%).

The physical properties of compound C-1 prepared as described above are shown in Table 5 below.

TABLE 5

| Compound | MW | UV | PL | M.P. |
|---|---|---|---|---|
| C-1 | 868.15 | 244 nm | 623 nm | 390° C. |

Hereinafter, the properties of the organic light-emitting diode (OLED) device comprising the compound of the present disclosure will be explained in detail, but is not limited by the following examples.

### Comparative Examples 1 to 6: Producing a Red Phosphorescent OLED Device Comprising a Conventional Compound as a Dopant

As a comparative example of the present disclosure, an OLED device comprising a conventional red phosphorescent organic electroluminescent material was produced as follows: A transparent electrode indium tin oxide (ITO) thin film (10 Ω/sq) on a glass substrate for an OLED (GEOMATEC CO., LTD., Japan) was subjected to an ultrasonic washing with acetone, ethanol and distilled water, sequentially, and then was stored in isopropanol. Next, the ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10⁻⁶ torr. Thereafter, an electric current was applied to the cell to evaporate the introduced material, thereby forming a first hole injection layer having a thickness of 90 nm on the ITO substrate. Compound HI-2 was then introduced into another cell of the vacuum vapor deposition apparatus, and an electric current was applied to the cell to evaporate the introduced material, thereby forming a second hole injection layer having a thickness of 5 nm on the first hole injection layer. Compound HT-1 was introduced into another cell of the vacuum vapor deposition apparatus. Thereafter, an electric current was applied to the cell to evaporate the introduced material, thereby forming a first hole transport layer having a thickness of 10 nm on the second hole injection layer. Compound HT-2 was then introduced into another cell of the vacuum vapor deposition apparatus, and an electric current was applied to the cell to evaporate the introduced material, thereby forming a second hole transport layer having a thickness of 60 nm on the first hole transport layer. After forming the hole injection layers and the hole transport layers, a light-emitting layer was then deposited as follows. Compound B-109 as a host was introduced into one cell of the vacuum vapor deposition apparatus and any one of the following compounds 0-1 to D-6 as a dopant was introduced into another cell of the apparatus. The two materials were evaporated at a different rate and the dopant was deposited in a doping amount of 2 wt %, based on the total weight of the host and dopant, to form a light-emitting layer having a thickness of 40 nm on the second hole transport layer. Compound ET-1 and compound EI-1 were then introduced into the other two cells and evaporated at a rate of 1:1 to form an electron transport layer having a thickness of 35 nm on the light-emitting layer. After depositing compound EI-1 as an electron injection layer having a thickness of 2 nm on the electron transport layer, an Al cathode having a thickness of 80 nm was deposited by another vacuum vapor deposition apparatus on the electron injection layer. Thus, an OLED device was produced.

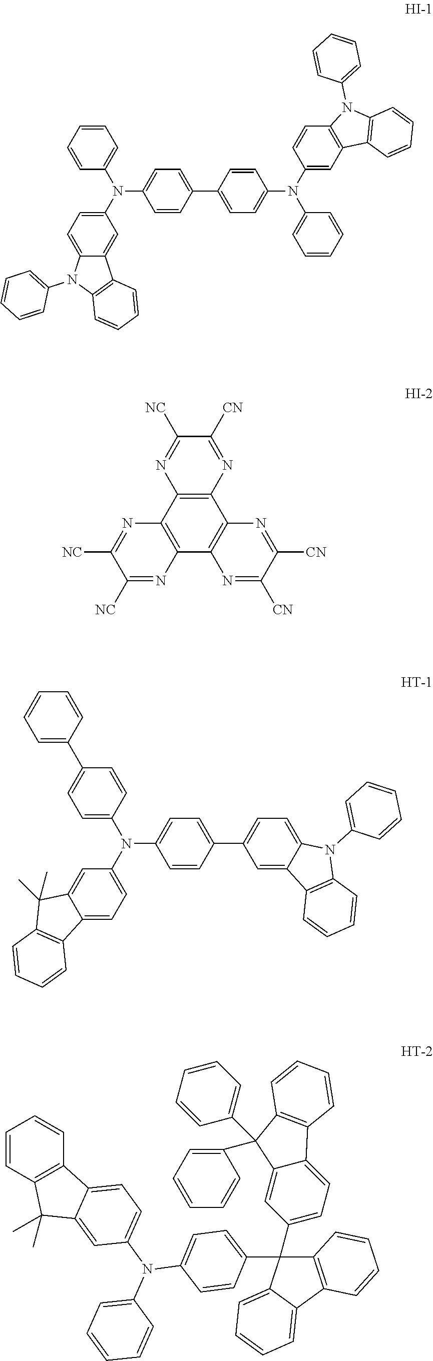 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; N#Cc1nc2c3nc(C#N)c(C#N)nc3c3nc(C#N)c(C#N)nc3c2nc1C#N ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(C4(c5ccc6c(c5)C(c5ccccc5)(c5ccccc5)c5ccccc5-6)c5ccccc5-c5ccccc54)cc3)cc21]

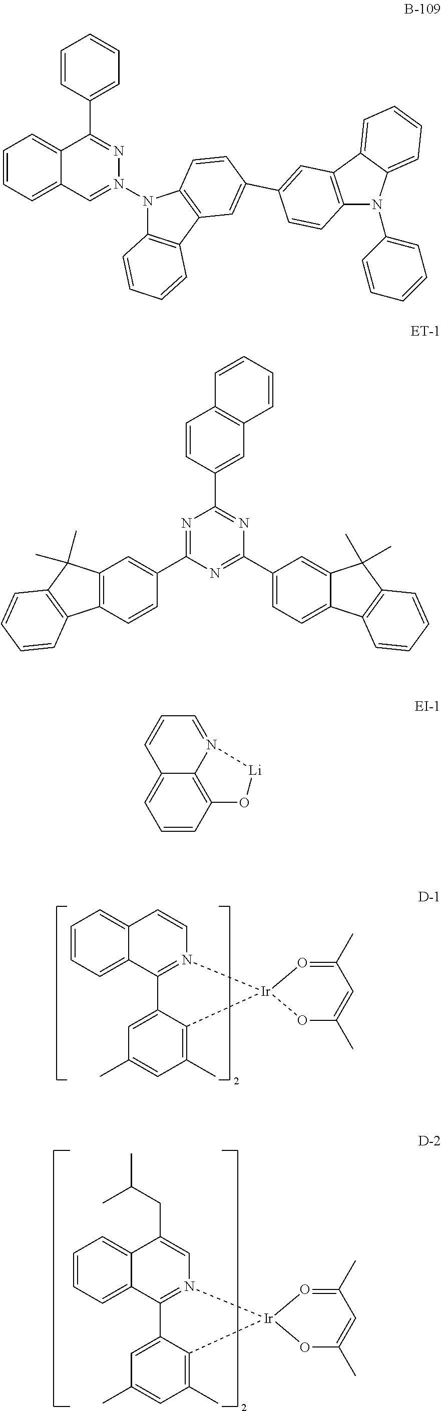

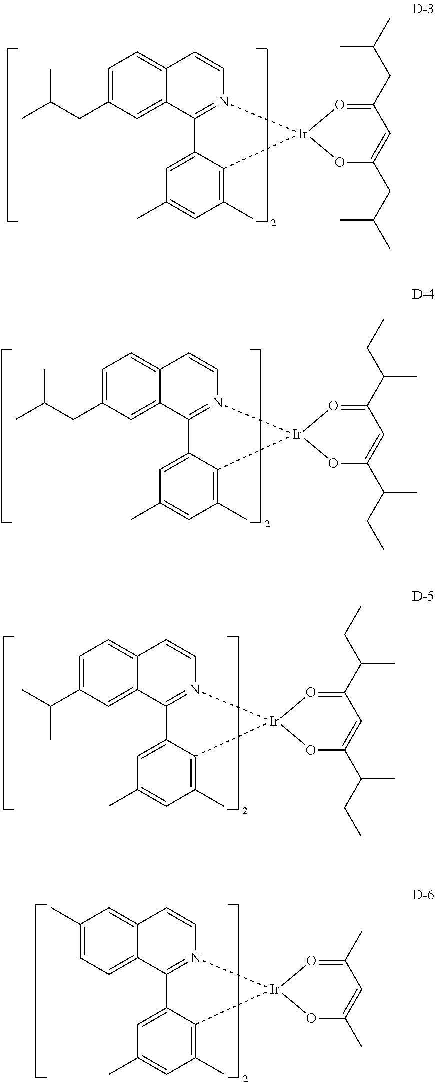

### Device Examples 1 to 6: Producing a Red Phosphorescent OLED Device Comprising a Compound According to the Present Disclosure as a Dopant

An OLED device was produced in the same manner as in Comparative Examples 1 to 6, except that compound C-4, compound C-2, compound C-1, compound C-16, compound C-21, and compound C-5 according to the present disclosure were used respectively as a dopant.

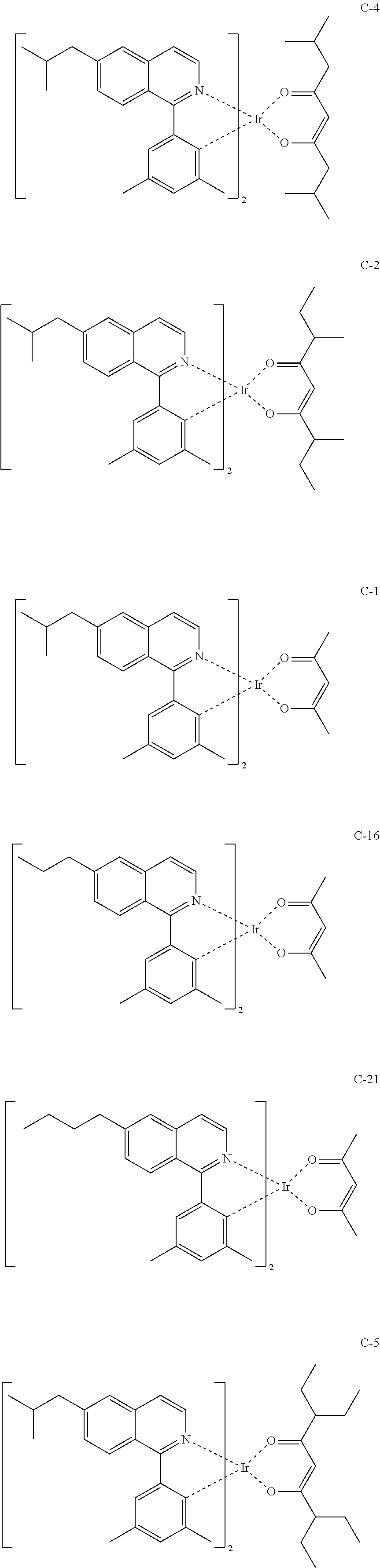

The results of the driving voltage, the luminous efficiency and the X and Y values of the CIE 1931 colorimetric system, which were measured by applying a voltage using a luminance meter (CS-100) manufactured by KONICA MINOLTA, based on 1,000 nits luminance of the red phosphorescent OLED device produced as described above are shown in Table 6 below.

TABLE 6

| | | | Driving | Current | | |
|---|---|---|---|---|---|---|
| | | | Voltage | Efficiency | CIE | |
| Item | Host | Dopant | [V] | [cd/A] | X | Y |
| Comparative | B-109 | D-1 | 4.6 | 13.6 | 0.696 | 0.301 |
| Example 1 | | | | | | |
| Comparative | B-109 | D-2 | 4.7 | 12.8 | 0.699 | 0.299 |
| Example 2 | | | | | | |
| Comparative | B-109 | D-3 | 4.3 | 18.0 | 0.693 | 0.305 |
| Example 3 | | | | | | |
| Comparative | B-109 | D-4 | 4.4 | 19.6 | 0.695 | 0.303 |
| Example 4 | | | | | | |
| Comparative | B-109 | D-5 | 4.4 | 18.7 | 0.697 | 0.302 |
| Example 5 | | | | | | |
| Comparative | B-109 | D-6 | 4.4 | 19.0 | 0.690 | 0.309 |
| Example 6 | | | | | | |
| Device | B-109 | C-4 | 4.2 | 22.5 | 0.690 | 0.309 |
| Example 1 | | | | | | |
| Device | B-109 | C-2 | 4.2 | 22.6 | 0.690 | 0.309 |
| Example 2 | | | | | | |
| Device | B-109 | C-1 | 4.3 | 21.4 | 0.690 | 0.309 |
| Example 3 | | | | | | |
| Device | B-109 | C-16 | 4.3 | 20.9 | 0.690 | 0.309 |
| Example 4 | | | | | | |
| Device | B-109 | C-21 | 4.3 | 21.2 | 0.690 | 0.309 |
| Example 5 | | | | | | |
| Device | B-109 | C-5 | 4.3 | 23.2 | 0.691 | 0.308 |
| Example 6 | | | | | | |

From Table 6, it can be confirmed that although the OLED devices (Device Examples 1 to 6) using the compound of the present disclosure, wherein the 6-position of isoquinoline in the ligand of the iridium (Ir) complex is substituted with a specific alkyl group according to the present disclosure, as a dopant, has an X value of the CIE 1931 colorimetric system equivalent to or at a similar level to the OLED devices (Comparative Examples 1 to 6) using a conventional compound as a dopant, the OLED devices according to the present disclosure exhibit low driving voltage and high current efficiency, thereby exhibiting a high luminance efficiency while realizing a deep red color.

From Table 6, it can also be confirmed that the current efficiencies of Device Examples 4 and 5 comprising compound C-16, in which R₁ in formula 1 is a n-propyl, or compound C-21, in which R₁ is a n-butyl, are increased by about 10% to 15% compared to that of Comparative Example 6 comprising the conventional compound D-6, in which R₁ is methyl. Also, it can be confirmed that the current efficiency of Device Example 5 comprising compound C-21, in which R₁ is a n-butyl, is higher than that of Device Example 4 comprising compound C-16, in which R₁ is a n-propyl. From this, it can be seen that the OLED device comprising the compound in which R₁ in formula 1 is a long-chain alkyl can exhibit high luminous efficiency properties while realizing a deep red color.

The three-dimensional structures of all materials were determined by performing structural optimization using the calculation method B3LYP/6-31 g*, and the Gaussian16 program was used. The distance between the atoms was calculated by using the three-dimensional coordinates of the determined structure, and the distance between the two atoms with the greatest distance was designated as x. After setting a two-dimensional plane in a direction perpendicular to a straight line passing through the two atoms forming x, all atoms were projected on the two-dimensional plane to obtain two-dimensional coordinates, and then the distance between the two atoms was obtained, where the distance between the two atoms with the greatest distance was designated as y. The values of x, y, and x/y of the compounds used as a dopant in the Device Examples and the Comparative Examples above, and compound T-1 were calculated and shown in Table 7 below, where x/y is a length characteristic in a specific direction.

TABLE 7

| | Aspect Ratio | | |
|---|---|---|---|
| | Simulation | | |
| Compound # | x [Å] | y [Å] | x/y |
| C-4 | 23.06 | 13.24 | 1.74 |
| C-2 | 23.06 | 13.40 | 1.72 |
| C-1 | 23.06 | 11.39 | 2.02 |
| C-21 | 24.92 | 11.61 | 2.15 |
| C-5 | 23.06 | 13.38 | 1.72 |
| D-1 | 16.11 | 11.86 | 1.36 |
| D-2 | 16.09 | 13.14 | 1.22 |
| D-3 | 21.49 | 12.95 | 1.66 |
| D-4 | 21.52 | 12.77 | 1.69 |
| D-5 | 19.40 | 12.61 | 1.54 |
| D-6 | 18.14 | 11.61 | 1.56 |
| 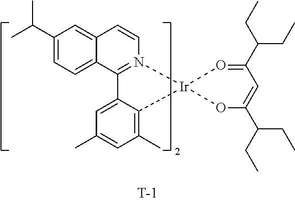 | 20.81 | 13.79 | 1.51 |

From Tables 6 and 7, it can be confirmed that the higher the x (horizontal direction) or x/y value, the higher the efficiency. In addition, it can be also confirmed that the case where an alkyl group having 4 or more carbons is substituted in the 6-position of isoquinoline shows the best efficiency. Specifically, it can be confirmed that only the compound with x greater than 22 and x/y greater than 1.7 by having an alkyl group of 4 or more carbons in the 6-position of isoquinoline shows a high efficiency of 20 cd/A or more. That is, compound T-1, the comparative compound, has the same structure as compound C-5, the compound of the present disclosure, except for the alkyl having three carbons. Since x of compound T-1 does not reach 22, it is expected that the OLED comprising compound T-1 cannot achieve high efficiency of 20 cd/A or more in the device structure above.

1. An organic electroluminescent compound represented by the following formula 1, wherein an organic electroluminescent device comprising the organic electroluminescent compound represents a deep red color: 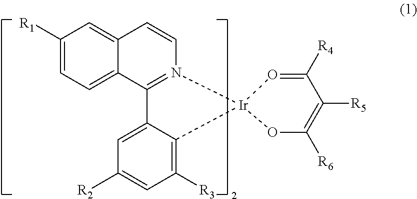
wherein
R₁ represents a substituted or unsubstituted (C4-C6)alkyl,
R₂ and R₃, each independently, represent a substituted or unsubstituted (C1-C5)alkyl, and
R₄ to R₆, each independently, represent hydrogen, deuterium, a substituted or unsubstituted (C1-C5)alkyl, or a substituted or unsubstituted (C5-C30)aryl; or are linked to an adjacent substituent to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom selected from the group consisting of nitrogen, oxygen, and sulfur.

2. The organic electroluminescent compound according to claim 1,
wherein the organic electroluminescent device comprising the organic electroluminescent compound represents an X value of 0.68 or more in the CIE 1931 colorimetric system.

3. The organic electroluminescent compound according to claim 1,
wherein
R₁ represents a (C4-C6)alkyl unsubstituted or substituted with deuterium, and
R₂ and R₃, each independently, represent (C1-C5)alkyl unsubstituted or substituted with deuterium.

4. The organic electroluminescent compound according to claim 1,
wherein
the (C4-C6)alkyl is any one selected from the group consisting of n-butyl, isobutyl, sec-butyl, tert-butyl, n-pentyl, tert-pentyl, neopentyl, isopentyl, sec-pentyl and 3-pentyl, and
the (C1-C5)alkyl is any one selected from the group consisting of methyl, ethyl, n-propyl, isopropyl, n-butyl, isobutyl, sec-butyl, tert-butyl, n-pentyl, tert-pentyl, neopentyl, isopentyl, sec-pentyl and 3-pentyl.

5. The organic electroluminescent compound according to claim 1,
wherein
the structure of 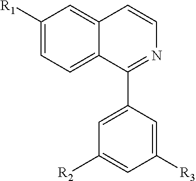
in the formula 1 represents any one selected from the group consisting of:

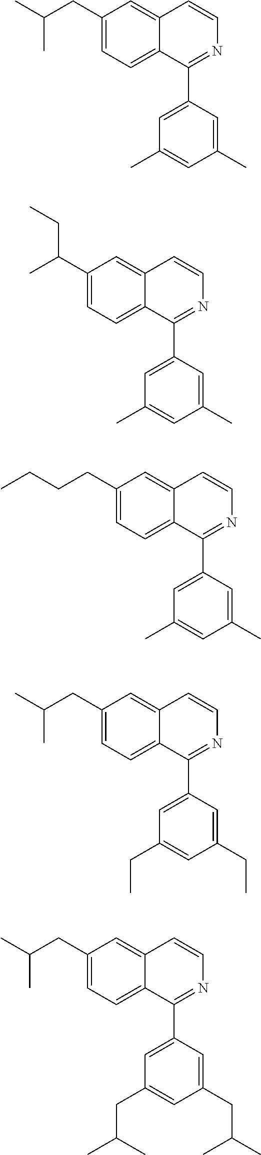

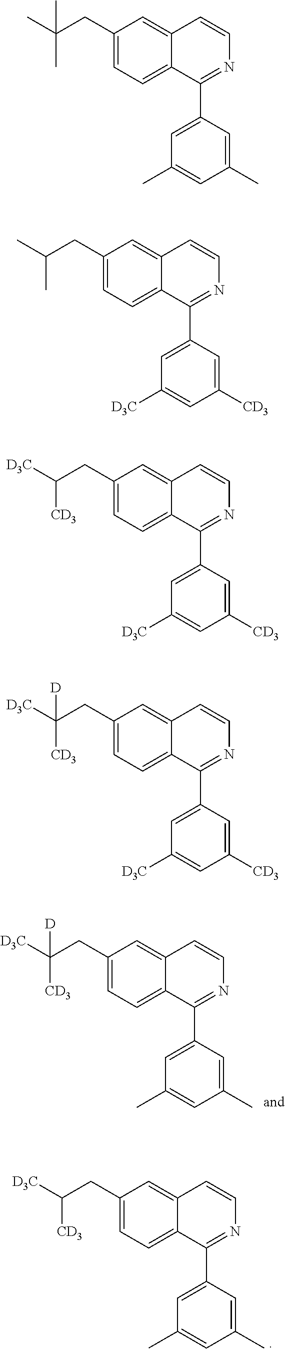

6. The organic electroluminescent compound according to claim 1,
wherein
the structure of 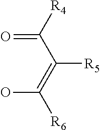
in the formula 1 represents any one selected from the group consisting of:

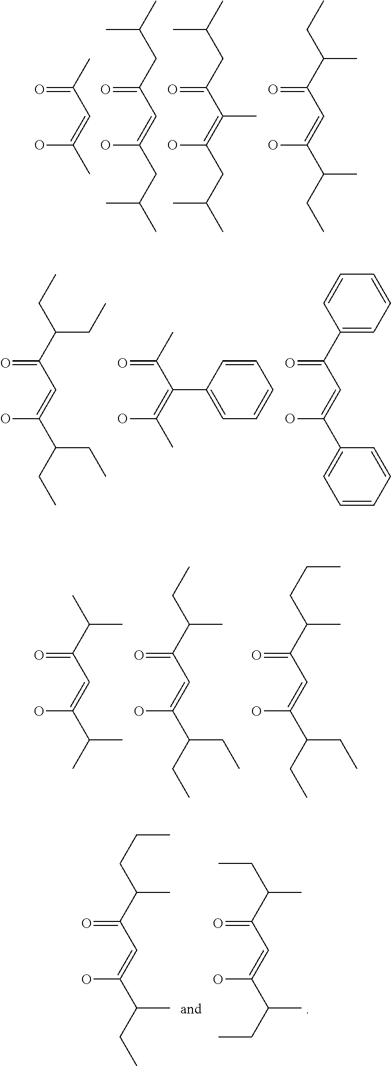

7. The organic electroluminescent compound according to claim 1,
wherein the compound represented by formula 1 is selected from the group consisting of:

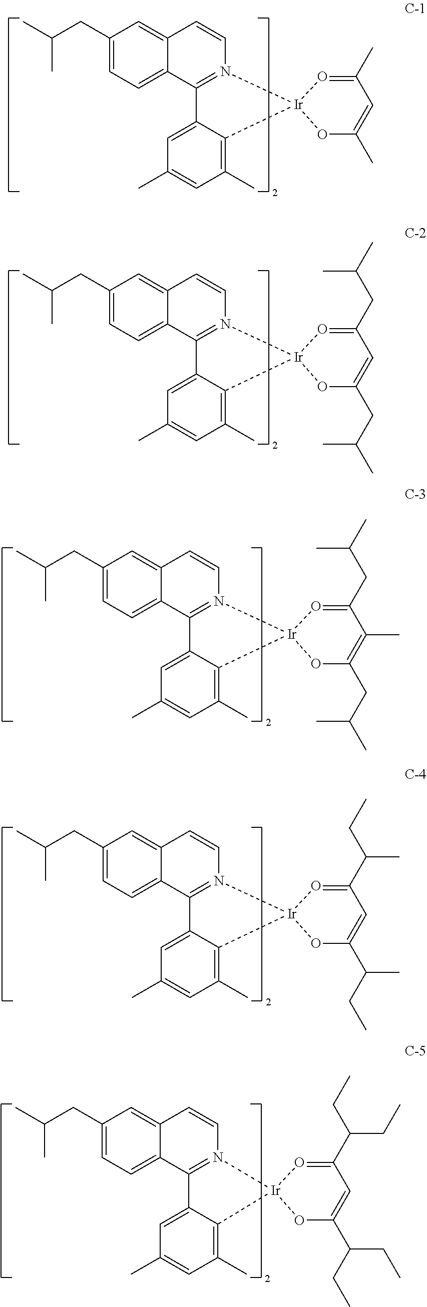

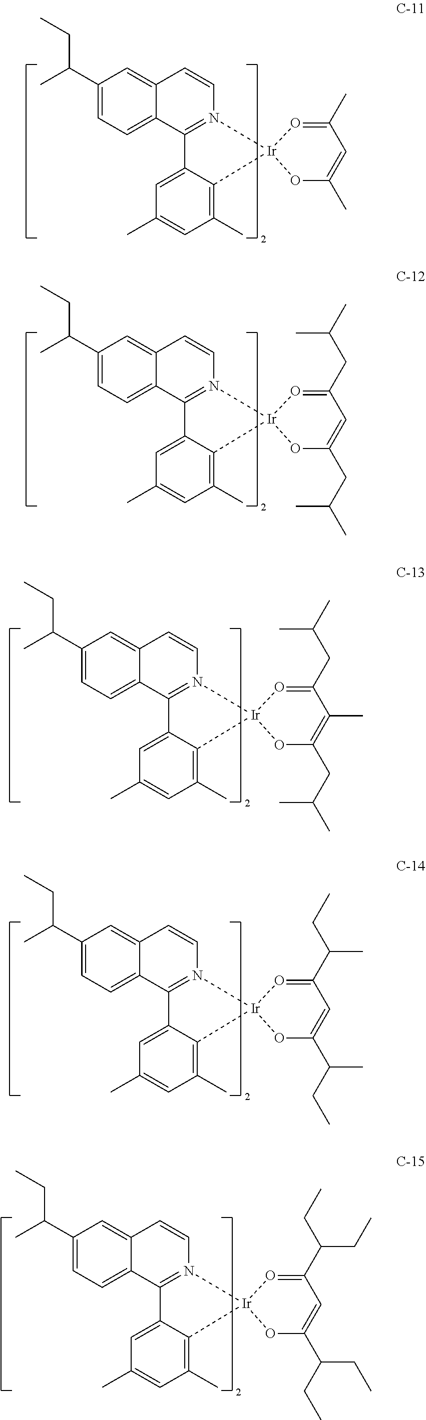

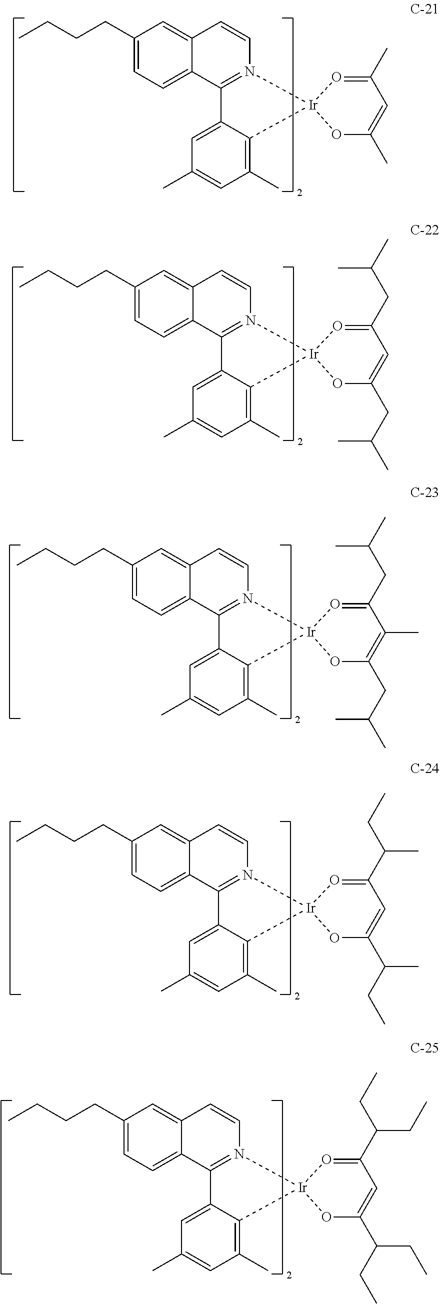

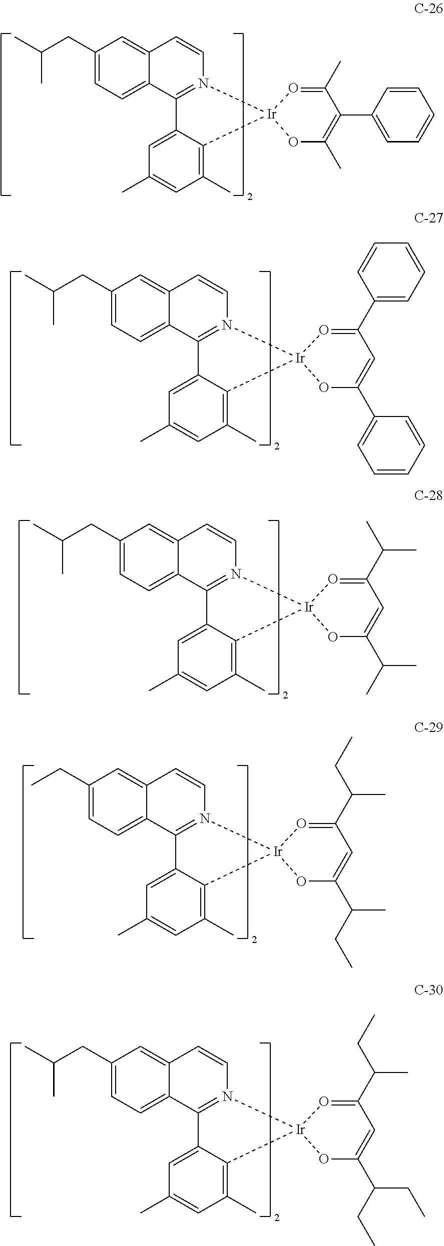

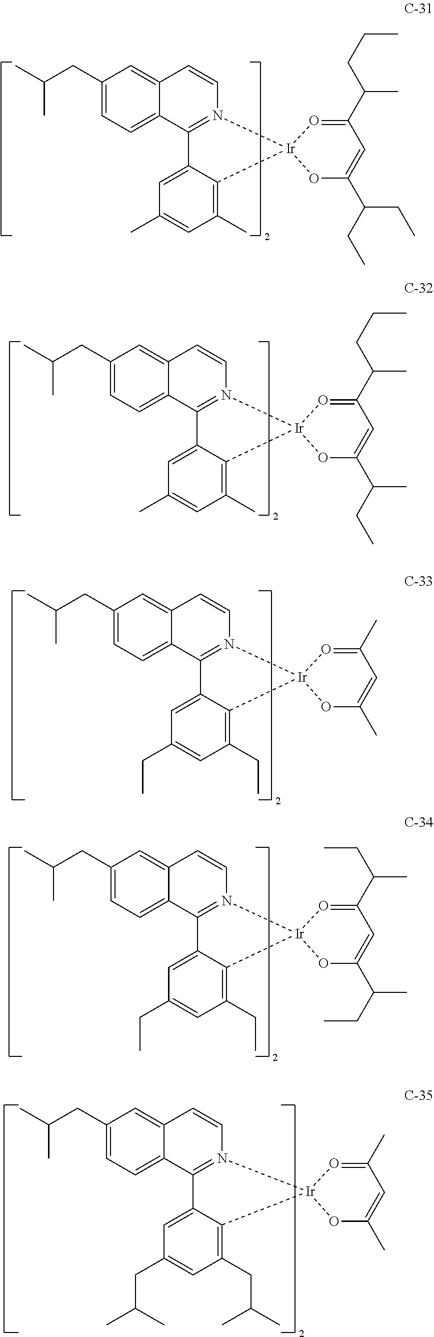

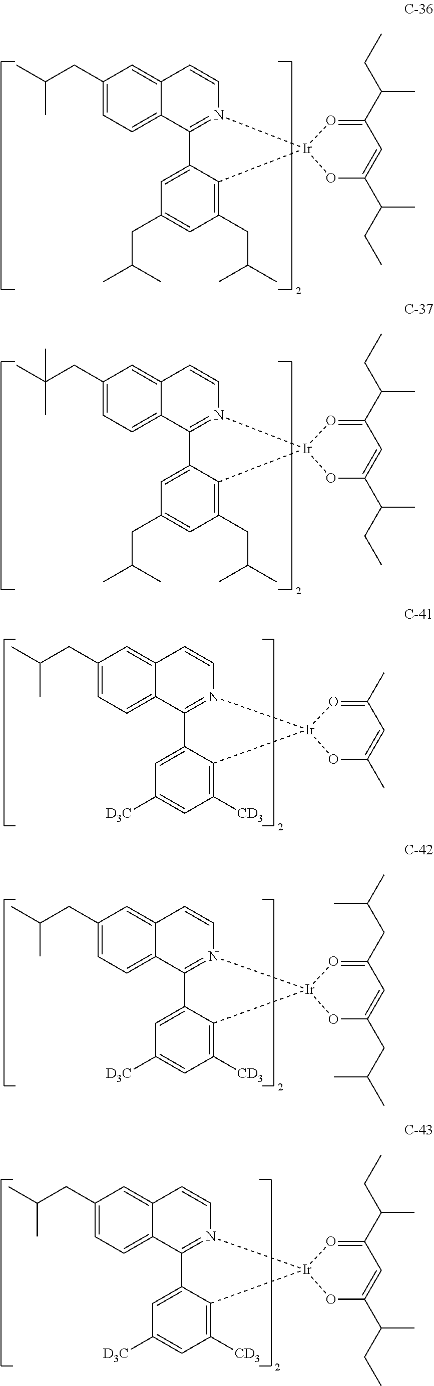

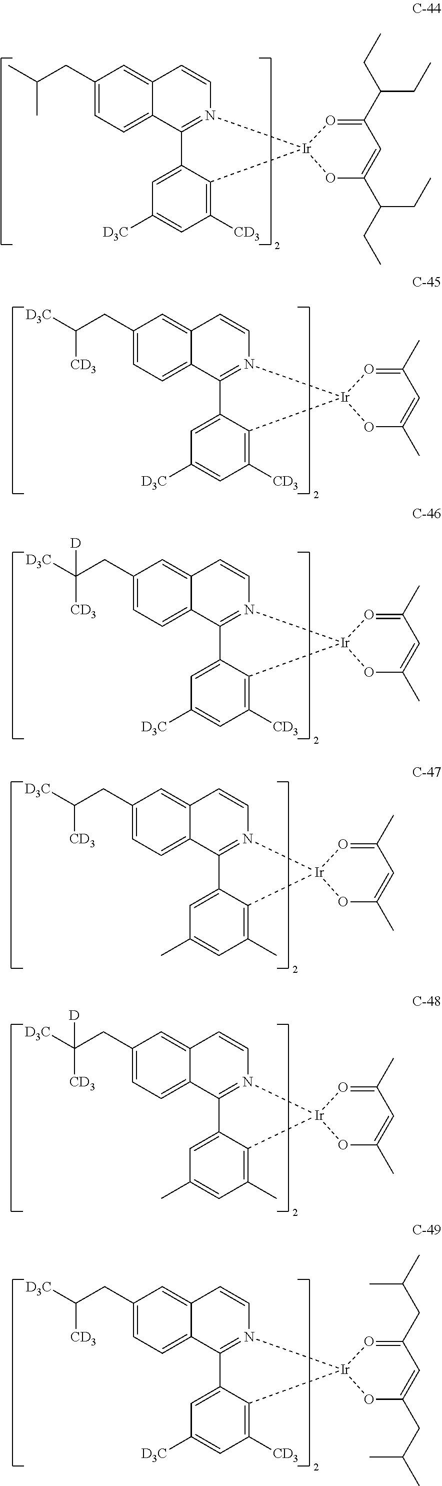

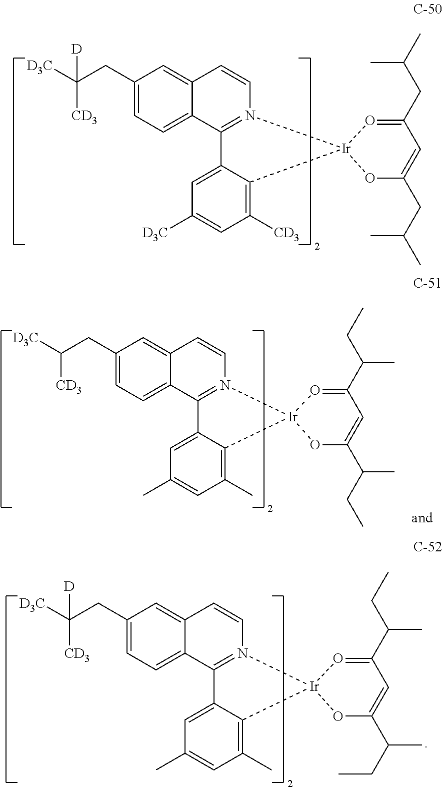

8. An organic electroluminescent device comprising a cathode, an anode, and an organic layer disposed between the cathode and the anode,
wherein the organic layer comprises the compound represented by formula 1 recited in claim 1.

9. The organic electroluminescent device according to claim 8, further comprising a compound represented by any one of the following formulas 2 to 4: 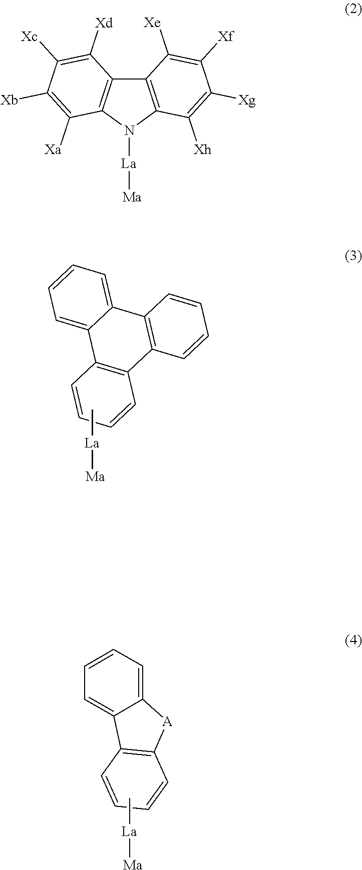
wherein
Ma represents a substituted or unsubstituted (C6-C30)aryl, or a substituted or unsubstituted (6- to 30-membered)heteroaryl,
La represents a single bond, a substituted or unsubstituted (C6-C30)arylene, or a substituted or unsubstituted (6- to 30-membered)heteroarylene,
A represents S, O, NRS, or CR₈R₉,
Xa to Xh, each independently, represent hydrogen, deuterium, a halogen, a cyano, a substituted or unsubstituted (C1-C30)alkyl, a substituted or unsubstituted (C2-C30)alkenyl, a substituted or unsubstituted (C2-C30)alkynyl, a substituted or unsubstituted (C3-C30)cycloalkyl, a substituted or unsubstituted (C6-C60)aryl, a substituted or unsubstituted (3- to 30-membered)heteroaryl, a substituted or unsubstituted tri(C1-C30)alkylsilyl, a substituted or unsubstituted tri(C6-C30)arylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted (C1-C30)alkyl(C6-C30)arylamino, or a substituted or unsubstituted mono- or di-(C6-C30)arylamino; or are linked to an adjacent substituent to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom from the group consisting of nitrogen, oxygen, and sulfur,
R₇ to R₉, each independently, represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or R₈ and R₉ are linked to each other to form a substituted or unsubstituted, mono- or polycyclic, (C3-C30) alicyclic or aromatic ring, or the combination thereof, wherein the carbon atom(s) of the alicyclic or aromatic ring, or the combination thereof may be replaced with at least one heteroatom selected from the group consisting of nitrogen, oxygen, and sulfur, and
the heteroaryl(ene) contains at least one heteroatom selected from the group consisting of B, N, O, S, Si, and P.

10. The organic electroluminescent device according to claim 9,
wherein the organic electroluminescent device comprises the compound represented by the formula 1 as a dopant, and the compound represented by any one of the formulas 2 to 4 as a host.
